(19) United States
(12) Patent Application Publication
(10) Pub. No.: US 2023/0054731 A1
(43) Pub. Date: Feb. 23, 2023

(54) ARRAY TYPE SEMICONDUCTOR LASER DEVICE

(71) Applicant: Nuvoton Technology Corporation Japan, Kyoto (JP)

(72) Inventors: Tohru NISHIKAWA, Toyama (JP); Mitsuru NISHITSUJI, Toyama (JP); Kazuya YAMADA, Toyama (JP); Masayuki HATA, Osaka (JP)

(21) Appl. No.: 18/045,699

(22) Filed: Oct. 11, 2022

Related U.S. Application Data
(63) Continuation of application No. PCT/JP2021/014743, filed on Apr. 7, 2021.

(30) Foreign Application Priority Data
Apr. 16, 2020 (JP) 2020-073278

(51) Int. Cl. H01S 5/40; H01S 5/042

(52) U.S. Cl. CPC H01S 5/4025; H01S 5/0422; H01S 5/04256

(57) ABSTRACT

An array type semiconductor laser device includes: a second electrode (p-electrode) disposed on another conductivity type semiconductor layer; a third electrode (n-electrode) disposed on a one conductivity type semiconductor layer and between a first electrode (p-electrode) and the second electrode; a fifth electrode (n-electrode) disposed on the one conductivity type semiconductor layer and between the third electrode and the second electrode; a sixth electrode (n-electrode) disposed on the one conductivity type semiconductor layer and across from the fifth electrode; a first conductor (wire) that electrically connects the second electrode and the third electrode; and a second conductor (n-wiring) that electrically connects the fifth electrode and the sixth electrode.

### CROSS REFERENCE TO RELATED APPLICATIONS

This is a continuation application of PCT International Application No. PCT/JP2021/014743 filed on Apr. 7, 2021, designating the United States of America, which is based on and claims priority of Japanese Patent Application No. 2020-073278 filed on Apr. 16, 2020. The entire disclosures of the above-identified applications, including the specifications, drawings and claims are incorporated herein by reference in their entirety.

### FIELD

The present disclosure relates to an array type semiconductor laser device.

### BACKGROUND

Conventionally, there is an array type semiconductor laser array element having a plurality of light-emitting element regions (for example, see Patent Literature (PTL) 1).

PTL 1 discloses a configuration in which the light-emitting element regions of the semiconductor laser array element are electrically connected in series. Accordingly, current is injected in series into the light-emitting element regions of the semiconductor laser array element disclosed in PTL 1. According to this, driving current can be reduced as compared with the case in which current is injected in parallel into the light-emitting element regions of the semiconductor laser array element.

### CITATION LIST

### Patent Literature

PTL: Japanese Unexamined Patent Application Publication No. H09-167878

### SUMMARY

### Technical Problem

However, with the configuration disclosed in PTL 1, a flow of current through an active layer (a light-emitting layer) shifts toward an n-side electrode, due to an arrangement of p-side and n-side electrodes. Accordingly, a light-emitting point in the active layer shifts toward the n-side electrode.

The present disclosure provides an array type semiconductor laser device that includes a plurality of semiconductor laser elements connected in series, and reduces a shift of a flow of current through an active layer.

### Solution to Problem

A semiconductor laser device according to an aspect of the present disclosure is an array type semiconductor laser device including: a semiconductor laser array element in which a first semiconductor laser element and a second semiconductor laser element are disposed on a substrate. The first semiconductor laser element includes a first one conductivity type semiconductor layer and a first other conductivity type semiconductor layer, the first one conductivity type semiconductor layer being closer to the substrate than the first other conductivity type semiconductor layer is to the substrate. The second semiconductor laser element includes a second one conductivity type semiconductor layer and a second other conductivity type semiconductor layer, the second one conductivity type semiconductor layer being closer to the substrate than the second other conductivity type semiconductor layer is to the substrate. The first semiconductor laser element includes a first waveguide that extends in a first direction along a surface of the substrate. The second semiconductor laser element is disposed, relative to the first semiconductor laser element, in a second direction along the surface of the substrate, the second direction being orthogonal to the first direction. The second semiconductor laser element includes a second waveguide that extends in the first direction. The first semiconductor laser element includes, on a first surface on a side opposite the substrate, a first electrode disposed on the first other conductivity type semiconductor layer. The second semiconductor laser element includes, on the first surface, a second electrode disposed on the second other conductivity type semiconductor layer. The first semiconductor laser element includes, on the first surface: a third electrode disposed on the first one conductivity type semiconductor layer and between the first electrode and the second electrode; and a fourth electrode disposed on the first one conductivity type semiconductor layer and across from the third electrode. The second semiconductor laser element includes, on the first surface: a fifth electrode disposed on the second one conductivity type semiconductor layer and between the second electrode and the third electrode; and a sixth electrode disposed on the second one conductivity type semiconductor layer and across from the fifth electrode. The array type semiconductor laser device further includes: a first conductor that electrically connects the second electrode and the third electrode; and a second conductor that electrically connects the fifth electrode and the sixth electrode.

### Advantageous Effects

According to an array type semiconductor laser device according to an aspect of the present disclosure, a plurality of semiconductor laser elements are connected in series, and a shift of a light-emitting point can be reduced.

### BRIEF DESCRIPTION OF DRAWINGS

These and other advantages and features will become apparent from the following description thereof taken in conjunction with the accompanying Drawings, by way of nonlimiting examples of embodiments disclosed herein.

FIG. 1 is a top view illustrating an array type semiconductor laser device according to Embodiment 1.

FIG. 2 is a cross sectional view illustrating the array type semiconductor laser device according to Embodiment 1, which is taken along line II-II in FIG. 1.

FIG. 3 is a bottom view of a semiconductor laser array element according to Embodiment 1.

FIG. 4 is a top view illustrating a submount according to Embodiment 1.

FIG. 5 is a cross sectional view illustrating the semiconductor laser array element according to Embodiment 1, which is taken along line XII-XII in FIG. 3.

FIG. 6 is an enlarged view illustrating a region surrounded by broken line VI in FIG. 5.

FIG. 7 is a cross sectional view illustrating a connection portion that connects the semiconductor laser array element and a base according to Embodiment 1.

FIG. 8 is a cross sectional view illustrating a joining layer that joins the base and a heat sink according to Embodiment 1.

FIG. 9 is a cross sectional view illustrating a semiconductor laser array element according to Variation 1 of Embodiment 1.

FIG. 10 is an enlarged view illustrating a region surrounded by broken line X in FIG. 9.

FIG. 11 is a top view illustrating an array type semiconductor laser device according to Variation 2 of Embodiment 1.

FIG. 12 is a top view illustrating an array type semiconductor laser device according to Variation 3 of Embodiment 1.

FIG. 13 is a top view illustrating an array type semiconductor laser device according to Embodiment 2.

FIG. 14 is a top view illustrating an array type semiconductor laser device according to Embodiment 3.

FIG. 15 is a top view illustrating a submount according to Embodiment 3.

FIG. 16 is a bottom view illustrating a semiconductor laser array element according to Embodiment 3.

FIG. 17 is a cross sectional view illustrating an array type semiconductor laser device according to Embodiment 3, which is taken along line XVII-XVII in FIG. 14.

FIG. 18 is a cross sectional view illustrating the array type semiconductor laser device according to Embodiment 3, which is taken along line XVIII-XVIII in FIG. 14.

FIG. 19 is a top view illustrating an array type semiconductor laser device according to Variation 1 of Embodiment 3.

FIG. 20 is a cross sectional view illustrating the array type semiconductor laser device according to Variation 1 of Embodiment 3, which is taken along line XX-XX in FIG. 19.

FIG. 21 is a cross sectional view illustrating insulating films and connection films according to Variation 1 of Embodiment 3, which is taken along line XXI-XXI in FIG. 19.

FIG. 22 is a cross sectional view illustrating the insulating film and the connection film according to Variation 1 of Embodiment 3, which is taken along line XXII-XXII in FIG. 19.

FIG. 23 is a top view illustrating an array type semiconductor laser device according to Embodiment 4.

FIG. 24 is a cross sectional view illustrating the array type semiconductor laser device according to Embodiment 4, which is taken along line XXIV-XXIV in FIG. 23.

FIG. 25 is a cross sectional view illustrating the array type semiconductor laser device according to Embodiment 4, which is taken along line XXV-XXV in FIG. 23.

FIG. 26 is a top view illustrating a submount according to Embodiment 4.

FIG. 27 is a bottom view illustrating the submount according to Embodiment 4.

FIG. 28 is an enlarged view illustrating a region surrounded by broken line XXVIII in FIG. 25.

FIG. 29 is an enlarged view illustrating a region surrounded by broken line XXIX in FIG. 25.

FIG. 30 is a cross sectional view of an array type semiconductor laser device according to Variation 1 of Embodiment 4, which includes a second conductor.

FIG. 31 is a cross sectional view of the array type semiconductor laser device according to Variation 1 of Embodiment 4, which includes a first conductor.

FIG. 32 is a cross sectional view of an array type semiconductor laser device according to Variation 2 of Embodiment 4, which includes a second conductor.

FIG. 33 is a cross sectional view of the array type semiconductor laser device according to Variation 2 of Embodiment 4, which includes a first conductor.

FIG. 34 is a top view illustrating an array type semiconductor laser device according to Variation 3 of Embodiment 4.

FIG. 35 is a cross sectional view illustrating the array type semiconductor laser device according to Variation 3 of Embodiment 4, which is taken along line XXXV-XXXV in FIG. 34.

FIG. 36 is a top view illustrating a submount according to Variation 3 of Embodiment 4.

FIG. 37 is a bottom view illustrating the submount according to Variation 3 of Embodiment 4.

FIG. 38 is a top view illustrating an array type semiconductor laser device according to Variation 4 of Embodiment 4.

FIG. 39 is a cross sectional view illustrating the array type semiconductor laser device according to Variation 4 of Embodiment 4, which is taken along line XXXIX-XXXIX in FIG. 38.

FIG. 40 is a top view illustrating a submount according to Variation 4 of Embodiment 4.

FIG. 41 is a top view illustrating an array type semiconductor laser device according to Embodiment 5.

FIG. 42 is a top view illustrating a semiconductor laser array element according to Embodiment 5.

FIG. 43 is a cross sectional view illustrating the array type semiconductor laser device according to Embodiment 5, which is taken along line XLIV-XLIV in FIG. 41.

FIG. 44 is a cross sectional view illustrating the array type semiconductor laser device according to Embodiment 5, which is taken along line XLIII-XLIII in FIG. 41.

FIG. 45 is a top view illustrating a submount according to Embodiment 5.

FIG. 46 is a bottom view illustrating the submount according to Embodiment 5.

FIG. 47 is a bottom view illustrating the semiconductor laser array element according to Embodiment 5.

FIG. 48 is a cross sectional view illustrating the semiconductor laser array element according to Embodiment 5, which is taken along line XLVIII-XLVIII in FIG. 47.

FIG. 49 is a cross sectional view illustrating the semiconductor laser array element according to Embodiment 5, which is taken along line XLIX-XLIX in FIG. 47.

FIG. 50 is an enlarged view illustrating a region surrounded by broken line L in FIG. 49.

FIG. 51 is a top view illustrating an array type semiconductor laser device according to Variation 1 of Embodiment 5.

FIG. 52 is a cross sectional view illustrating the array type semiconductor laser device according to Variation 1 of Embodiment 5, which is taken along line LII-LII in FIG. 51.

FIG. 53 is a top view illustrating an array type semiconductor laser device according to Embodiment 6.

FIG. 54 is a bottom view illustrating a semiconductor laser array element according to Embodiment 6.

FIG. 55 is a cross sectional view of the array type semiconductor laser device according to Embodiment 6, which includes a second conductor and is taken along line LV-LV in FIG. 53.

FIG. 56 is a cross sectional view illustrating the array type semiconductor laser device according to Embodiment 6, which is taken along line LVI-LVI in FIG. 53.

[ FIG. 57 is a cross sectional view of the array type semiconductor laser device according to Embodiment 6, which includes a first conductor and is taken along line LVII-LVII in FIG. 53.

FIG. 58 is a bottom view illustrating a semiconductor laser array element according to Variation 1 of Embodiment 6.

FIG. 59 is a cross sectional view of the semiconductor laser array element according to Variation 1 of Embodiment 6, which includes a second conductor and is taken along line LIX-LIX in FIG. 58.

FIG. 60 is a cross sectional view illustrating the semiconductor laser array element according to Variation 1 of Embodiment 6, which is taken along line LX-LX in FIG. 58.

FIG. 61 is a cross sectional view of the semiconductor laser array element according to Variation 1 of Embodiment 6, which includes a first conductor and is taken along line LXI-LXI in FIG. 58.

FIG. 62 is a bottom view illustrating a semiconductor laser array element according to Variation 2 of Embodiment 6.

FIG. 63 is a cross sectional view of the semiconductor laser array element according to Variation 2 of Embodiment 6, which includes a second conductor and is taken along line LXIII-LXIII in FIG. 62.

FIG. 64 is a cross sectional view illustrating the semiconductor laser array element according to Variation 2 of Embodiment 6, which is taken along line LXIV-LXIV in FIG. 62.

FIG. 65 is a cross sectional view of the semiconductor laser array element according to Variation 2 of Embodiment 6, which includes a first conductor and is taken along line LXV-LXV in FIG. 62.

FIG. 66 is a top view illustrating an array type semiconductor laser device according to Embodiment 7.

FIG. 67 is a bottom view illustrating a semiconductor laser array element according to Embodiment 7.

FIG. 68 is a cross sectional view illustrating the array type semiconductor laser device according to Embodiment 7, which is taken along line LXVIII-LXVIII in FIG. 66.

FIG. 69 is a cross sectional view of the array type semiconductor laser device according to Embodiment 7, which includes a second conductor and is taken along line LXIX-LXIX in FIG. 66.

[FIG. 70] FIG. 70 is a bottom view illustrating a semiconductor laser array element according to a variation of Embodiment 7.

FIG. 71 is a cross sectional view of the semiconductor laser array element according to the variation of Embodiment 7, which includes a first conductor and is taken along line LXXI-LXXI in FIG. 70.

FIG. 72 is a cross sectional view illustrating the semiconductor laser array element according to the variation of Embodiment 7, which is taken along line LXXII-LXXII in FIG. 70.

FIG. 73 is a top view illustrating an array type semiconductor laser device according to Embodiment 8.

FIG. 74 is a bottom view illustrating a semiconductor laser array element according to Embodiment 8.

FIG. 75 is a cross sectional view illustrating the array type semiconductor laser device according to Embodiment 8, which is taken along line LXXV-LXXV in FIG. 73.

FIG. 76 is a cross sectional view of the array type semiconductor laser device according to Embodiment 8, which includes a first conductor and is taken along line LXXVI-LXXVI in FIG. 73.

FIG. 77 is a bottom view illustrating a semiconductor laser array element according to a variation of Embodiment 8.

FIG. 78 is a cross sectional view illustrating the semiconductor laser array element according to the variation of Embodiment 8, which is taken along line LXXVIII-LXXVIII in FIG. 77.

FIG. 79 is a cross sectional view illustrating the semiconductor laser array element according to the variation of Embodiment 8, which is taken along line LXXIX-LXXIX in FIG. 77.

### DESCRIPTION OF EMBODIMENTS

The following describes in detail embodiments of the present disclosure, with reference to the drawings. Note that the embodiments described below each show a general or specific example of the present disclosure. The numerical values, shapes, materials, elements, the arrangement and connection of the elements, steps, and the processing order of the steps, for instance, described in the following embodiments are examples, and thus are not intended to limit the present disposure.

Note that the drawings are schematic diagrams, and do not necessarily provide strictly accurate illustration. Accordingly, for example, scales are not necessarily the same in the drawings. Throughout the drawings, the same reference sign is given to substantially the same element, and redundant description for such substantially the same element may be omitted or simplified.

In the following embodiments, expressions that use numerical values such as “4 µm” are used. For example, “4 µm” means not only exactly 4 µm, but also substantially 4 µm. Stated differently, “4 µm” also means a value that includes approximately several per cent of error, for example. Such an expression may include a maximum of approximately 50% of error. The same applies to other expressions that use numerical values.

In the following embodiments, expressions that use “substantially” such as “substantially the same” are used. For example, “substantially” means not only exactly the same, but also substantially the same. Stated differently, “substantially” also means that approximately several per cent of error, for example, is included. Such an expression may include a maximum of approximately 50% of error.

In the embodiments below, the terms “above” and “below” do not indicate upward (vertically upward) and downward (vertically downward) in the absolute recognition of space. Furthermore, the terms “above” and “below” are used not only when two elements are spaced apart from each other and another element is present therebetween, but also when two elements are in close contact with each other and touching each other. The following embodiments are described, assuming that the Z-axis positive direction is referred to using “above”, and the Z-axis negative direction is referred to using “below”. In addition, description is given assuming that the resonator length direction of a semiconductor laser element (a direction in which a waveguide extends) is a Y-axis direction or a first direction. The direction orthogonal to the Y axis and the Z axis is the X-axis direction, and also referred to as a lateral direction or a second direction.

In the embodiments below, the “thickness” and the “height” both mean a length in the Z-axis direction.

In the present disclosure, one of n-type or p-type is referred to as one conductivity type and the other is referred to as the other conductivity type. In the following embodiments, there are cases where the n-type is referred to as one conductivity type and the p-type is referred to as the other conductivity type, yet the present disclosure also encompasses a structure in which the n-type and the p-type are switched. In addition, the term “on” in expressions such as mounted on, disposed on, provided on, and formed on, for example, does not necessarily indicate direct contact, and thus is also used when indirect contact is mentioned. Hence, when A is on B, this means that not only A is touching B, but also one or more other elements are between A and B. The terms “connected” and “joined” in expressions such as “connected to” and “joined to”, for example, do not necessarily mean being physically connected or physically joined. The terms are also used to indicate states of being indirectly connected and jointed, such as being electrically connected and joined.

### Outline of the Present Disclosure

An array type semiconductor laser device includes a plurality of semiconductor laser elements.

For example, the array type semiconductor laser device includes a semiconductor laser array element in which a first semiconductor laser element and a second semiconductor laser element are formed on the same substrate.

The first semiconductor laser element includes a first one conductivity type semiconductor layer and a first other conductivity type semiconductor layer, the first one conductivity type semiconductor layer being closer to the substrate than the first other conductivity type semiconductor layer is to the substrate.

The first semiconductor laser element includes a first waveguide that extends in a first direction along a surface of the substrate, and includes, on a first surface on a side opposite the substrate, a first electrode formed on the first other conductivity type semiconductor layer, includes, on the first surface, a third electrode formed on the first one conductivity type semiconductor layer and disposed between the first electrode and a second electrode (a later-described second electrode included in the second semiconductor laser element), and a fourth electrode formed on the first one conductivity type semiconductor layer and disposed across from the third electrode.

The second semiconductor laser element includes a second one conductivity type semiconductor layer and a second other conductivity type semiconductor layer, the second one conductivity type semiconductor layer being closer to the substrate than the second other conductivity type semiconductor layer is to the substrate. The second semiconductor laser element is disposed, relative to the first semiconductor laser element, in a second direction that extends along the surface of the substrate and is orthogonal to the first direction. The second semiconductor laser element includes a second waveguide that extends in the first direction, and includes, on the first surface, the second electrode formed on the second other conductivity type semiconductor layer. The second semiconductor laser element includes a fifth electrode formed on the second one conductivity type semiconductor layer and disposed between the third electrode and the second electrode, and a sixth electrode formed on the second one conductivity type semiconductor layer and disposed across from the fifth electrode.

Here, the array type semiconductor laser device according to the present disclosure includes a first conductor that electrically connects the second electrode and the third electrode, and a second conductor that electrically connects the fifth electrode and the sixth electrode.

According to this, the plurality of semiconductor laser elements included in the array type semiconductor laser device can be connected in series, and current can be applied uniformly in the second direction to the one conductivity type semiconductor layers and other semiconductor layers (more specifically, the waveguides or active layers later described) that are included in the first semiconductor laser element and the second semiconductor laser element. Hence, according to the array type semiconductor laser device according to the present disclosure, a shift of a light-emitting point (in a waveguide or an active layer later described) of each of the first semiconductor laser element and the second semiconductor laser element can be reduced.

In the following, details of embodiments and variations of array type semiconductor laser devices according to the present disclosure are to be described.

Note that in the following, a description may be given, assuming that the Y-axis direction is a first direction, and the X-axis direction is a second direction.

Further, in the following, a direction in which the semiconductor laser elements output laser beams may also be referred to as forward, and the opposite direction may also be referred to as backward. For example, in the following description, the Y-axis positive direction relative to the semiconductor laser elements is also referred to as forward, and the Y-axis negative direction is also referred to as backward.

A first electrode included in one of the semiconductor laser elements is also referred to as p-electrode P10, a second electrode included therein is also referred to as p-electrode P11, a third electrode included therein is also referred to as n-electrode N11, a fourth electrode included therein is also referred to as n-electrode N10, a fifth electrode included therein is referred to as n-electrode N12, and a sixth electrode included therein is also referred to as n-electrode N13.

A conductor that electrically connects p-electrode P11 and n-electrode N11 is also referred to as a first conductor. A conductor that electrically connects n-electrode N12 and n-electrode N13 is also referred to as a second conductor.

### Embodiment 1

### Configuration

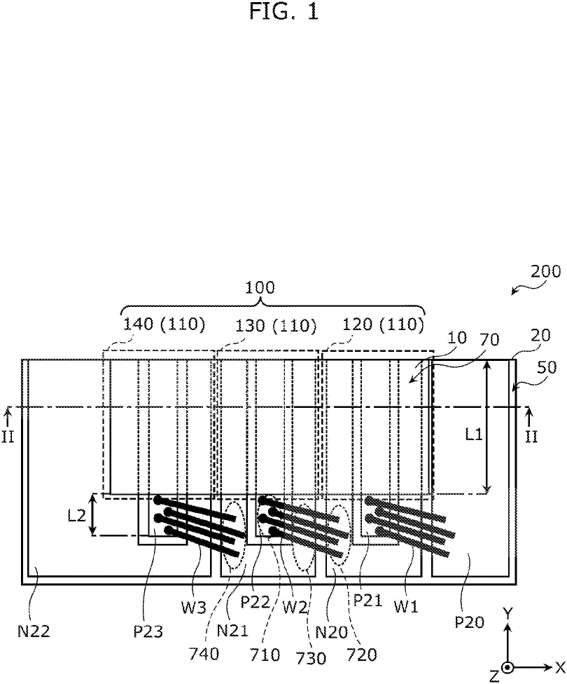

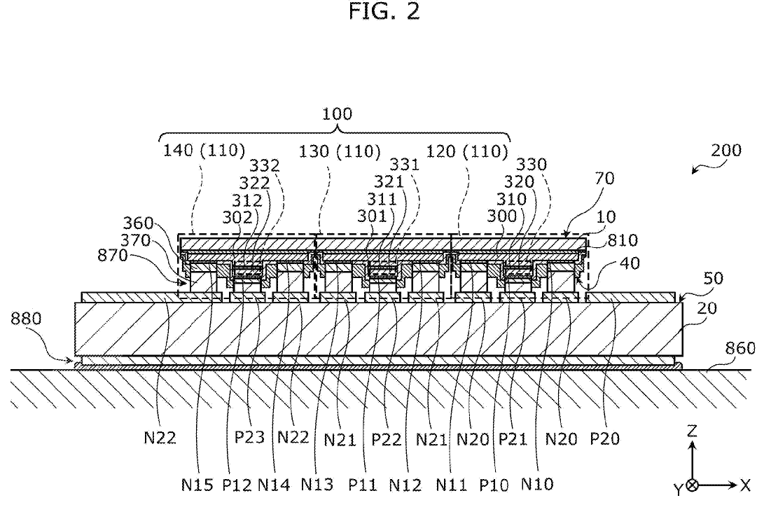

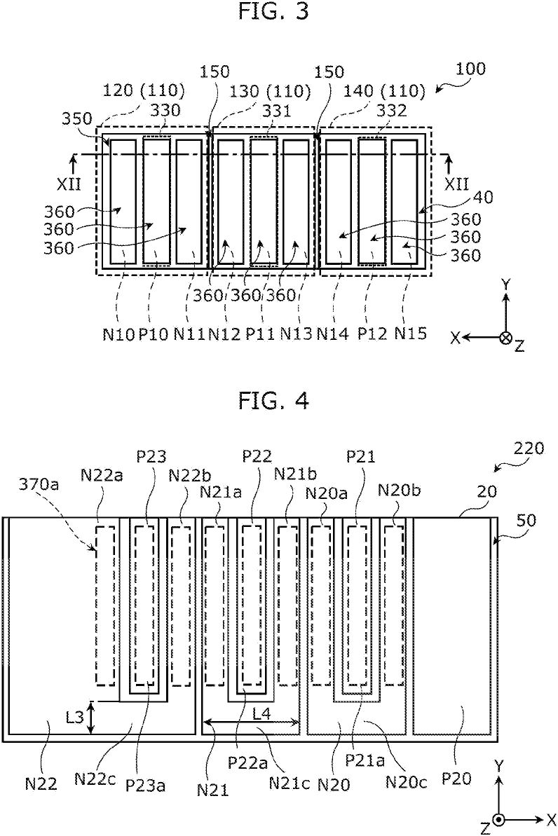

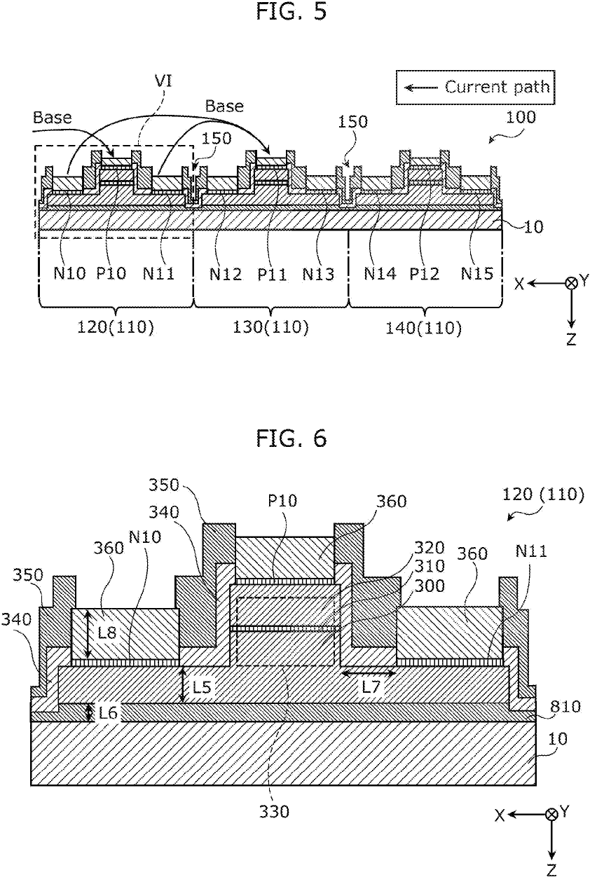

FIG. 1 is a top view illustrating array type semiconductor laser device 200 according to Embodiment 1. FIG. 2 is a cross sectional view illustrating array type semiconductor laser device 200 according to Embodiment 1, which is taken along line II-II in FIG. 1. FIG. 3 is a bottom view of semiconductor laser array element 100 according to Embodiment 1. FIG. 4 is a top view illustrating submount 220 according to Embodiment 1. FIG. 5 is a cross sectional view illustrating semiconductor laser array element 100 according to Embodiment 1. FIG. 6 is an enlarged view illustrating a region surrounded by broken line VI in FIG. 5.

Array type semiconductor laser device 200 is a device in which semiconductor laser element 120, semiconductor laser element 130, and semiconductor laser element 140 are formed on substrate 10, being electrically isolated from one another.

Note that semiconductor laser element 120, semiconductor laser element 130, and semiconductor laser element 140 being electrically isolated from one another means that, for example, one conductivity type semiconductor layers, active layers, and other conductivity type semiconductor layers that are included in semiconductor laser elements 120 and 130 are not in direct contact (or in other words, are physically separated) and furthermore, one conductivity type semiconductor layers, active layers, and other conductivity type semiconductor layers that are included in semiconductor laser elements 130 and 140 are not in direct contact (or in other words, are physically separated), and means that semiconductor laser element 120 and semiconductor laser element 130 (and semiconductor laser element 130 and semiconductor laser element 140) are electrically connected via external lines. For example, in semiconductor laser element 120, one conductivity type semiconductor layer 300 is connected to other conductivity type semiconductor layer 320 via active layer 310, not via an external line.

Semiconductor laser element 120, semiconductor laser element 130, and semiconductor laser element 140 are electrically connected in series in this order. For example, one conductivity type semiconductor layer 300 in semiconductor laser element 120 is electrically connected to one conductivity type semiconductor layer 301 in semiconductor laser element 130 via active layer 311.

Array type semiconductor laser device 200 includes substrate 10, semiconductor laser array element 100, and base 20.

Substrate 10 is a semiconductor substrate having an undersurface below which semiconductor laser array element 100 is formed. Substrate 10 is a GaAs substrate, for example. Barrier layer 810 is formed on substrate 10.

Barrier layer 810 is an electrically insulating layer. Barrier layer 810 is formed between substrate 10 and one conductivity type semiconductor layer 300, between substrate 10 and one conductivity type semiconductor layer 301, and between substrate 10 and one conductivity type semiconductor layer 302. Barrier layer 810 is an i-GaAs layer, for example. Thickness L6 of barrier layer 810 is at least 5 µm, for example.

Semiconductor laser array element 100 includes waveguides 330, 331, and 332 (and light-emitting points), and outputs laser beams. The light-emitting points are spots at which semiconductor laser array element 100 emits laser beams, and are in the positions of waveguides 330 to 332 illustrated in FIG. 2, for example. Semiconductor laser array element 100 includes semiconductor laser elements 110. In the present embodiment, semiconductor laser array element 100 includes semiconductor laser element 120 (a first semiconductor laser element), semiconductor laser element 130 (a second semiconductor laser element), and semiconductor laser element 140 (a third semiconductor laser element). Semiconductor laser element 120 includes n-electrode N10, p-electrode P10, and n-electrode N11. Semiconductor laser element 130 includes n-electrode N12, p-electrode P11, and n-electrode N13. Semiconductor laser element 140 includes n-electrode N14, p-electrode P12, and n-electrode N15. Note that the widths of waveguides 330, 331 and 332 in the X-axis direction are substantially the same as the widths of p-electrodes P10, P11 and P12 in the X-axis direction, respectively.

Note that when a common description that applies to all semiconductor laser elements 120, 130, and 140 is given, semiconductor laser element 120, semiconductor laser element 130, and semiconductor laser element 140 may be simply referred to as semiconductor laser element(s) 110.

It is sufficient if the number of semiconductor laser elements included in semiconductor laser array element 100 is at least two, and the number thereof is not limited in particular. Semiconductor laser elements 110 included in semiconductor laser array element 100 are connected in series. Thus, semiconductor laser element 120 and semiconductor laser element 130 are connected in series.

Semiconductor laser element 120 includes one conductivity type semiconductor layer 300 (a first one conductivity type semiconductor layer), active layer 310, and other conductivity type semiconductor layer 320 (a first other conductivity type semiconductor layer), from the substrate 10 side. Semiconductor laser element 120 includes waveguide 330 (a first waveguide) that extends in a first direction (the Y-axis direction in the present embodiment) along a surface of substrate 10. Waveguide 330 is a waveguide portion for laser beams, which includes a portion of one conductivity type semiconductor layer 300, a portion of active layer 310, and a portion of other conductivity type semiconductor layer 320.

Semiconductor laser element 120 includes p-electrode P10 (a first electrode), n-electrode N11 (a third electrode), and n-electrode N10 (a fourth electrode).

On a surface (also referred to as an undersurface or first surface 40) located on a side opposite substrate 10, p-electrode P10 is formed so as to be electrically connected to other conductivity type semiconductor layer 320.

On first surface 40, n-electrode N11 is formed so as to be electrically connected to one conductivity type semiconductor layer 300, and is disposed between p-electrode P10 and p-electrode P11.

On first surface 40, n-electrode N10 is formed on one conductivity type semiconductor layer 300, and is disposed across p-electrode P10 from n-electrode N11. Stated differently, p-electrode P10 is located between n-electrode N11 and n-electrode N10 in a top view.

As illustrated in FIG. 6, thickness L5 of one conductivity type semiconductor layer 300 between barrier layer 810 and n-electrode N10 is at least 5 µm, for example.

Semiconductor laser element 120 includes insulating film 340, protective film 350, and wiring electrode 360.

Insulating film 340 is an electrically insulating film. Insulating film 340 covers side surfaces of semiconductor layers such as one conductivity type semiconductor layer 300, active layer 310, and other conductivity type semiconductor layer 320. Width L7 of insulating film 340 in the X-axis direction is at least 15 µm, for example.

Protective film 350 covers insulating film 340, and is for protecting insulating film 340 and semiconductor layers.

Wiring electrode 360 is for electrically connecting n-electrodes N10 and N11 and p-electrode P10 to other elements such as wirings formed on base 20.

Thickness L8 of wiring electrode 360 is at least 3 µm, for example.

Note that each of semiconductor laser element 130 and semiconductor laser element 140 also has a configuration similar to the configuration of semiconductor laser element 120 illustrated in FIG. 6.

Semiconductor laser element 130 includes one conductivity type semiconductor layer 301 (a second one conductivity type semiconductor layer), active layer 311, and other conductivity type semiconductor layer 321 (a second other conductivity type semiconductor layer), from the substrate 10 side. Semiconductor laser element 130 includes waveguide 331 (a second waveguide) that extends in the first direction.

Semiconductor laser element 130 includes p-electrode P11 (a second electrode), n-electrode N12 (a fifth electrode), and n-electrode N13 (a sixth electrode).

On first surface 40, p-electrode P11 is formed on other conductivity type semiconductor layer 321.

On first surface 40, n-electrode N12 is formed on one conductivity type semiconductor layer 301, and is disposed between n-electrode N11 and p-electrode P11.

On first surface 40, n-electrode N13 is formed on one conductivity type semiconductor layer 301 and is disposed across p-electrode P11 from n-electrode N12.

Semiconductor laser element 140 includes one conductivity type semiconductor layer 302 (a third one conductivity type semiconductor layer), active layer 312, and other conductivity type semiconductor layer 322 (a third other conductivity type semiconductor layer), from the substrate 10 side. Semiconductor laser element 140 includes waveguide 332 (a third waveguide) that extends in the first direction.

Semiconductor laser element 140 includes p-electrode P12, n-electrode N14, and n-electrode N15.

On first surface 40, p-electrode P12 is formed on other conductivity type semiconductor layer 322.

On first surface 40, n-electrode N14 and n-electrode N15 are formed on one conductivity type semiconductor layer 302.

As illustrated in FIG. 3, semiconductor laser element 130 is aligned with semiconductor laser element 120 in the second direction (the X-axis direction in the present embodiment) along a surface of substrate 10, which is orthogonal to the first direction. In a top view, n-electrode N15, p-electrode P12, n-electrode N14, n-electrode N13, p-electrode P11, n-electrode N12, n-electrode N11, p-electrode P10, and n-electrode N10 are all quadrilateral, and are aligned in this order parallel to one another in the X-axis direction. Note that in FIG. 3, when semiconductor laser array element 100 is viewed from the undersurface, n-electrode N15, p-electrode P12, n-electrode N14, n-electrode N13, p-electrode P11, n-electrode N12, n-electrode N11, p-electrode P10, and n-electrode N10 are each formed into a quadrilateral shape that is substantially the same as the shape of corresponding wiring electrode 360 thereof, and are covered with corresponding wiring electrodes 360 thereof. Portions of the undersurface of semiconductor laser array element 100 where wiring electrodes 360 are not exposed are covered with protective film 350.

For example, at least one of semiconductor laser element 120 or semiconductor laser element 130 oscillates in a multi-transverse mode. For example, at least one of the widths of waveguides 330 and 331 is adjusted to cause at least one of semiconductor laser element 120 or semiconductor laser element 130 to oscillate in the multi-transverse mode.

One conductivity type semiconductor layer 300 and one conductivity type semiconductor layer 301 each include an n-type semiconductor layer. Other conductivity type semiconductor layer 320 and other conductivity type semiconductor layer 321 each include a p-type semiconductor layer.

Submount 220 has patterned wirings formed on base 20. Base 20 (a first base) is a substrate having a top surface (second surface 50) on which semiconductor laser array element 100 is disposed (mounted). In the present embodiment, semiconductor laser array element 100 is flip-chip mounted on base 20.

As illustrated in FIG. 4, p-wirings P20, P21, P22, and P23 that are p-side conductive films quadrilateral in the top view and n-wirings N20, N21, and N22 that are n-side conductive films U-shaped in the top view are formed on second surface 50. Here, p-wiring P21 is between straight portion N20a that is an end portion of n-wiring N20 and straight portion N20b that is another end portion thereof. Similarly, p-wiring P22 is between straight portion N21a that is an end portion of n-wiring N21 and straight portion N21b that is another end portion thereof. Similarly, p-wiring P23 is between straight portion N22a that is an end portion of n-wiring N22 and straight portion N22b that is another end portion thereof. Straight portion N22a, p-wiring P23, straight portion N22b, straight portion N21a, p-wiring P22, straight portion N21b, straight portion N20a, p-wiring P21, straight portion N20b, and p-wiring P20 are aligned in this order parallel to one another in the X-axis direction.

The p-electrodes and the n-electrodes included in semiconductor laser array element 100 are electrically connected to the patterned wirings formed on base 20 via wiring electrodes 360 and connection layer 370.

For example, n-electrode N10 and n-electrode N11 are electrically connected to straight portion N20b and straight portion N20a of n-wiring N20, respectively, via wiring electrodes 360 and connection layer 370. For example, n-electrode N12 and n-electrode N13 are electrically connected to straight portion N21b and straight portion N21a of n-wiring N21, respectively, via wiring electrodes 360 and connection layer 370. For example, n-electrode N14 and n-electrode N15 are electrically connected to straight portion N22b and straight portion N22a of n-wiring N22, respectively, via wiring electrodes 360 and connection layer 370. For example, p-electrode P10 is electrically connected to p-wiring P21 via wiring electrode 360 and connection layer 370. For example, p-electrode P11 is electrically connected to p-wiring P22 via wiring electrode 360 and connection layer 370. For example, p-electrode P12 is electrically connected to p-wiring P23 via wiring electrode 360 and connection layer 370.

Center portion N20c of n-wiring N20, center portion N21c of n-wiring N21, center portion N22c of n-wiring N22, one end portion P21a of p-wiring P21, one end portion P22a of p-wiring P22, and one end portion P23a of p-wiring P23 are exposed from backward ends (end portions on the negative side of the Y-axis direction in the present embodiment) of semiconductor laser elements 120 and 130 in the Y-axis direction. A first conductive film (a first conductor) and a second conductive film (a second conductor) are exposed from the backward end of semiconductor laser element 120 in the first direction. The second conductive film includes third portion 730 exposed from semiconductor laser element 120 and electrically connected to n-electrode N12, and fourth portion 740 exposed from semiconductor laser element 120 and electrically connected to n-electrode N13.

Wires W1 to W3 made of metal, which are for electrically connecting the patterned wirings, are formed on second surface 50. For example, p-wiring P20 and p-wiring P21 are electrically connected by wire W1 joined to p-wiring P20 and one end portion P21a. For example, n-wiring N20 and p-wiring P22 are electrically connected by wire W2 joined to center portion N20c and one end portion P22a. For example, n-wiring N21 and p-wiring P23 are electrically connected by wire W3 joined to center portion N21c and one end portion P23a. Wires W1, W2, and W3 are each formed of four Au wires.

P-electrode P11 and n-electrode N11 are electrically connected via n-wiring N20, wire W2, and p-wiring P22. In the present embodiment, n-wiring N20, wire W2, and p-wiring P22 are included in the first conductor.

N-electrode N12 and n-electrode N13 are electrically connected via n-wiring N21. Thus, in the present embodiment, n-wiring N21 that is a conductive film (a second conductive film) is the second conductor. Similarly, n-electrode N10 and n-electrode N11 are electrically connected via n-wiring N20, and n-electrode N14 and n-electrode N15 are electrically connected via n-wiring N22.

The width (length L3 in the Y-axis direction) of a portion of n-wiring N21 that extends in the X-axis direction is at most 60 µm, for example. Length L4 (length of a bridge wiring) of a portion of n-wiring N21 that extends in the X-axis direction is approximately 630 µm, for example.

Array type semiconductor laser device 200 includes a first metal wire (wire W2). The first metal wire (wire W2) electrically connects first portion 710 of p-wiring P22 and second portion 720 of n-wiring N20. First portion 710 of p-wiring P22 indicates the same region as one end portion P22a of p-wiring P22 described above.

Array type semiconductor laser device 200 includes recess 150 between semiconductor laser element 120 and semiconductor laser element 130. In the present embodiment, recess 150 is formed in semiconductor laser array element 100.

Recess 150 is a groove that prevents semiconductor laser element 120 and semiconductor laser element 130 from being electrically connected not via, for instance, a wiring, and is formed between semiconductor laser element 120 and semiconductor laser element 130. Recess 150 is a groove that reaches barrier layer 810. For example, a portion of recess 150 is formed in barrier layer 810. Insulating film 340 and protective film 350 are formed in recess 150.

Semiconductor laser array element 100 is mounted on base 20. Base 20 is an insulating base, for example.

In the present embodiment, a side (an undersurface side) of substrate 10 where first surface 40 is located is joined to second surface 50 (top surface) of base 20.

For example, in the top view, length L2 in the Y-axis direction of each portion of p-wirings P21, P22, and P23 that does not overlap semiconductor laser array element 100 is at most 500 µm.

Semiconductor laser array element 100 and base 20 are connected by connection portions 870.

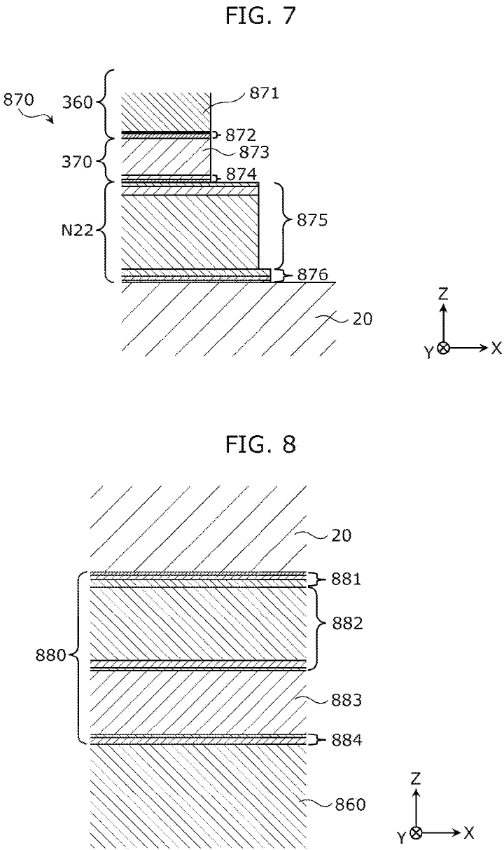

FIG. 7 is a cross sectional view illustrating connection portion 870 according to Embodiment 1.

In connection portion 870, wiring electrode 360 includes, for example, metal layer 871 and barrier metal layer 872 in the order from the upper layer side. Connection layer 370 includes solder layer 873 and solder-forming underlayer 874. The patterned wirings (for example, n-wiring N22) each include upper conductive layer 875 and underlayer 876. Underlayer 876 is formed on base 20. As illustrated in FIG. 4, connection layer 370 is formed in each of connection regions 370a indicated by the dashed lines on the patterned wirings.

Metal layer 871 includes Au, for example. Metal layer 871 is formed by plating, for example.

Barrier metal layer 872 includes, for example, a Pt layer and a Ti layer in the order from the lower layer side.

Solder layer 873 includes AuSn solder, for example.

Solder-forming underlayer 874 includes, for example, a Ti layer and a Pt layer in the order from the lower layer side.

Upper conductive layer 875 includes, for example, a Cu layer, an Ni layer, and an Au layer in the order from the lower layer side. Upper conductive layer 875 is formed by plating, for example.

Underlayer 876 includes, for example, a Ti layer, a Pt layer, and an Au layer in the order from the lower layer side, and is a base layer for forming upper conductive layer 875 by plating.

Base 20 includes an insulating ceramic material, examples of which include AlN and SiC.

Array type semiconductor laser device 200 further includes a first terminal and a second terminal.

The first terminal is electrically connected to p-electrode P10. In the present embodiment, the first terminal is p-wiring P20 formed on base 20.

The second terminal is electrically connected to n-electrode N12. In the present embodiment, the second terminal is n-wiring N22 formed on base 20. Note that in the present embodiment, n-electrode N12 is electrically connected to n-wiring N22 via n-wiring N21, wire W3, p-wiring P23, and semiconductor laser element 140.

A direct current is applied to semiconductor laser array element 100 from an external power source not illustrated, via the first terminal and the second terminal.

Base 20 is placed above heat sink 860 with joining layer 880 being provided therebetween.

Heat sink 860 is formed of highly heat conductive metal material, examples of which include Cu and Al.

Heat sink 860 and base 20 are joined using, for instance, SnAgCu solder, for example.

FIG. 8 is a cross sectional view illustrating joining layer 880 according to Embodiment 1.

Joining layer 880 includes underlayer 881, lower conductive layer 882, solder layer 883, and upper conductive layer 884 in the order from the upper layer side.

Underlayer 881 includes, for example, an Au layer, a Pt layer, and a Ti layer in the order from the lower layer side.

Lower conductive layer 882 includes, for example, an Au layer, an Ni layer, and a Cu layer in the order from the lower layer side. Lower conductive layer 882 is formed by plating, for example, and in this case, underlayer 881 is a base for lower conductive layer 882.

Solder layer 883 includes SnAgCu-based low-melting solder, for example.

Upper conductive layer 884 includes, for example, an Ni layer and an Au layer in the order from the lower layer side. Upper conductive layer 884 is formed by plating, for example.

According to the configuration as described above, array type semiconductor laser device 200 does not include wirings (also referred to as bridge wirings) that electrically connect semiconductor laser elements 110 or electrically connect semiconductor laser elements 110 and base 20. Thus, a process of manufacturing array type semiconductor laser device 200 can be further readily designed. A special process is unnecessary for base 20, and thus base 20 can be readily designed. As an assembly process for manufacturing array type semiconductor laser device 200, the configuration as described above has less points to note (lower risk of failure), and is highly feasible.

The flow of current in array type semiconductor laser device 200 starts from p-wiring P20 that is an anode electrode, and is as follows: p-wiring P20 → wire W1 → p-wiring P21 → p-electrode P10 → n-electrodes N10 and N11 → n-wiring N20 → wire W2 → p-wiring P22 → p-electrode P11 → n-electrodes N12 and N13 → n-wiring N21 → wire W3 → p-wiring P23 → p-electrode P12 → n-electrodes N14 and N15 → n-wiring N22 that is a cathode electrode.

The length of resonators of semiconductor laser elements 110 (the length in the Y-axis direction, or more specifically, length L1) is 4 mm, for example.

The thickness of plating of the wirings (Cu-plated wirings) formed on base 20 is, for example, a maximum of 75 µm, and a total of the plating thickness and the thickness of connection layer 370 (having a thickness of at least 5 µm) is at least 80 µm. A distance between adjacent wirings is the plating thickness× 150% at a minimum. Examples of a metal material used for base 20 include Cu, Au, and Al.

Electric wirings (wirings and wires W1, W2, and W3 formed on base 20) each have a resistance determined by the cross-sectional area and the length of the electric wiring. Such a resistance component becomes a heat source, and if the temperature exceeds a melting point of the wiring material due to, for instance, a flow of an overcurrent, a wiring melts and breaks. As a result of examination, an inventor of the present application found that when a current of 1.4 A flowed through a single Au wire (having a length of 3 mm) that had a diameter of 25 µm, the Au wire melted. In view of this, a rated current is set to a value of approximately ⅓ of a fusing current calculated by a structure of an electric wiring (material, a length, and a cross-sectional area of the wiring).

Expression 1 below is satisfied, where the material electric conductivity of an electric wiring is Am (%), the length of the electric wiring is L (m), and the cross-sectional area of the electric wiring is S (µm²).

$$\left(\text{Rated} \text{current}\right) = \left(8.56 \times {10}^{- 3} \times \text{Am} \times \text{S}\right) / \left(3 \times \text{L}\right) \left(\text{A}\right)$$

With regard to electric conductivity of materials, when Au is assumed to be 100%, Cu is 138%, Al is 84%, and n-GaAs is 1%, for example.

The occurrence of melting of an electric wiring can be reduced, by determining a size, for instance, of the electric wiring using Expression 1 above.

### Advantageous Effects and Others

As described above, array type semiconductor laser device 200 according to Embodiment 1 is an array type semiconductor laser device that includes semiconductor laser array element 100 in which semiconductor laser element 120 and semiconductor laser element 130 are formed on substrate 10. Semiconductor laser element 120 includes one conductivity type semiconductor layer 300 and other conductivity type semiconductor layer 320, one conductivity type semiconductor layer 300 being closer to substrate 10 than other conductivity type semiconductor layer 320 is to substrate 10. Semiconductor laser element 130 includes one conductivity type semiconductor layer 301 and other conductivity type semiconductor layer 321, one conductivity type semiconductor layer 301 being closer to substrate 10 than other conductivity type semiconductor layer 321 is to substrate 10. Semiconductor laser element 120 includes waveguide 330 that extends in a first direction (the Y-axis direction) along a surface of substrate 10. Semiconductor laser element 130 is disposed, relative to semiconductor laser element 120, in a second direction (the X-axis direction) along the surface of substrate 10, the second direction being orthogonal to the Y-axis direction. Semiconductor laser element 130 includes waveguide 331 that extends in the Y-axis direction. Semiconductor laser element 120 includes, on first surface 40 on a side opposite substrate 10, a first electrode (p-electrode P10) formed on other conductivity type semiconductor layer 320. Semiconductor laser element 130 includes, on first surface 40, a second electrode (p-electrode P11) formed on other conductivity type semiconductor layer 321. Semiconductor laser element 120 includes, on first surface 40, a third electrode (n-electrode N11) formed on one conductivity type semiconductor layer 300 and disposed between p-electrode P10 and p-electrode P11, and a fourth electrode (n-electrode N10) formed on one conductivity type semiconductor layer 300 and disposed across p-electrode P10 from n-electrode N11. Semiconductor laser element 130 includes, on first surface 40, a fifth electrode (n-electrode N12) formed on one conductivity type semiconductor layer 301 and disposed between n-electrode N11 and p-electrode P11, and a sixth electrode (n-electrode N13) formed on one conductivity type semiconductor layer 301 and disposed across p-electrode P11 from n-electrode N12. Array type semiconductor laser device 200 includes a first conductor that electrically connects p-electrode P11 and n-electrode N11, and a second conductor that electrically connects n-electrode N12 and n-electrode N13.

Note that in the present embodiment, the first conductor includes p-wiring P22, n-wiring N20, and wire W2. In the present embodiment, the second conductor is n-wiring N21.

According to this, n-electrodes are disposed on both side portions of each semiconductor laser element 110. Accordingly, current readily flows through center portions of waveguides 330 and 331 (more specifically, active layers 310 and 311) in the direction (the X-axis direction) orthogonal to the direction in which waveguides 330 and 331 extend in the top view. Thus, according to array type semiconductor laser device 200, plural semiconductor laser elements 110 are connected in series, and a shift of a flow of current through each of the active layers can be reduced.

For example, at least one of semiconductor laser element 120 or semiconductor laser element 130 oscillates in a multi-transverse mode.

According to this, the output of laser beams from array type semiconductor laser device 200 can be increased by increasing the width of a waveguide to cause the multi-transverse mode oscillation, for example.

For example, one conductivity type semiconductor layer 300 and one conductivity type semiconductor layer 301 each include an n-type semiconductor layer, and other conductivity type semiconductor layer 320 and other conductivity type semiconductor layer 321 each include a p-type semiconductor layer.

According to this, an n-type semiconductor has higher conductivity than a p-type semiconductor. Current flows through one conductivity type semiconductor layer 300 and one conductivity type semiconductor layer 301, in a direction along surfaces of the layers. Since one conductivity type semiconductor layer 300 and one conductivity type semiconductor layer 301 are formed of n-type semiconductors, the resistance of the layers and the resistance of the elements can be decreased, and thus current can be readily caused to uniformly flow through active layers 310 and 311 in the lateral direction.

For example, substrate 10 is an insulating substrate.

According to this, semiconductor laser element 120 and semiconductor laser element 130 can be readily electrically isolated (insulated). In this case, a semi-insulating GaAs substrate or a semi-insulating InP substrate may be used as substrate 10, and barrier layer 810 may not be formed.

For example, array type semiconductor laser device 200 further includes barrier layer 810 between substrate 10 and one conductivity type semiconductor layer 300 and between substrate 10 and one conductivity type semiconductor layer 301.

According to this, even if, for example, substrate 10 includes, for instance, a nitride semiconductor having conductive properties due to which insulating properties are not readily obtained, semiconductor laser element 120 and semiconductor laser element 130 can be electrically isolated. Even when substrate 10 is an insulating substrate, electrical isolation between semiconductor laser element 120 and semiconductor laser element 130 is more ensured.

For example, array type semiconductor laser device 200 further includes recess 150 between semiconductor laser element 120 and semiconductor laser element 130.

According to this, one conductivity type semiconductor layer 300 and one conductivity type semiconductor layer 301 can be readily insulated, and thus electrical isolation between semiconductor laser element 120 and semiconductor laser element 130 in a position where electrodes are not located can be achieved.

For example, a side of substrate 10 where first surface 40 is located is joined to second surface 50 of base 20.

According to this, heat generated by semiconductor laser element 110 can be readily dissipated to base 20.

For example, the first conductor is formed on base 20.

According to this, the first conductor is not disposed on first surface 40 of array type semiconductor laser device 200, and thus the arrangement of the first conductor and the second conductor on first surface 40 in array type semiconductor laser device 200 can be prevented from being complicated.

According to this, the first conductor can be readily formed on base 20.

As described above, the first conductor is a first conductive film (p-wiring P22) formed on second surface 50.

For example, p-wiring P22 is exposed from a backward end of semiconductor laser element 120 in the Y-axis direction.

According to this, p-wiring P22 and n-wiring N20 can be connected in one end portion P22a exposed from the backward end of semiconductor laser element 120. Accordingly, n-electrode N11 and p-wiring P22 can be readily electrically isolated.

For example, the first conductive film (p-wiring P22 and n-wiring N20 in the case of Embodiment 1) includes first portion 710 of p-wiring P22 exposed from semiconductor laser element 120 and semiconductor laser element 130 and electrically connected to p-electrode P11, and second portion 720 of n-wiring N20 exposed from semiconductor laser element 120 and semiconductor laser element 130 and electrically connected to n-electrode N11. Array type semiconductor laser device 200 further includes a first metal wire (wire W2) that electrically connects first portion 710 and second portion 720.

According to this, by using the first metal wire (wire W2), p-electrode P11 and n-electrode N11 can be connected so that the first conductive film (n-wiring N20 and p-wiring P22 in the present embodiment) does not contact the second conductive film (n-wiring N21 in the present embodiment).

For example, the second conductor (n-wiring N21 in the present embodiment) is formed on base 20.

According to this, the second conductor is not disposed on first surface 40 in array type semiconductor laser device 200. Accordingly, the arrangement of the first conductor and the second conductor on first surface 40 in array type semiconductor laser device 200 can be prevented from being complicated.

For example, the second conductor is a second conductive film (for example, n-wiring N21) formed on second surface 50.

According to this, the second conductor can be readily formed on base 20.

For example, the second conductive film (n-wiring N21, for example) is exposed from the backward end of semiconductor laser element 120 in the Y-axis direction.

According to this, the fifth electrode and the sixth electrode can be connected in the portions of the second conductive film exposed from the backward ends of semiconductor laser elements 120 and 130, and thus the second electrode and the second conductor can be readily electrically insulated.

For example, array type semiconductor laser device 200 further includes a first terminal (for example, p-wiring P20) connected to p-electrode P10.

According to this, for example, an external power source not illustrated and semiconductor laser elements 110 can be readily electrically connected.

For example, array type semiconductor laser device 200 further includes a second terminal (for example, n-wiring N22) connected to n-electrode N12.

According to this, an external power source not illustrated and semiconductor laser elements 110 can be readily electrically connected.

### Variation

Next, a variation of the array type semiconductor laser device according to Embodiment 1 is to be described. Note that in the variation described in the following, differences from the elements included in array type semiconductor laser device 200 according to Embodiment 1 are to be mainly described, and a description of the same elements may be simplified or omitted.

### Variation 1

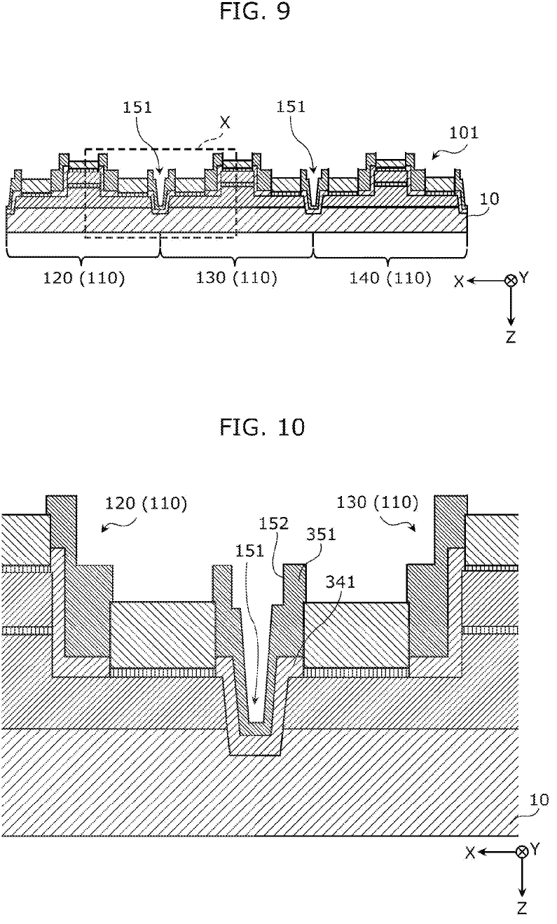

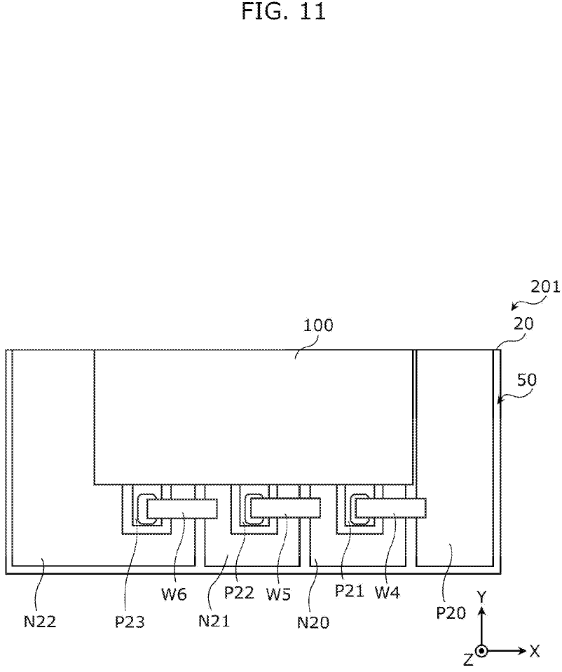

FIG. 9 is a cross sectional view illustrating semiconductor laser array element 101 according to Variation 1 of Embodiment 1. FIG. 10 is an enlarged view illustrating a region surrounded by broken line X in FIG. 9.

Semiconductor laser array element 101 includes recess 151 between semiconductor laser element 120 and semiconductor laser element 130.

Recess 151 is a groove that is formed between semiconductor laser element 120 and semiconductor laser element 130, and prevents semiconductor laser element 120 and semiconductor laser element 130 from being electrically connected not via a wiring, for instance. Recess 151 reaches substrate 10, for example. Stated differently, a portion of recess 151 is formed also in substrate 10. Insulating film 341 and protective film 351 are formed on recess 151.

Recess 151 of semiconductor laser array element 101 has a shape different from that of recess 150 of semiconductor laser array element 100. Recess 151 is formed into a tapered shape having a width in the second direction (X-axis direction) that increases from the bottom (a lower portion) of recess 151 to opening 152 (an upper portion) of the recess. Recess 151 having such a shape can be formed by wet-etching a GaAs-based semiconductor, for instance.

As described above, recess 151 reaches substrate 10 in this variation.

This can further ensure that semiconductor laser element 120 and semiconductor laser element 130 are electrically isolated.

In this variation, recess 151 is formed such that the width in the X-axis direction increases from the bottom of recess 151 to opening 152 of recess 151.

According to this, by forming recess 151 such that the width of opening 152 increases, insulating film 341 and protective film 351, for instance, can be equally formed over the corners, the lateral surfaces, and the bottom surface of opening 152 of recess 151.

### Variation 2

FIG. 11 is a top view illustrating array type semiconductor laser device 201 according to Variation 2 of Embodiment 1.

Array type semiconductor laser device 201 is different from array type semiconductor laser device 200 in shape of wires.

Wires W4, W5, and W6 included in array type semiconductor laser device 201 have a curved plate shape (a ribbon shape), not a linear shape. Thus, the shape and the number of wires included in array type semiconductor laser device 201 are not limited in particular. Resistance can be further reduced by widening wires W4, W5, and W6.

### Variation 3

FIG. 12 is a top view illustrating array type semiconductor laser device 202 according to Variation 3 of Embodiment 1. Note that, although not illustrated, semiconductor laser array element 100 included in array type semiconductor laser device 202 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction, as illustrated in FIG. 3.

Array type semiconductor laser device 202 is different from array type semiconductor laser device 200 in layout of patterned wirings formed on base 21 (a first base).

On second surface 50 of base 21, p-wiring P24 that is U-shaped in the top view, n-wirings N24 to N27 that are quadrilateral in the top view, and pn-wirings PN1 and PN2 that are U-shaped in the top view are formed. Here, n-wiring N24 is between straight portion P24a that is one end portion of p-wiring P24 and straight portion P24b that is another end portion thereof. Similarly, n-wiring N25 is between straight portion PN1a that is one end portion of pn-wiring PN1 and straight portion PN1b that is another end portion thereof. Similarly, n-wiring N26 is between straight portion PN2a that is one end portion of pn-wiring PN2 and straight portion PN2b that is another end portion thereof. N-wiring N27, straight portion PN2a, n-wiring N26, straight portion PN2b, straight portion PN1a, n-wiring N25, straight portion PN1b, straight portion P24a, n-wiring N24, and straight portion P24b are aligned in this order parallel to one another in the X-axis direction.

P-wiring P24 is an electrode film electrically connected to p-electrode P10. N-wiring N24 is an electrode film electrically connected to n-electrode N10. N-wiring N25 is an electrode film electrically connected to n-electrode N12. N-wiring N26 is an electrode film electrically connected to n-electrode N14. N-wiring N27 is an electrode film electrically connected to n-electrode N15. Straight portion PN1b and straight portion PN1a of pn-wiring PN1 are electrically connected to n-electrode N11 and p-electrode P11, respectively. Straight portion PN2b and straight portion PN2a of pn-wiring PN2 are electrically connected to n-electrode N13 and p-electrode P12, respectively.

As described above, in this variation, the first conductor that electrically connects p-electrode P11 included in semiconductor laser element 130 and n-electrode N11 included in semiconductor laser element 120 is a first conductive film (pn-wiring PN1) formed on second surface 50.

The first conductive film (the first conductor) is exposed from the backward ends of semiconductor laser element 120 and semiconductor laser element 130 in the first direction. Thus, pn-wiring PN1 has a portion that that does not overlap semiconductor laser element 120 and semiconductor laser element 130 in the top view, on the backward end side of semiconductor laser elements 120 and 130.

The first conductive film (pn-wiring PN1 in this variation) includes first portion 710 exposed from semiconductor laser element 120 and semiconductor laser element 130 and electrically connected to p-electrode P11, and second portion 720 exposed from semiconductor laser element 120 and semiconductor laser element 130 and electrically connected to n-electrode N11.

The second conductive film (n-wiring N25 and pn-wiring PN2 in this variation) includes third portion 730 exposed from semiconductor laser element 120 and semiconductor laser element 130 and electrically connected to n-electrode N12, and fourth portion 740 exposed from semiconductor laser element 120 and semiconductor laser element 130 and electrically connected to n-electrode N13.

Array type semiconductor laser device 202 includes a second metal wire (wire W8) that electrically connects third portion 730 and fourth portion 740.

By setting a wire position as close as possible to semiconductor laser element 110 and appropriately making a change to a wire line (increasing the cross-sectional area of the wire and minimizing the length of the wire), the wire resistance between n-electrodes can be further decreased. Thus, the width of an n-electrode included in semiconductor laser element 110 can be decreased. Accordingly, the size of semiconductor laser array element 100 can be decreased.

For example, the second conductive film (n-wiring N25 and pn-wiring PN2) includes third portion 730 of n-wiring N25 exposed from semiconductor laser element 120 and semiconductor laser element 130 and electrically connected to n-electrode N12, and fourth portion 740 of pn-wiring PN2 exposed from semiconductor laser element 120 and semiconductor laser element 130 and electrically connected to n-electrode N13. For example, array type semiconductor laser device 202 further includes a second metal wire (wire W8) that electrically connects third portion 730 and fourth portion 740.

According to this, by using wire W8, n-electrode N12 and n-electrode N13 can be connected so that the second conductive film does not contact the first conductive film.

### Embodiment 2

Next, an array type semiconductor laser device according to Embodiment 2 is to be described. Note that in the description of the array type semiconductor laser device according to Embodiment 2, differences from the array type semiconductor laser device according to Embodiment 1 are mainly described, and a description of similar structural elements to those of the array type semiconductor laser device according to Embodiment 1 may be omitted while substantially the same reference signs are given thereto.

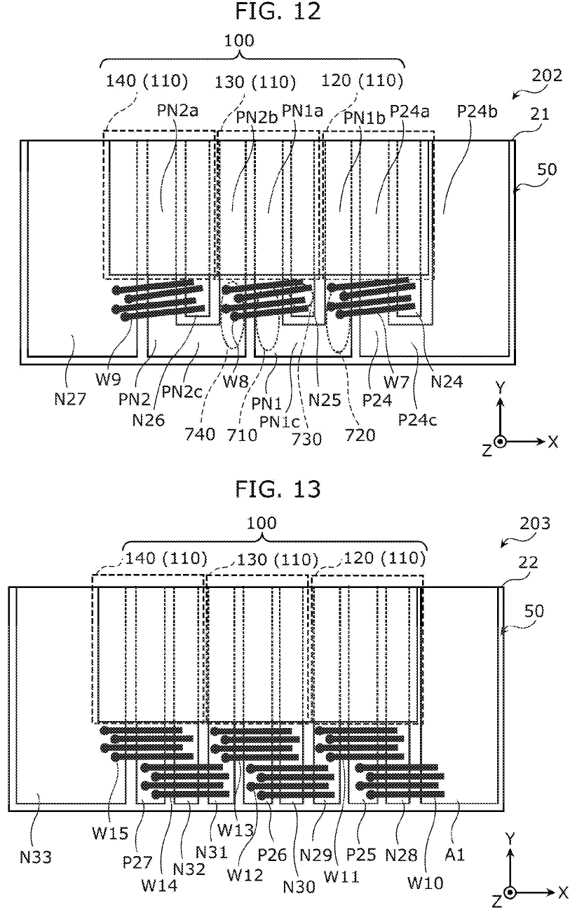

FIG. 13 is a top view illustrating array type semiconductor laser device 203 according to Embodiment 2. Note that, semiconductor laser array element 100 included in array type semiconductor laser device 203 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction, as illustrated in FIG. 3.

Array type semiconductor laser device 203 is different from array type semiconductor laser device 200 in layout of a wiring pattern formed on base 22 (a first base).

N-wiring N33, p-wiring P27, n-wiring N32, n-wiring N31, p-wiring P26, n-wiring N30, n-wiring N29, p-wiring P25, n-wiring N28, and wiring A1 that are quadrilateral in the top view are formed on second surface 50 of base 22, being aligned in this order parallel to one another in the X-axis direction.

Wiring A1 is an electrode film that functions as an anode electrode. Wiring A1 is electrically connected to p-wiring P25 via wire W10.

P-wiring P25 is an electrode film electrically connected to p-electrode P10. P-wiring P26 is an electrode film electrically connected to p-electrode P11. P-wiring P27 is an electrode film electrically connected to p-electrode P12. N-wiring N28 is an electrode film electrically connected to n-electrode N10. N-wiring N28 is electrically connected to n-wiring N29 via wire W11. N-wiring N29 is an electrode film electrically connected to n-electrode N11. N-wiring N29 is electrically connected to p-wiring P26 via wire W12. N-wiring N30 is an electrode film electrically connected to n-electrode N12. N-wiring N30 is electrically connected to n-wiring N31 via wire W13. N-wiring N31 is an electrode film electrically connected to n-electrode N13. N-wiring N31 is electrically connected to p-wiring P27 via wire W14. N-wiring N32 is an electrode film electrically connected to n-electrode N14. N-wiring N32 is electrically connected to n-wiring N33 via wire W15.

N-wiring N33 is an electrode film electrically connected to n-electrode N15. N-wiring N33 functions as a cathode electrode.

End portions of n-wiring N33, p-wiring P27, n-wiring N32, n-wiring N31, p-wiring P26, n-wiring N30, n-wiring N29, p-wiring P25, and n-wiring N28 on the negative side of the Y-axis direction are exposed from backward ends in the Y-axis direction (end portions on the negative side of the Y-axis direction in the present embodiment) of semiconductor laser elements 120 and 130 in the Y-axis direction.

As described above, n-wirings electrically connected to n-electrodes included in semiconductor laser elements 110 are electrically connected on base 22 by wires W11, W13 , and W15 on the backward end side of semiconductor laser elements 110.

P-wirings electrically connected to p-electrodes included in semiconductor laser elements 110 are electrically connected to n-wirings by wires W10, W12, and W14 on the backward end side of semiconductor laser elements 110.

In the present embodiment, array type semiconductor laser device 203 includes four each of wires W10 to W15. Wires W10 to W15 each include Au, for example.

As described above, wirings that electrically connect electrodes included in semiconductor laser array element 100 may be electrically connected by electrode films or by metal wires.

### Embodiment 3

Next, an array type semiconductor laser device according to Embodiment 3 is to be described. Note that in the description of the array type semiconductor laser device according to Embodiment 3, differences from the array type semiconductor laser devices according to Embodiments 1 and 2 are mainly described, and a description of similar structural elements to those of the array type semiconductor laser devices according to Embodiments 1 and 2 may be omitted while substantially the same reference signs are given thereto.

### Configuration

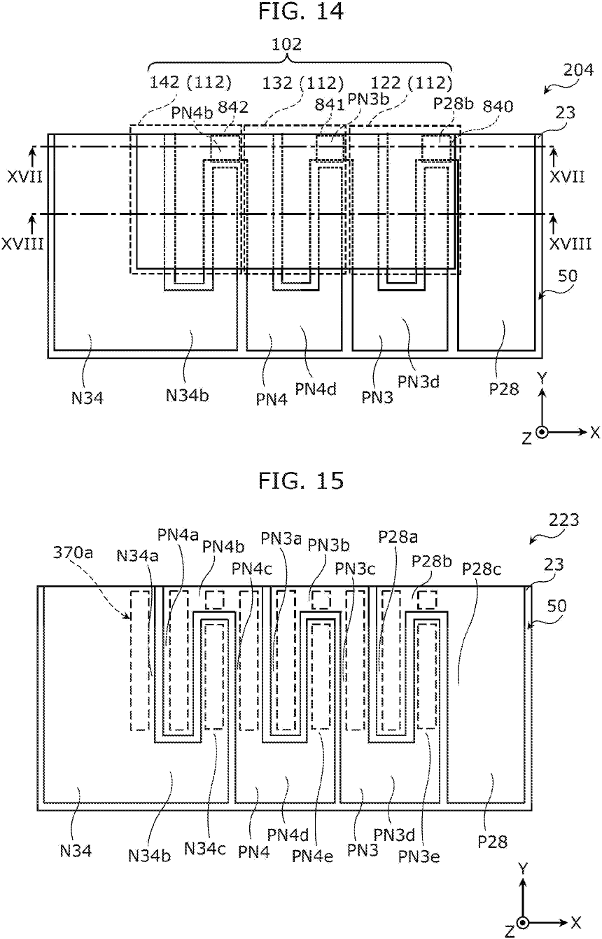

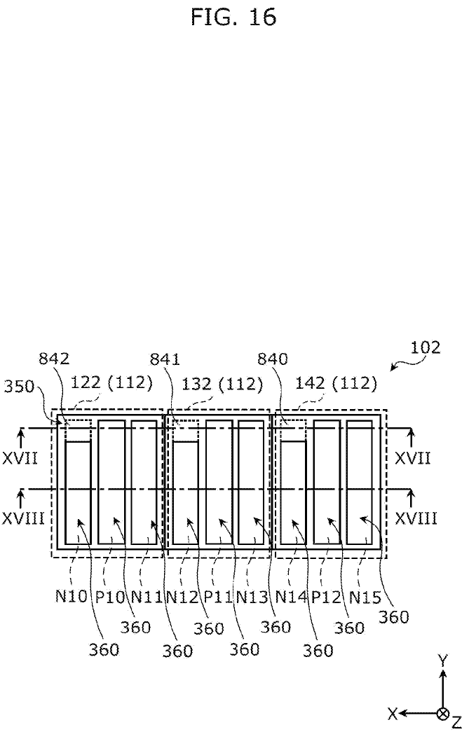

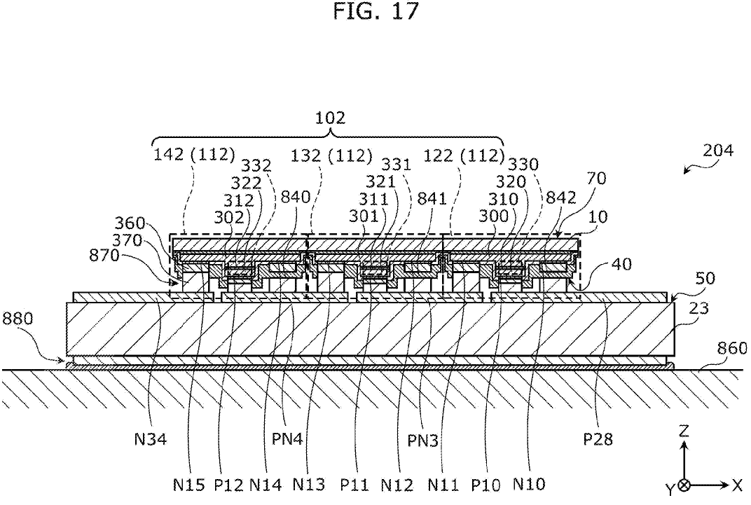

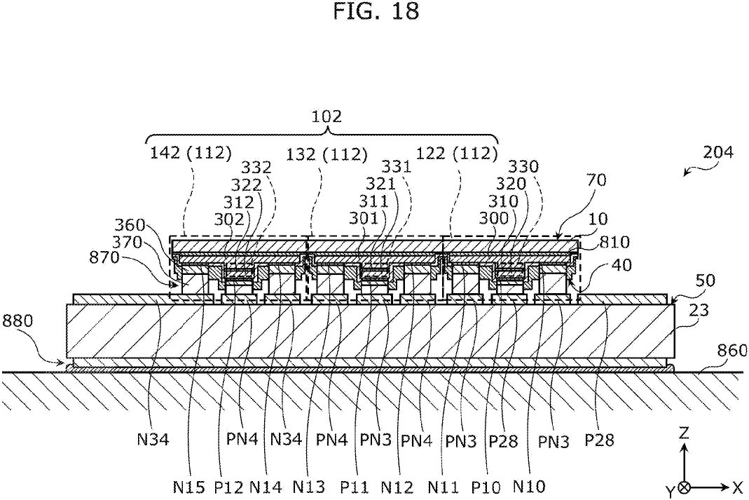

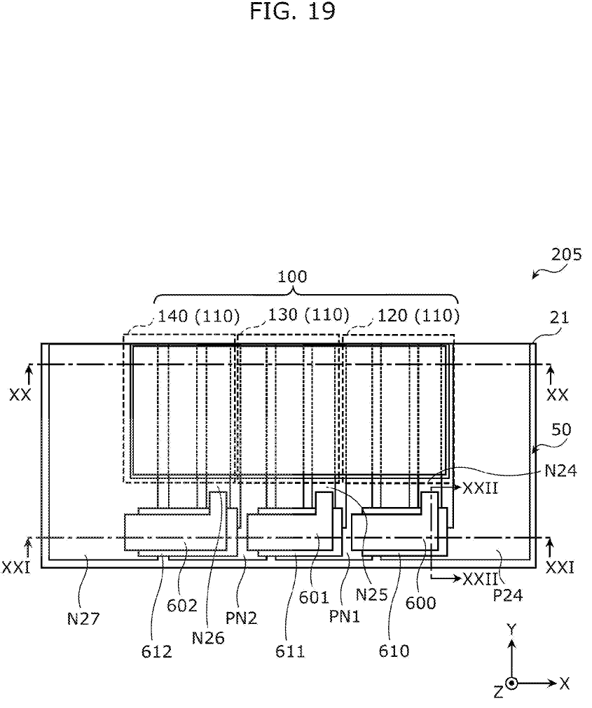

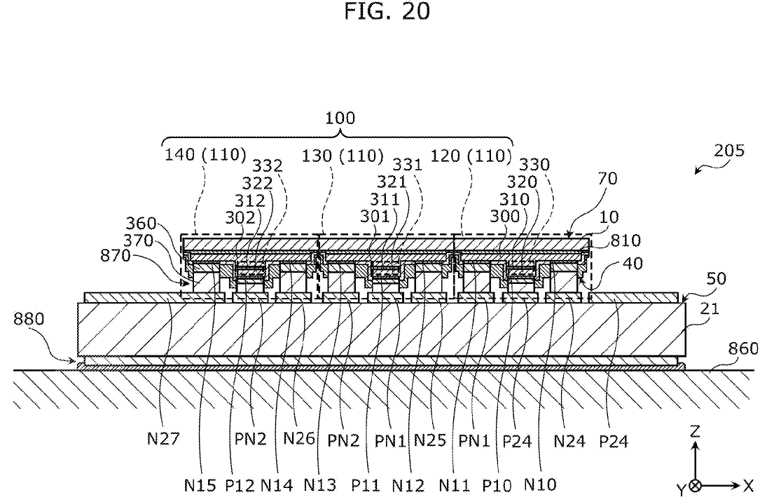

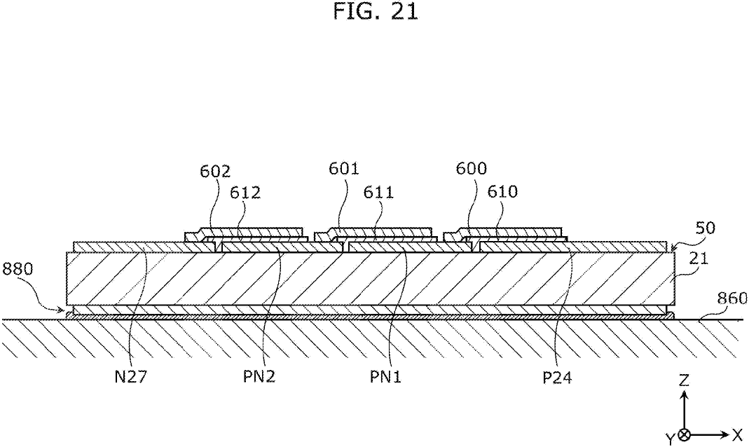

FIG. 14 is a top view illustrating array type semiconductor laser device 204 according to Embodiment 3. FIG. 15 is a top view illustrating submount 223 according to Embodiment 3. FIG. 16 is a bottom view illustrating semiconductor laser array element 102 according to Embodiment 3. FIG. 17 is a cross sectional view illustrating array type semiconductor laser device 204 according to Embodiment 3, which is taken along line XVII-XVII in FIG. 14. FIG. 18 is a cross sectional view illustrating array type semiconductor laser device 204 according to Embodiment 3, which is taken along line XVIII-XVIII in FIG. 14.

Array type semiconductor laser device 204 includes substrate 10, semiconductor laser array element 102, and base 23 (a first base).

Semiconductor laser array element 102 includes semiconductor laser elements 112. In the present embodiment, semiconductor laser array element 102 includes semiconductor laser element 122 (a first semiconductor laser element), semiconductor laser element 132 (a second semiconductor laser element), and semiconductor laser element 142 (a third semiconductor laser element).

Note that when a common description that applies to all semiconductor laser elements 122, 132, and 142 is given, semiconductor laser element 122, semiconductor laser element 132, and semiconductor laser element 142 may be simply referred to as semiconductor laser element(s) 112.

Array type semiconductor laser device 204 does not include wire lines.

As illustrated in FIG. 15, submount 223 has patterned wirings formed on base 23. Semiconductor laser array element 102 is disposed (mounted) on base 23. On second surface 50 of base 23, p-wiring P28 that is J-shaped, pn-wirings PN3 and PN4 that are N-shaped, and n-wiring N34 that is J-shaped are formed.

Straight portion P28a that is a shorter end portion of p-wiring P28 is electrically connected to p-electrode P10. Pn-wiring PN3 includes straight portion PN3e that is an end portion electrically connected to n-electrode N10, straight portion PN3c that is a center portion electrically connected to n-electrode N11, and straight portion PN3a that is an end portion electrically connected to p-electrode P11. Pn-wiring PN4 includes straight portion PN4e that is an end portion electrically connected to n-electrode N12, straight portion PN4c that is a center portion electrically connected to n-electrode N13, and straight portion PN4a that is an end portion electrically connected to p-electrode P12. N-wiring N34 includes straight portion N34c that is a shorter end portion electrically connected to n-electrode N14, and straight portion N34a that is a longer end portion electrically connected to n-electrode N15. Straight portion P28a is between straight portion PN3c and straight portion PN3e. Straight portion PN3a is between straight portion PN4c and straight portion PN4e. Straight portion PN4a is between straight portion N34a and straight portion N34c. Straight portion PN3e is between straight portion P28a and straight portion P28c. Straight portion PN4e is between straight portion PN3a and straight portion PN3c. Straight portion N34c is between straight portion PN4a and straight portion PN4c. Straight portion N34a, straight portion PN4a, straight portion N34c, straight portion PN4c, straight portion PN3a, straight portion PN4e, straight portion PN3c, straight portion P28a, straight portion PN3e, and straight portion P28c are aligned in this order parallel to one another in the X-axis direction.

As illustrated in FIG. 16, semiconductor laser array element 102 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction. Semiconductor laser element 122 includes n-electrode N10, p-electrode P10, and n-electrode N11. Semiconductor laser element 132 includes n-electrode N12, p-electrode P11, and n-electrode N13. Semiconductor laser element 142 includes n-electrode N14, p-electrode P12, and n-electrode N15. Note that when semiconductor laser array element 102 is viewed from the undersurface, n-electrode N15, p-electrode P12, n-electrode N14, n-electrode N13, p-electrode P11, n-electrode N12, n-electrode N11, p-electrode P10, and n-electrode N10 are each formed into a quadrilateral shape that is substantially the same as the shape of corresponding wiring electrode 360 thereof, and are covered with corresponding wiring electrodes 360 thereof.

Here, semiconductor laser array element 102 further includes protective films 840, 841, and 842, in addition to the configuration of semiconductor laser array element 100.

Protective films 840, 841, and 842 are membrane-shaped insulating films having electrically insulating properties.

Protective film 842 is formed over a portion of wiring electrode 360 and a portion of n-electrode N10. Specifically, protective film 842 is provided in a position that overlaps connection portion P28b of p-wiring P28 (a portion that connects straight portion P28a and straight portion P28c) in the top view, at end portions on the emission side (end portions on the positive side of the Y-axis direction) of wiring electrode 360 and n-electrode N10 that are included in semiconductor laser element 122.

Accordingly, p-wiring P28 is electrically insulated from wiring electrode 360 and n-electrode N10, and pn-wiring PN3 is electrically connected to wiring electrode 360 and n-electrode N10.

Protective film 841 is formed over a portion of wiring electrode 360 and a portion of n-electrode N12. Specifically, protective film 841 is provided in a position that overlaps connection portion PN3b of pn-wiring PN3 (a portion that connects straight portion PN3a and straight portion PN3c) in the top view, at end portions on the emission side (end portions on the positive side of the Y-axis direction) of wiring electrode 360 and n-electrode N12 that are included in semiconductor laser element 132.

Accordingly, pn-wiring PN3 is electrically insulated from wiring electrode 360 and n-electrode N12, and pn-wiring PN4 is electrically connected to wiring electrode 360 and n-electrode N12.

Protective film 840 is formed in a portion of wiring electrode 360 and a portion of n-electrode N14. Specifically, protective film 840 is provided in a position that overlaps connection portion PN4b of pn-wiring PN4 (a portion that connects straight portion PN4a and straight portion PN4c) in the top view, at end portions on the emission side (end portions on the positive side of the Y-axis direction) of wiring electrode 360 and n-electrode N14 that are included in semiconductor laser element 142.

Connection portion PN3d of pn-wiring PN3 that connects straight portion PN3c and straight portion PN3e, connection portion PN4d of pn-wiring PN4 that connects straight portion PN4c and straight portion PN4e, and connection portion N34b of n-wiring N34 that connects straight portion N34a and straight portion N34c are exposed from the backward ends (in the present embodiment, end portions on the negative side of the Y-axis direction) of semiconductor laser elements 122 and 132.

Accordingly, pn-wiring PN4 is electrically insulated from wiring electrode 360 and n-electrode N14, and n-wiring N34 and n-electrode N14 are electrically connected to each other.

Portions of the undersurface of semiconductor laser array element 102 where wiring electrodes 360 are not exposed are covered with protective film 350. Protective films 840, 841, and 842 are formed integrally with and using the same material as that of protective film 350.

As illustrated in FIG. 15, connection layer 370 is formed in each of connection regions 370a indicated by the dashed lines on the patterned wirings. Connection layer 370 formed at connection portion P28b, connection layer 370 formed at connection portion PN3b, and connection layer 370 formed at connection portion PN4b are joined to protective film 840, protective film 841, and protective film 842, respectively.

According to the above configuration, without using metal wires such as wires, power can be supplied to semiconductor laser element 112 at appropriate positions via the patterned wirings formed on the top surface (second surface 50) of base 23.

### Variation

Next, a variation of the array type semiconductor laser device according to Embodiment 3 is to be described. Note that in the variation described in the following, differences from the elements included in the array type semiconductor laser device according to Embodiment 3 are to be mainly described, and a description of the same elements may be simplified or omitted.

Note that the layout of the patterned wirings formed on second surface 50 of base 21 included in array type semiconductor laser device 205 is the same as that on base 21 included in array type semiconductor laser device 202 described above. In array type semiconductor laser device 205, the patterned wirings are electrically connected further by connection films.

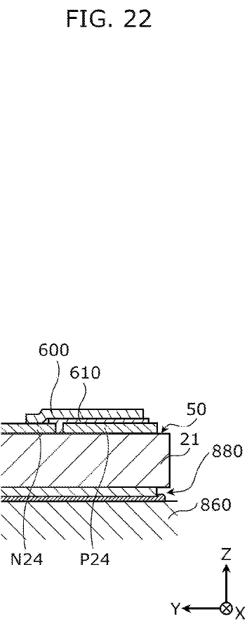

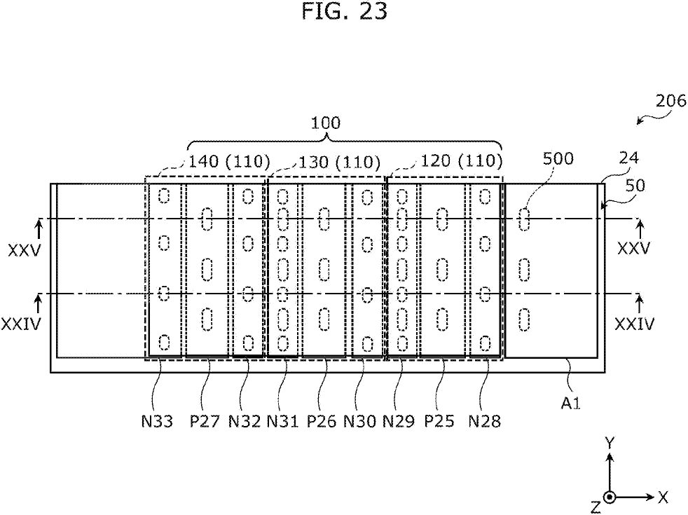

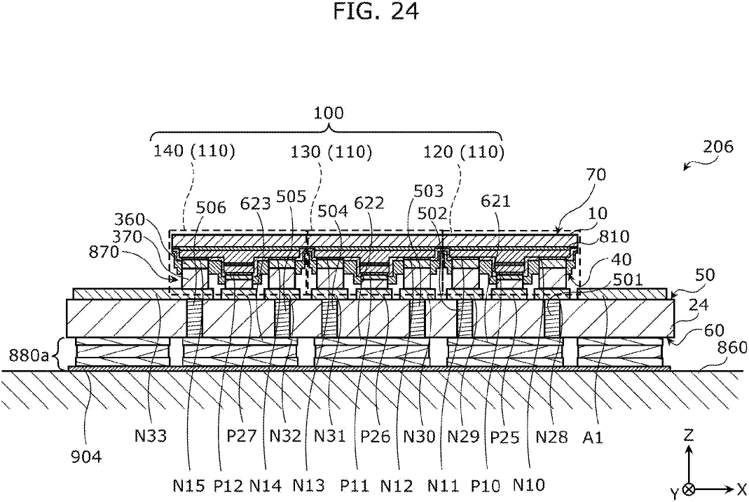

FIG. 19 is a top view illustrating array type semiconductor laser device 205 according to Variation 1 of Embodiment 3. FIG. 20 is a cross sectional view illustrating array type semiconductor laser device 205 according to Variation 1 of Embodiment 3, which is taken along line XX-XX in FIG. 19. FIG. 21 is a cross sectional view illustrating insulating films 610 to 612 and connection films 600 to 602 according to Variation 1 of Embodiment 3, which is taken along line XXI-XXI in FIG. 19. FIG. 22 is a cross sectional view illustrating insulating film 610 and connection film 600 according to Variation 1 of Embodiment 3, which is taken along line XXII-XXII in FIG. 19.

Array type semiconductor laser device 205 includes substrate 10, semiconductor laser array element 100, and base 21.

Note that semiconductor laser array element 100 included in array type semiconductor laser device 205 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction, as illustrated in FIG. 3.

On second surface 50 of base 21, p-wiring P24, n-wirings N24 to N27, and pn-wirings PN1 and PN2 are formed, as illustrated in FIG. 12.

Membrane-shaped insulating films 610 to 612 are formed on the top surfaces of the patterned wirings formed on second surface 50 of base 21. Membrane-shaped conductive connection films 600 to 602 are formed on the top surfaces of insulating films 610 to 612.

For example, connection film 600 electrically connects n-wiring N24 and pn-wiring PN1. Connection film 600 is disposed above p-wiring P24 with insulating film 610 being provided therebetween. Accordingly, connection film 600 is electrically insulated from p-wiring P24.

For example, connection film 601 electrically connects n-wiring N25 and pn-wiring PN2. Connection film 601 is disposed above pn-wiring PN1 with insulating film 611 being provided therebetween. Accordingly, connection film 601 is electrically insulated from pn-wiring PN1.

For example, connection film 602 electrically connects n-wiring N26 and n-wiring N27. Connection film 602 is disposed above pn-wiring PN2 with insulating film 612 being provided therebetween. Accordingly, connection film 602 is electrically insulated from pn-wiring PN2.

According to this variation, without using metal wires such as wires W7 to W9 as in array type semiconductor laser device 202, power can be supplied to semiconductor laser array element 100 via the membrane-shaped conductive connection films formed on second surface 50 of base 21.

### Embodiment 4

Next, an array type semiconductor laser device according to Embodiment 4 is to be described. Note that in the description of the array type semiconductor laser device according to Embodiment 4, differences from the array type semiconductor laser devices according to Embodiments 1 to 3 are mainly described, and a description of similar structural elements to those of the array type semiconductor laser devices according to Embodiments 1 to 3 may be omitted while substantially the same reference signs are given thereto.

Semiconductor laser array element 100 in Embodiment 4 and each variation of Embodiment 4 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction, as illustrated in FIG. 3.

### Configuration

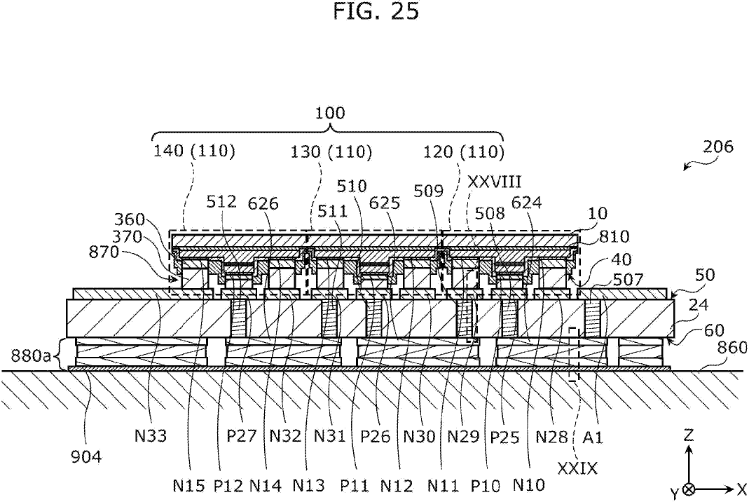

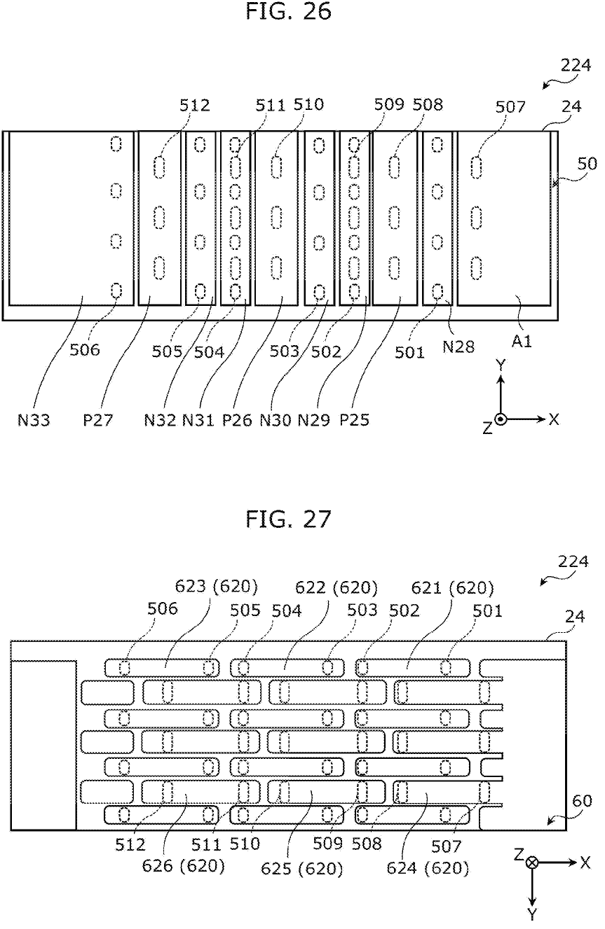

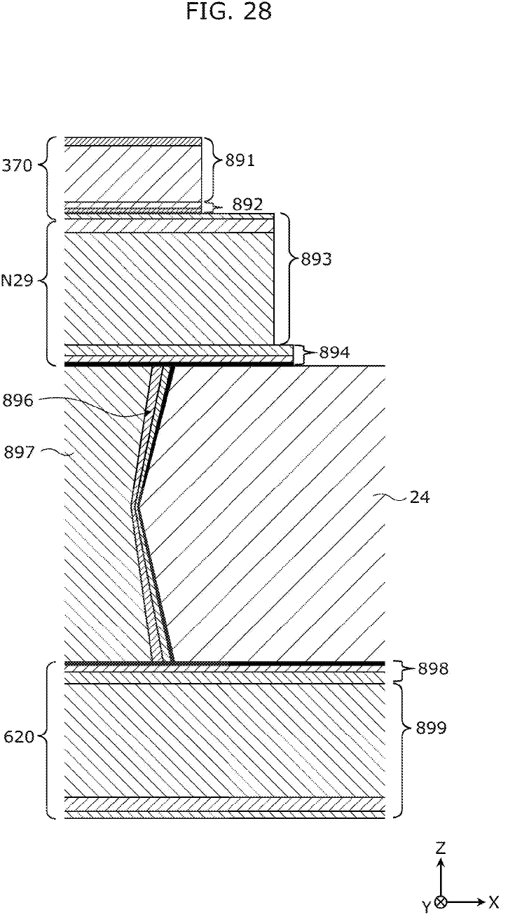

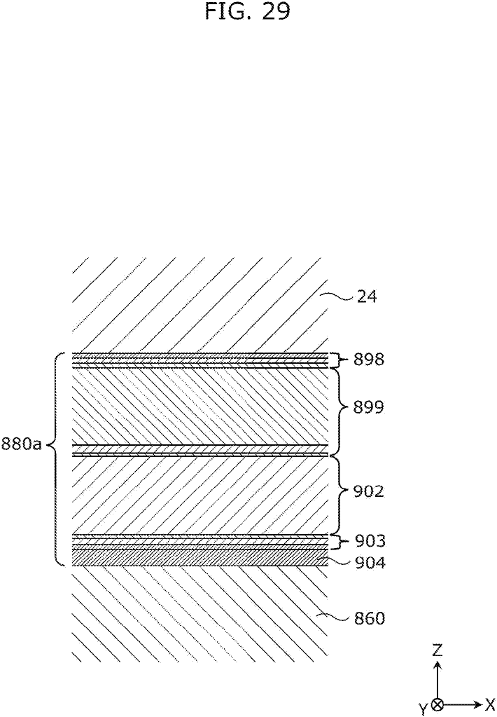

FIG. 23 is a top view illustrating array type semiconductor laser device 206 according to Embodiment 4. FIG. 24 is a cross sectional view illustrating array type semiconductor laser device 206 according to Embodiment 4, which is taken along line XXIV-XXIV in FIG. 23. FIG. 25 is a cross sectional view illustrating array type semiconductor laser device 206 according to Embodiment 4, which is taken along line XXV-XXV in FIG. 23. FIG. 26 is a top view illustrating submount 224 according to Embodiment 4. FIG. 27 is a bottom view illustrating submount 224 according to Embodiment 4.

Array type semiconductor laser device 206 includes substrate 10, semiconductor laser array element 100, and submount 224 (a first base). Submount 224 has a wiring pattern formed on and vias in base 24.

Semiconductor laser array element 100 is mounted on base 24. On second surface 50 of base 24, a wiring pattern (wiring A1, p-wirings P25 to P27, and n-wirings N28 to N33) are formed in the same layout as that on base 22.

Base 24 includes plural vias 500.

Note that in the following, when a common description that applies to the vias included in the array type semiconductor laser device is given, the vias may be simply referred to as via(s) 500.

Vias 500 are conductive electrodes that pass through base 24 in a direction orthogonal to second surface 50. Specifically, via 500 electrically connects patterned wirings formed on second surface 50 of base 24 and patterned wirings formed on third surface 60 that is the undersurface of base 24 and is located on a side opposite second surface 50. Thus, via 500 passes through from second surface 50 to third surface 60.

Each of vias 501 to 512 is formed with a plurality of vias, and each set of vias is aligned in the Y-axis direction. For example, vias 502 and vias 509 are alternately aligned in the Y-axis direction. For example, vias 504 and vias 511 are alternately aligned in the Y-axis direction.

Vias 500 are electrically connected to one another by respective conductive films 620. Note that when a common description that applies to all conductive films 621 to 626 is given, conductive films 621 to 626 are also simply referred to as conductive film(s) 620.

Conductive film 620 is an electrically conductive film formed on third surface 60 of base 24. Conductive films 620 are formed on third surface 60 of base 24. Specifically, conductive films 621 to 626 are formed on third surface 60 of base 24.

For example, conductive films 621 electrically connect vias 501 and vias 502. Thus, conductive films 621 electrically connect n-electrode N10 and n-electrode N11 of semiconductor laser element 120. For example, conductive films 622 electrically connect vias 503 and vias 504. Thus, conductive films 622 electrically connect n-electrode N12 and n-electrode N13 of semiconductor laser element 130. For example, conductive films 623 electrically connect vias 505 and vias 506. Thus, conductive films 623 electrically connect n-electrode N14 and n-electrode N15 of semiconductor laser element 140. For example, conductive films 624 electrically connect vias 507 and vias 508. Thus, conductive films 624 electrically connect p-electrode P10 and wiring A1 of semiconductor laser element 120. For example, conductive films 625 electrically connect vias 509 and vias 510. Thus, conductive films 625 electrically connect p-electrode P11 of semiconductor laser element 130 and n-electrode N11 of semiconductor laser element 120. For example, conductive films 626 electrically connect vias 511 and vias 512. Thus, conductive films 626 electrically connect p-electrode P12 of semiconductor laser element 140 and n-electrode N13 of semiconductor laser element 130.

Conductive films 621 to 626 extend in the X-axis direction.

For example, conductive films 624 and conductive films 621 are alternately aligned in the Y-axis direction. For example, conductive films 621 and conductive films 625 are alternately aligned in the Y-axis direction. For example, conductive films 625 and conductive films 622 are alternately aligned in the Y-axis direction. For example, conductive films 622 and conductive films 626 are alternately aligned in the Y-axis direction. For example, conductive films 626 and conductive films 623 are alternately aligned in the Y-axis direction.

Conductive film 623, conductive film 622, and conductive film 621 in each set are aligned in a straight line in the X-axis direction. Conductive film 626, conductive film 625, and conductive film 624 in each set are aligned in a straight line in the X-axis direction.

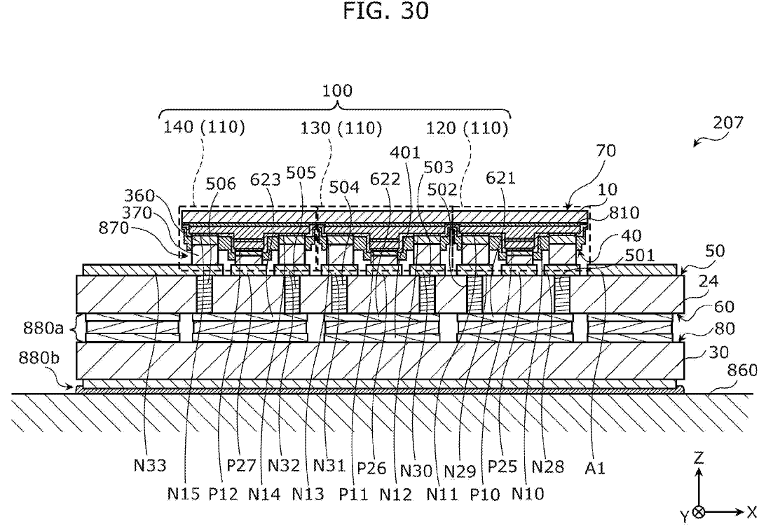

FIG. 28 is an enlarged view illustrating a region surrounded by broken line XXVIII in FIG. 25.

Above the top surface of via 500, connection layer 370 includes solder layer 891 and solder-forming underlayer 892 in the order from the upper layer side.

A patterned wiring (for example, n-wiring N29) includes upper conductive layer 893 and underlayer 894.

In a through-hole in base 24 in the vicinity of via 500, via underlayer 896 and metal plug 897 are formed. Below the undersurface of via 500, conductive film 620 includes underlayer 898 and lower conductive layer 899.

Solder layer 891 includes an AuSn solder layer and an Au layer in this order from the lower layer side, for example.

Solder-forming underlayer 892 includes, for example, a Ti layer and a Pt layer in the order from the lower layer side.

Upper conductive layer 893 includes, for example, a Cu layer, an Ni layer, and a Pt layer in the order from the lower layer side. Upper conductive layer 893 is formed by plating.

Underlayer 894 is a base layer for forming upper conductive layer 893 by plating, and includes, for example, a Ti layer, a Pt layer, and an Au layer in the order from the lower layer side.

Base 24 is an insulating substrate that includes at least one of AlN or SiC, for example.

Via underlayer 896 includes, for example, a Ti layer, a Pt layer, and an Au layer in the order from the lateral wall side (the positive side of the X axis direction) of via 500.

Metal plug 897 is formed by Cu plating, for example.

For example, underlayer 898 is a base layer for forming metal plug 897 by plating, and includes an Au layer, a Pt layer, and a Ti layer in the order from the lower layer side.

Lower conductive layer 899 includes an Au layer, an Ni layer, and a Cu layer in the order from the lower layer side, for example.

Base 24 is placed above heat sink 860 with conductive films 620 and joining layer 880a being provided therebetween.

FIG. 29 is an enlarged view illustrating a region surrounded by broken line XXIX in FIG. 25.

Joining layer 880a includes underlayer 898, lower conductive layer 899, solder layer 902, upper metal layer 903, and insulating film 904 in the order from the upper layer side.

For example, underlayer 898 includes an Au layer, a Pt layer, and a Ti layer in the order from the lower layer side, and is a base layer for forming lower conductive layer 899 by plating.

For example, lower conductive layer 899 includes an Au layer, an Ni layer, and a Cu layer in the order from the lower layer side. Lower conductive layer 899 is formed by plating.

Solder layer 902 includes an SnAgCu-based low-melting solder material, for example.

Upper metal layer 903 includes, for example, a Ti layer, a Pt layer, and an Au layer in the order from the lower layer side.

Insulating film 904 includes an electrically insulating and highly heat conductive ceramic material such as AlN, for example.

### Advantageous Effects and Others

As described above, in array type semiconductor laser device 206 according to Embodiment 4, base 24 has third surface 60 located on a side opposite second surface 50, a first through-hole (in which via 510 is formed) that passes through from second surface 50 to third surface 60, and a second through-hole (in which via 509 is formed) that passes through from second surface 50 to third surface 60. The first conductor includes a third conductor (via 510), a fourth conductor (via 509), and a third conductive film (conductive film 625). The third conductive film (conductive film 625) is formed on third surface 60. The third conductor (via 510) is formed in the first through-hole, and electrically connects p-electrode P11 of semiconductor laser element 130 and the third conductive film (conductive film 625). The fourth conductor (via 509) is formed in the second through-hole, and electrically connects n-electrode N11 of semiconductor laser element 120 and the third conductive film (conductive film 625).

According to this, it is sufficient if the length of base 24 in the Y-axis direction is approximately the length of a resonator of semiconductor laser array element 100, and the area of base 24 (the area of second surface 50) can be decreased as compared with the case in which p-electrode P11 of semiconductor laser element 130 and n-electrode N11 of semiconductor laser element 120 are connected in portions of the first conductive film that are exposed from the backward ends of semiconductor laser element 120 and semiconductor laser element 130.

For example, a plurality of third conductors are formed in the Y-axis direction, and a plurality of fourth conductors are formed in the Y-axis direction.

According to this, current can be caused to flow through p-electrode P11 and n-electrode N11 uniformly in the first direction. For example, when a single first conductor is provided, there is a problem that most of the current flows through p-electrode P11 and n-electrode N11 in the vicinity of the first conductor. However, such a configuration can reduce the occurrence of the problem that most of the current flows through p-electrode P11 and n-electrode N11 in the vicinity of the first conductor, and can cause current to flow through p-electrode P11 and n-electrode N11 uniformly in the first direction.

Furthermore, both the plurality of third conductors (vias 510) and the plurality of fourth conductors (vias 509) are formed in the Y-axis direction, and a total cross-sectional area of the third conductors and a total cross-sectional area of the fourth conductors are increased. Thus, the rated current value can be increased.

According to this, the area of p-electrode P11 and n-electrode N11 of semiconductor laser array element 100 can be decreased, and the area of semiconductor laser array element 100 and the area of base 24 can be decreased.

For example, base 24 has third surface 60 located on a side opposite second surface 50, a fifth through-hole (in which via 503 is formed) that passes through from second surface 50 to third surface 60, and a sixth through-hole (in which via 504 is formed) that passes through from second surface 50 to third surface 60. The second conductor includes a sixth conductor (via 503), a seventh conductor (via 504), and a fourth conductive film (conductive film 622). The fourth conductive film (conductive film 622) is formed on third surface 60. The sixth conductor (via 503) is formed in the fifth through-hole, and electrically connects n-electrode N12 and the fourth conductive film (conductive film 622). The seventh conductor (via 504) is formed in the sixth through-hole, and electrically connects n-electrode N13 and the fourth conductive film (conductive film 622).

According to this, it is sufficient if the length of base 24 in the Y-axis direction is approximately the length of a resonator of semiconductor laser array element 100, and the area of base 24 can be decreased, as compared with the case in which n-electrode N12 and n-electrode N13 are connected in portions of wirings exposed from the backward ends of semiconductor laser element 120 and semiconductor laser element 130.

For example, a plurality of sixth conductors are formed in the Y-axis direction, and a plurality of seventh conductors are formed in the Y-axis direction.

According to this, current can be caused to flow through n-electrode N12 and n-electrode N13 uniformly in the first direction. For example, when a single second conductor is provided, there is a problem that most of the current flows through n-electrode N12 and n-electrode N13 in the vicinity of the second conductor. However, such a configuration can reduce the occurrence of the problem that most of the current flows through n-electrode N12 and n-electrode N13 in the vicinity of the second conductor, and can cause current to flow through n-electrode N12 and n-electrode N13 uniformly in the first direction.

Furthermore, the plurality of sixth conductors (vias 503) and the plurality of seventh conductors (vias 504) are formed, each set of the conductors is aligned in the Y-axis direction, and the total cross-sectional area of the sixth conductors and the total cross-sectional area of the seventh conductors (the area of cross sections along the XY plane, for example) are increased. Thus, the rated current value can be increased.

According to this, the area of n-electrode N12 and n-electrode N13 of semiconductor laser array element 100 can be decreased, and the area of semiconductor laser array element 100 and the area of base 24 can be decreased.

For example, as described above, base 24 includes third surface 60 located on a side opposite second surface 50, a first through-hole (in which via 510 is formed) that passes through from second surface 50 to third surface 60, and a second through-hole (in which via 509 is formed) that passes through from second surface 50 to third surface 60. The first conductor includes the third conductor (via 510), the fourth conductor (via 509), and the third conductive film (conductive film 625). The third conductive film (conductive film 625) is formed on third surface 60. The third conductive film (conductive film 625) is formed on third surface 60. The third conductor (via 510) is formed in the third through-hole, and electrically connects p-electrode P11 and the third conductive film (conductive film 625). The fourth conductor (via 509) is formed in the second through-hole, and electrically connects n-electrode N11 and the third conductive film (conductive film 625). Base 24 further includes a fifth through-hole (in which via 503 is formed) that passes through from second surface 50 to third surface 60, and a sixth through-hole (in which via 504 is formed) that passes through from second surface 50 to third surface 60. The second conductor includes a sixth conductor (via 503), a seventh conductor (via 504), and a fourth conductive film (conductive film 622). The fourth conductive film (conductive film 622) is formed on third surface 60. The sixth conductor (via 503) is formed in the fifth through-hole, and electrically connects n-electrode N12 and the fourth conductive film (conductive film 622). The seventh conductor (via 504) is formed in the sixth through-hole, and electrically connects n-electrode N13 and the fourth conductive film (conductive film 622).

According to this, it is sufficient if the length of base 24 in the Y-axis direction is approximately the length of a resonator of semiconductor laser array element 100, and the area of base 24 can be decreased, as compared with the case in which p-electrode P11 and n-electrode N11 are connected and n-electrode N12 and n-electrode N13 are connected in portions of wirings exposed from the backward ends of semiconductor laser element 120 and semiconductor laser element 130.

For example, as described above, a plurality of third conductors are formed in the Y-axis direction, a plurality of fourth conductors are formed in the Y-axis direction, a plurality of sixth conductors are formed in the Y-axis direction, a plurality of seventh conductors are formed in the Y-axis direction, a plurality of third conductive films (conductive films 625) are formed in the Y-axis direction, and a plurality of fourth conductive films (conductive films 622) are formed in the Y-axis direction. Here, for example, the third conductive films (conductive films 625) and the fourth conductive films (conductive films 622) are alternately formed in the Y-axis direction.

According to this, current can be caused to flow through p-electrode P11 and n-electrode N11 uniformly in the first direction. Furthermore, current can be caused to flow through n-electrode N12 and n-electrode N13 uniformly in the first direction. For example, when a single first conductor is provided, there is a problem that most of the current flows through p-electrode P11 and n-electrode N11 in the vicinity of the first conductor. When a single second conductor is provided, there is a problem that most of the current flows through n-electrode N12 and n-electrode N13 in the vicinity of the second conductor. However, such a configuration reduces the occurrence of these problems, and allows current to flow uniformly in the first direction through p-electrode P11, n-electrode N11, n-electrode N12, and n-electrode N13.

Furthermore, the plurality of third conductors, the plurality of fourth conductors, the plurality of sixth conductors, and the plurality of seventh conductors are formed, each set of the conductors is aligned in the Y-axis direction, and a total cross-sectional area of the third conductors, a total cross-sectional area of the fourth conductors, a total cross-sectional area of the sixth conductors, and a total cross-sectional area of the seventh conductors (the areas of cross sections along the XY plane, for example) are increased. Thus, the rated current value can be increased.

According to this, the area of each of p-electrode P11, n-electrode N11, n-electrode N12, and n-electrode N13 of semiconductor laser array element 100 can be decreased, and the area of semiconductor laser array element 100 and the area of base 24 can be decreased.

### Variation

Next, a variation of the array type semiconductor laser device according to Embodiment 4 is to be described. Note that in the variation described in the following, differences from the elements included in the array type semiconductor laser device according to Embodiment 4 are to be mainly described, and a description of the same elements may be simplified or omitted.

### Variation 1

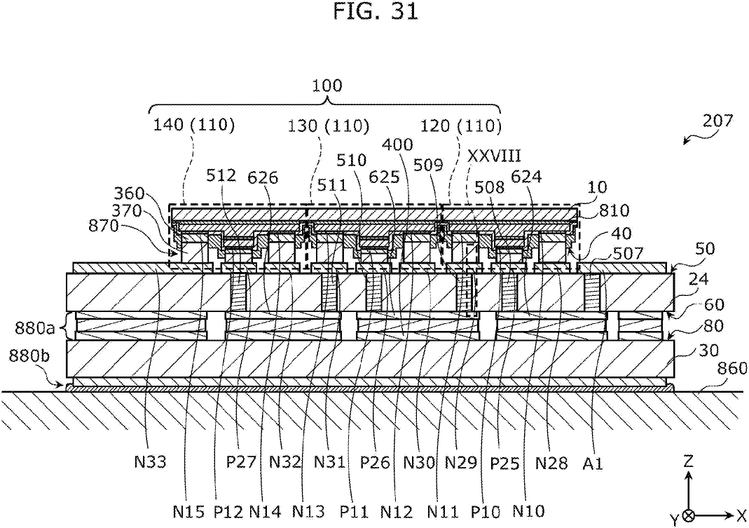

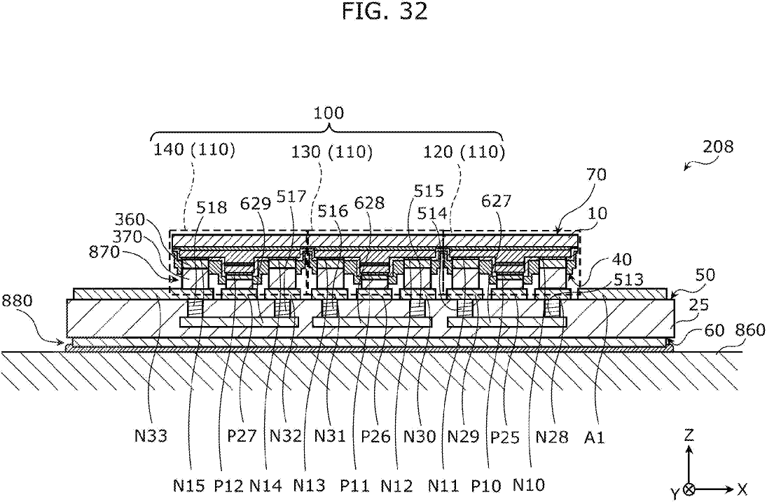

FIG. 30 and FIG. 31 are cross sectional views each illustrating array type semiconductor laser device 207 according to Variation 1 of Embodiment 4. Specifically, FIG. 30 is a cross sectional view of array type semiconductor laser device 207 according to Variation 1 of Embodiment 4, which includes a second conductor. FIG. 31 is a cross sectional view of the array type semiconductor laser device according to Variation 1 of Embodiment 4, which includes a first conductor. Note that FIG. 30 illustrates a cross section corresponding to FIG. 24, whereas FIG. 31 illustrates a cross section corresponding to FIG. 25.

Array type semiconductor laser device 207 further includes base 30 (a second base) and joining layer 880b, in addition to the configuration of array type semiconductor laser device 206. Base 30 is an insulating substrate that includes at least one of AlN or SiC, for example.

Base 24 (a first base) is placed above base 30 with joining layer 880a being provided therebetween. Base 30 is placed above heat sink 860 with joining layer 880b being provided therebetween.

Base 30 includes fifth surface 80 to which base 24 is connected. Stated differently, third surface 60 of base 24 is joined to fifth surface 80 of base 30.

Metal film 400 (a first metal film) is formed on fifth surface 80, across from conductive film 625 (a third conductive film). Metal film 401 (a second metal film) is formed on fifth surface 80, across from conductive film 622 (a fourth conductive film).

Metal films 400 and 401 are portions of joining layer 880a, for example. Note that as illustrated in FIG. 30 and FIG. 31, joining layer 880a may not include insulating film 904 illustrated in FIG. 29, for example.

As described above, for example, third surface 60 is joined to fifth surface 80 of base 30. In this case, for example, a first metal film (metal film 400) is formed, on fifth surface 80, across from a third conductive film (conductive film 625), and a second metal film (metal film 401) is formed, on fifth surface 80, across from a fourth conductive film (conductive film 622).

According to this, while conductive film 625 is electrically insulated from conductive film 622, heat generated in semiconductor laser array element 100 can be efficiently dissipated from base 24 to base 30, via conductive films 625 and 622 and metal films 400 and 401.

### Variation 2

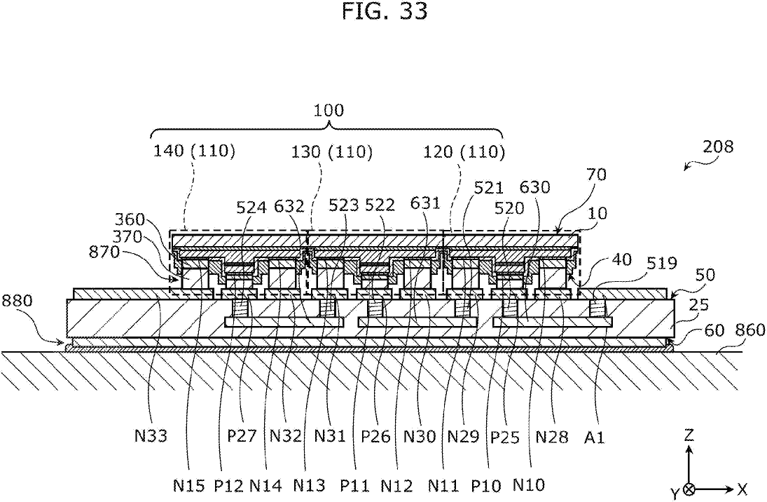

FIG. 32 and FIG. 33 are cross sectional views each illustrating array type semiconductor laser device 208 according to Variation 2 of Embodiment 4. Specifically, FIG. 32 is a cross sectional view of array type semiconductor laser device 208 according to Variation 2 of Embodiment 4, which includes a second conductor. FIG. 33 is a cross sectional view of array type semiconductor laser device 208 according to Variation 2 of Embodiment 4, which includes a first conductor. Note that FIG. 32 illustrates a cross section corresponding to FIG. 24, whereas FIG. 33 illustrates a cross section corresponding to FIG. 25.

In array type semiconductor laser device 208, conductive films 627 to 632 are electrically conductive films for electrically connecting vias 500, are formed inside base 25 (a first base). Specifically, array type semiconductor laser device 208 includes vias 513 to 524 that do not completely pass through base 25 from second surface 50 to third surface 60 and one or more of patterned wirings formed on second surface 50 of base 25 are electrically connected through the inside of base 25 by conductive films 627 to 632. Conductive films 627 to 632 extend inside of base 25 in the X-axis direction.

For example, conductive film 627 electrically connects via 513 and via 514. For example, conductive film 628 electrically connects via 515 and via 516. For example, conductive film 629 electrically connects via 517 and via 518. For example, conductive film 630 electrically connects via 519 and via 520. For example, conductive film 631 electrically connects via 521 and via 522. For example, conductive film 632 electrically connects via 523 and via 524.

According to these, for example, n-electrode N11 and p-electrode P11 are electrically connected through vias 521 and 522 and conductive film 631. For example, n-electrode N12 and n-electrode N13 are electrically connected through vias 515 and 516 and conductive film 628.

For example, array type semiconductor laser device 208 can insulate conductive films 627 to 632, by using an insulating ceramic material such as SiC and/or AlN for base 25.

Base 25 is placed above heat sink 860 with joining layer 880 being provided therebetween.

As described above, for example, base 25 includes a fifth conductor (conductive film 631) located inside of base 25, a third through-hole (in which via 522 is formed) that passes through from second surface 50 to a fifth conductor (conductive film 631), and a fourth through-hole (in which via 521 is formed) that passes through from second surface 50 to the fifth conductor. In this case, for example, the first conductor includes a third conductor (via 522), a fourth conductor (via 521), and a fifth conductor (conductive film 631). In this case, for example, the third conductor (via 522) is formed in the third through-hole, and electrically connects p-electrode P11 and the fifth conductor (conductive film 631). In this case, for example, the fourth conductor (via 521) is formed in the fourth through-hole, and electrically connects n-electrode N11 and the fifth conductor (conductive film 631).

According to this, it is sufficient if the length of base 25 in the Y-axis direction is approximately the length of a resonator of semiconductor laser array element 100, and the area of base 25 can be decreased, as compared with the case in which p-electrode P11 and n-electrode N11 are connected in portions of patterned wirings exposed from the backward ends of semiconductor laser elements 120 and 130.

For example, base 25 includes an eighth conductor (conductive film 628) located inside of base 25, a seventh through-hole (in which via 515 is formed) that passes through from second surface 50 to the eighth conductor (conductive film 628), and an eighth through-hole (in which via 516 is formed) that passes through from second surface 50 to the eighth conductor (conductive film 628). In this case, for example, the second conductor includes a ninth conductor (via 515), a tenth conductor (via 516), and the eighth conductor (conductive film 628). The ninth conductor (via 515) is formed in the seventh through-hole, and electrically connects n-electrode N12 and the eighth conductor (conductive film 628). In this case, for example, the tenth conductor (via 516) is formed in the second through-hole, and electrically connects n-electrode N13 and the eighth conductor (conductive film 628).

According to this, it is sufficient if the length of base 25 in the Y-axis direction is approximately the length of a resonator of semiconductor laser array element 100, and the area of base 25 can be decreased, as compared with the case in which n-electrode N12 and n-electrode N13 are connected in portions of patterned wirings exposed from the backward ends of semiconductor laser elements 120 and 130.

### Variation 3

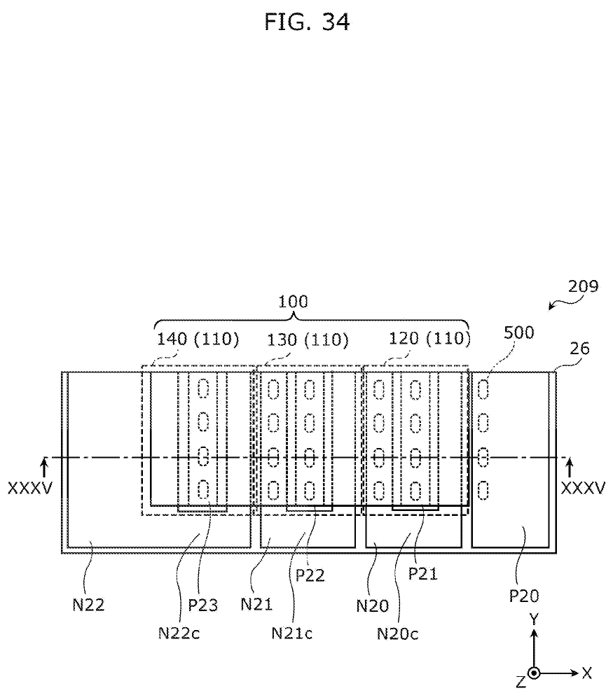

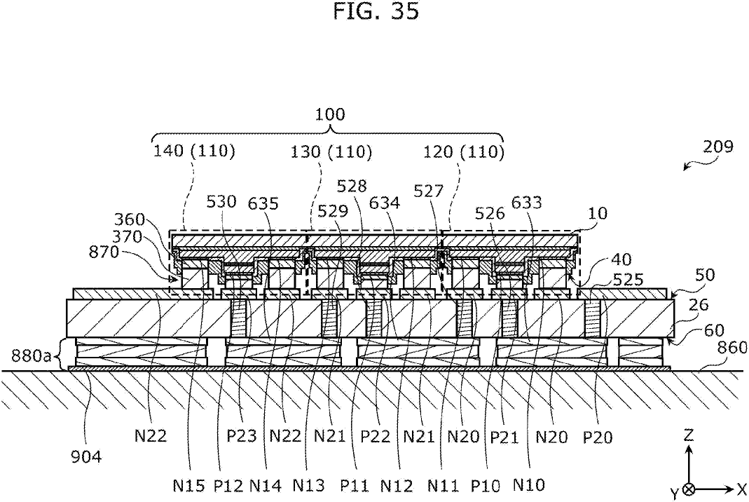

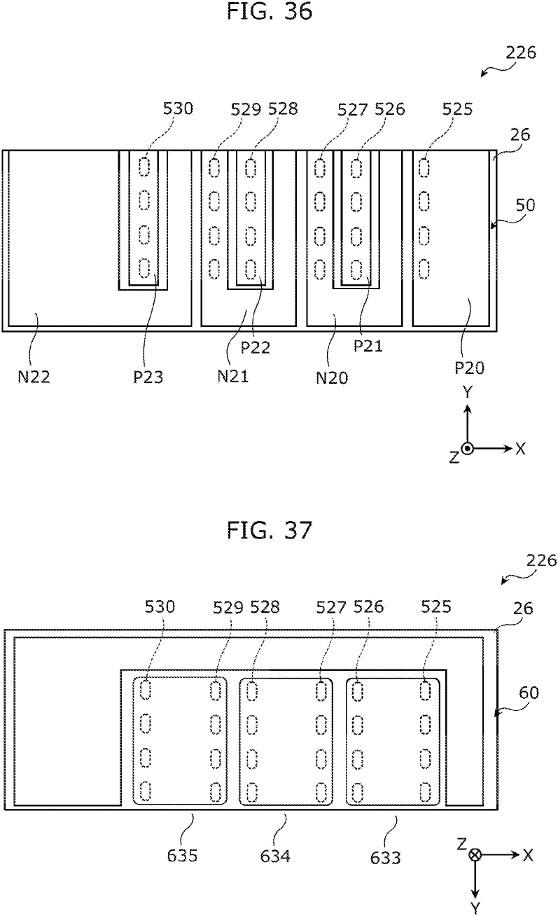

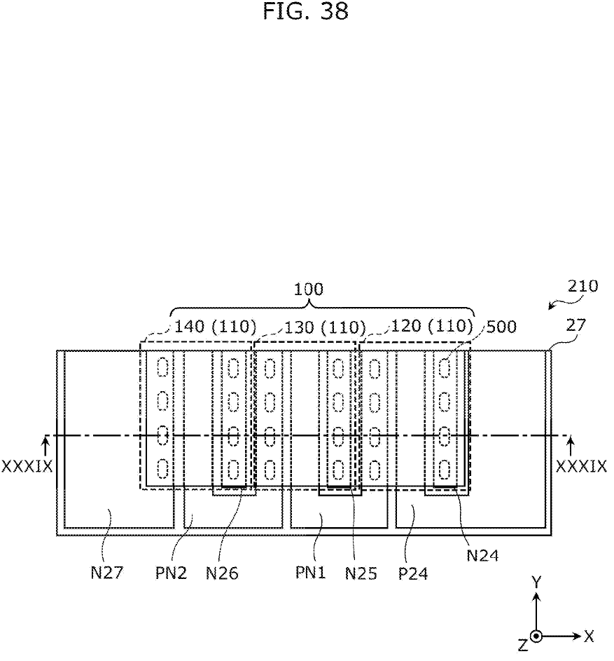

FIG. 34 is a top view illustrating array type semiconductor laser device 209 according to Variation 3 of Embodiment 4. FIG. 35 is a cross sectional view illustrating array type semiconductor laser device 209 according to Variation 3 of Embodiment 4, which is taken along line XXXV-XXXV in FIG. 34. FIG. 36 is a top view illustrating submount 226 according to Variation 3 of Embodiment 4. FIG. 37 is a bottom view illustrating submount 226 according to Variation 3 of Embodiment 4. Submount 226 has a wiring pattern formed on and vias in base 26.

The wiring pattern formed on the top surface of base 26 (a first base) has the same layout as that of base 20 illustrated in FIG. 4. Specifically, conductive patterned wirings (p-wirings P20, P21, P22, and P23 and n-wirings N20, N21, and N22) are formed on base 26.

Vias 500 that pass through from second surface 50 to third surface 60 are formed in base 26. Specifically, vias 525 to 530 that pass through from second surface 50 to third surface 60 are formed in base 26. Each of vias 525 to 530 is formed with a plurality of vias in base 26, and each set of vias is aligned in the Y-axis direction.

Conductive films 633 to 635 having electrically conductive properties are formed on third surface 60 of base 26.

For example, conductive film 633 electrically connects via 525 and via 526. For example, conductive film 634 electrically connects via 527 and via 528. For example, conductive film 635 electrically connects via 529 and via 530. Conductive film 635, conductive film 634, and conductive film 633 are quadrilateral in the top view, and aligned in this order in the X-axis direction.

According to these, for example, n-electrode N11 and p-electrode P11 are electrically connected through vias 527 and 528 and conductive film 634. For example, n-electrode N12 and n-electrode N13 are electrically connected via n-wiring N21.

Center portion N20c of n-wiring N20, center portion N21c of n-wiring N21, and center portion N22c of n-wiring N22 are exposed from backward ends of semiconductor laser elements 110, 120, and 130 in the Y-axis direction (end portions on the negative side of the Y-axis direction in the present embodiment).

### Variation 4

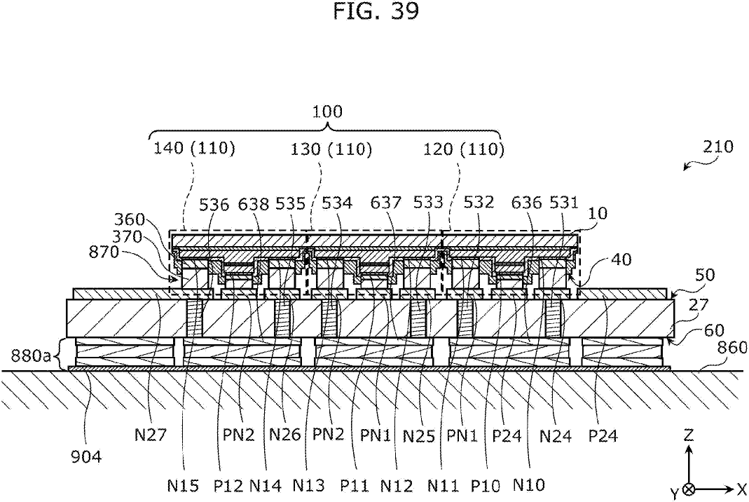

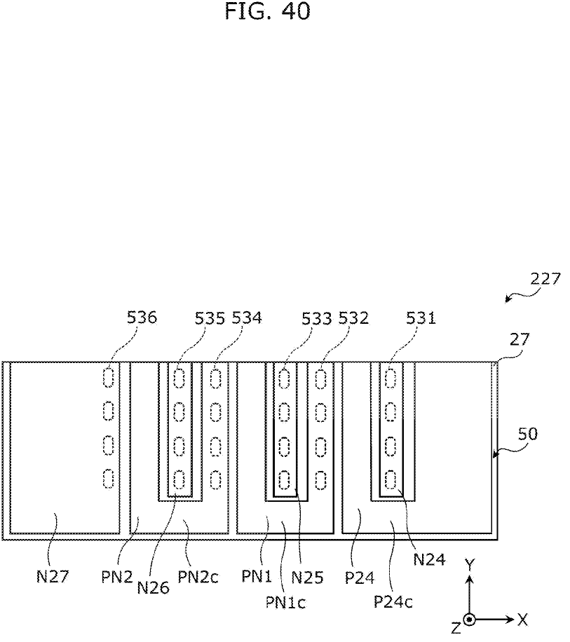

FIG. 38 is a top view illustrating array type semiconductor laser device 210 according to Variation 4 of Embodiment 4. FIG. 39 is a cross sectional view illustrating array type semiconductor laser device 210 according to Variation 4 of Embodiment 4, which is taken along line XXXIX-XXXIX in FIG. 38. FIG. 40 is a top view illustrating submount 227 according to Variation 4 of Embodiment 4. Submount 227 has a wiring pattern formed on and vias in base 27.

The wiring pattern formed on base 27 (a first base) has the same layout as that of base 21. Specifically, conductive patterned wirings (p-wiring P24, n-wirings N24 to N27, and pn-wirings PN1 and PN2) are formed on base 27.

Vias 500 that pass through from second surface 50 to third surface 60 are formed in base 27. Specifically, vias 531 to 535 that pass through from second surface 50 to third surface 60 are formed in base 27. Each of vias 531 to 536 is formed with a plurality of vias in base 27, and each set of vias is aligned in the Y-axis direction.

Conductive films 636 to 638 having electrically conductive properties are formed on third surface 60 of base 27.

For example, conductive film 636 electrically connects via 531 and via 532. Thus, conductive film 636 electrically connects n-electrode N10 and n-electrode N11 of semiconductor laser element 120. For example, conductive film 637 electrically connects via 533 and via 534. Thus, conductive film 637 electrically connects n-electrode N12 and n-electrode N13 of semiconductor laser element 130. For example, conductive film 638 electrically connects via 535 and via 536. Thus, conductive film 638 electrically connects n-electrode N14 and n-electrode N15 of semiconductor laser element 140.

According to these, for example, n-electrode N11 of semiconductor laser element 120 and p-electrode P11 of semiconductor laser element 130 are electrically connected via pn-wiring PN1. For example, n-electrode N12 and n-electrode N13 of semiconductor laser element 130 are electrically connected through vias 533 and 534 and conductive film 637.

Center portion P24c of p-wiring P24, center portion PN1c of pn-wiring PN1, and center portion PN2c of pn-wiring PN2 are exposed from backward ends of semiconductor laser elements 120, 130, and 140 in the Y-axis direction (end portions on the negative side of the Y-axis direction in the present embodiment).

As described above in Variation 3 and Variation 4, semiconductor laser elements 110 may be connected in series through vias and conductive films, without using wires.

### Embodiment 5

Next, an array type semiconductor laser device according to Embodiment 5 is to be described. Note that in the description of the array type semiconductor laser device according to Embodiment 5, differences from the array type semiconductor laser devices according to Embodiments 1 to 4 are mainly described, and a description of similar structural elements to those of the array type semiconductor laser devices according to Embodiments 1 to 4 may be omitted while substantially the same reference signs are given thereto.

### Configuration

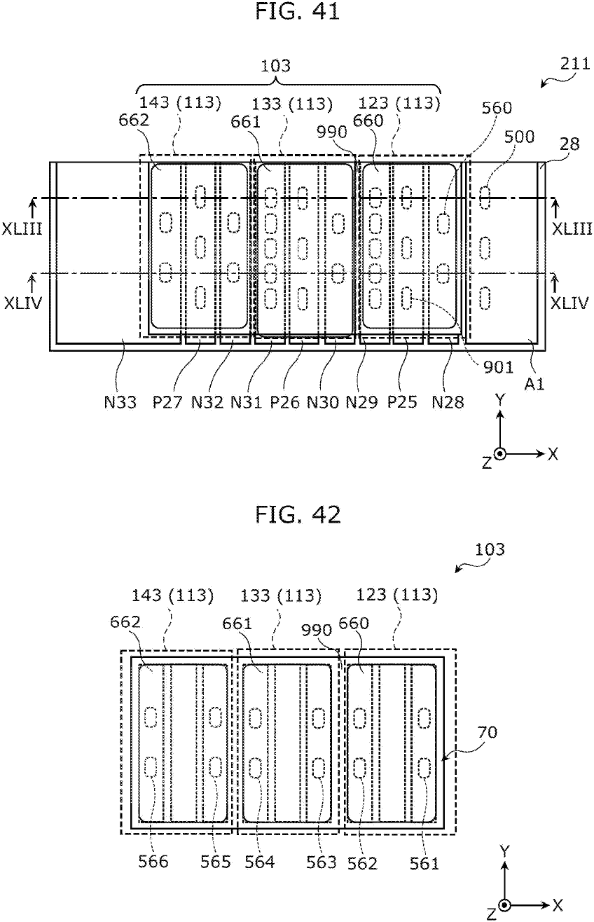

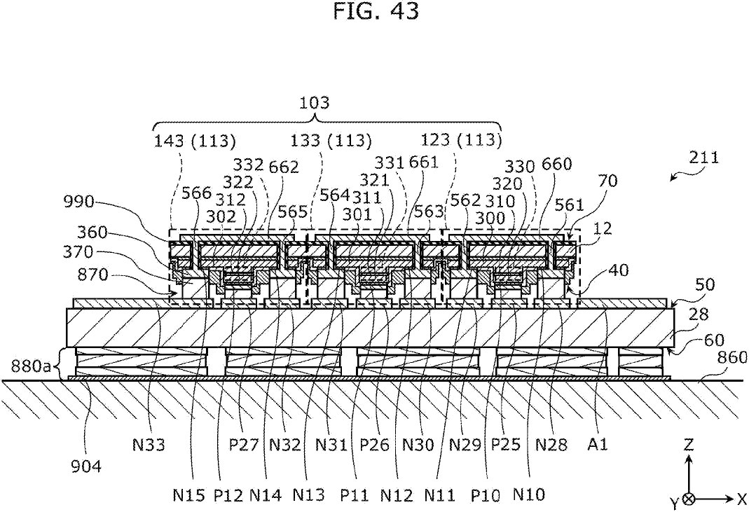

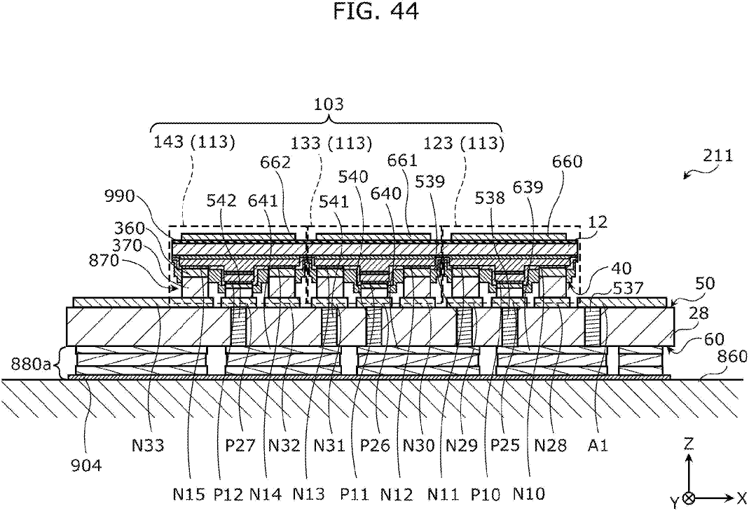

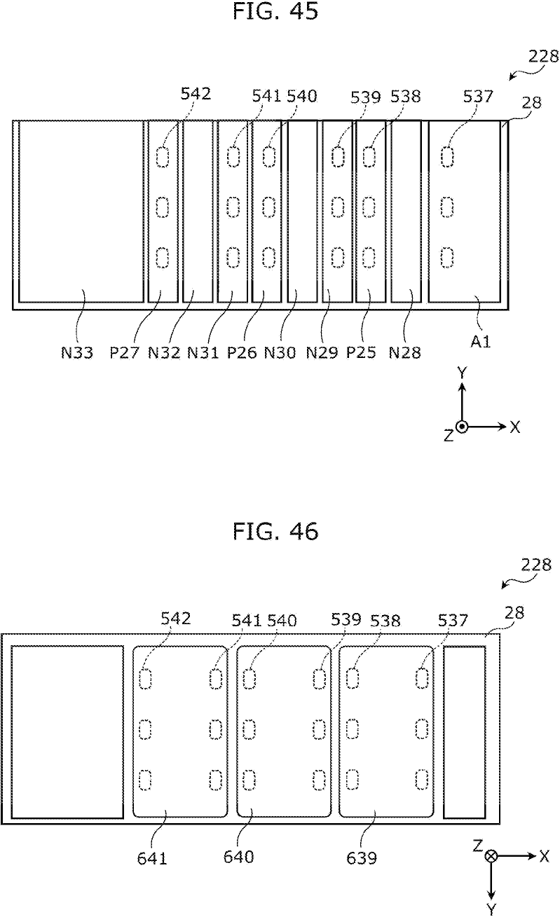

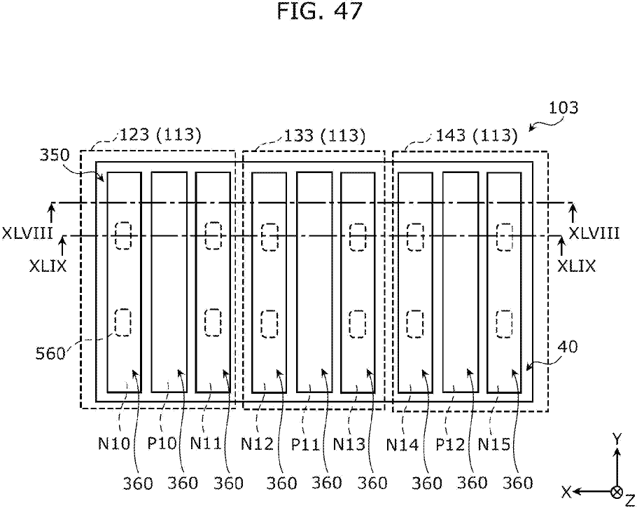

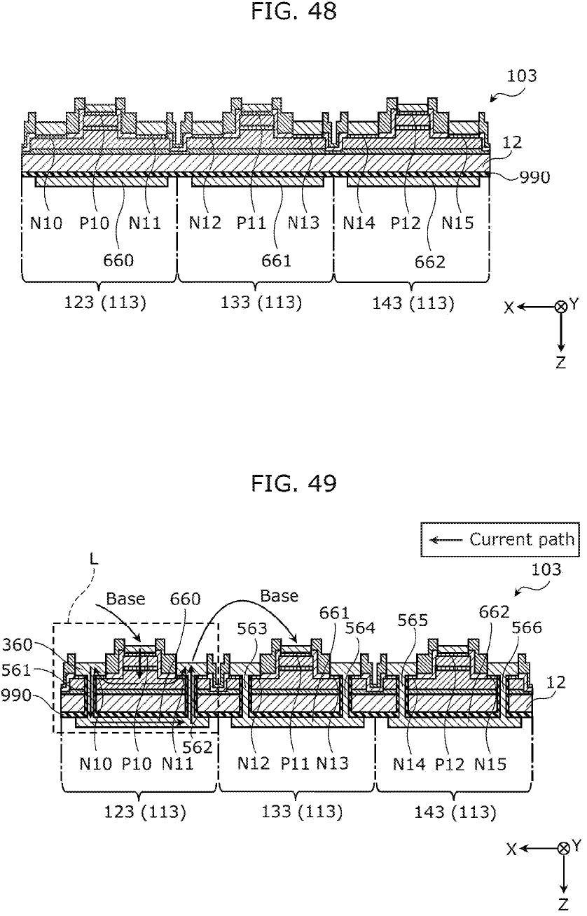

FIG. 41 is a top view illustrating array type semiconductor laser device 211 according to Embodiment 5. FIG. 42 is a top view illustrating semiconductor laser array element 103 according to Embodiment 5. FIG. 43 is a cross sectional view illustrating array type semiconductor laser device 211 according to Embodiment 5, which is taken along line XLIV-XLIV in FIG. 41. FIG. 44 is a cross sectional view illustrating array type semiconductor laser device 211 according to Embodiment 5, which is taken along line XLIII-XLIII in FIG. 41. FIG. 45 is a top view illustrating submount 228 according to Embodiment 5. FIG. 46 is a bottom view illustrating submount 228 according to Embodiment 5. FIG. 47 is a bottom view illustrating semiconductor laser array element 103 according to Embodiment 5. FIG. 48 is a cross sectional view illustrating semiconductor laser array element 103 according to Embodiment 5, which is taken along line XLVIII-XLVIII in FIG. 47. FIG. 49 is a cross sectional view illustrating semiconductor laser array element 103 according to Embodiment 5, which is taken along line XLIX-XLIX in FIG. 47. FIG. 50 is an enlarged view illustrating a region surrounded by broken line L in FIG. 49.

Array type semiconductor laser device 211 includes substrate 12, semiconductor laser array element 103, and submount 228. Submount 228 has a wiring pattern formed on and vias in base 28.

Semiconductor laser array element 103 includes semiconductor laser elements 113. Specifically, semiconductor laser array element 103 includes semiconductor laser element 123 (a first semiconductor laser element), semiconductor laser element 133 (a second semiconductor laser element), and semiconductor laser element 143 (a third semiconductor laser element). Semiconductor laser array element 103 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction. In FIG. 47, when semiconductor laser array element 103 is viewed from the undersurface, n-electrode N15, p-electrode P12, n-electrode N14, n-electrode N13, p-electrode P11, n-electrode N12, n-electrode N11, p-electrode P10, and n-electrode N10 are each formed into a quadrilateral shape that is substantially the same as the shape of corresponding wiring electrode 360 thereof, and are covered with corresponding wiring electrodes 360 thereof. Portions of the undersurface of semiconductor laser array element 103 where wiring electrodes 360 are not exposed are covered with protective film 350.

Specifically, semiconductor laser element 123 includes n-electrode N10, p-electrode P10, and n-electrode N11. Semiconductor laser element 133 includes n-electrode N12, p-electrode P11, and n-electrode N13. Semiconductor laser element 143 includes n-electrode N14, p-electrode P12, and n-electrode N15.

Note that when a common description that applies to all semiconductor laser elements 123, 133, and 143 is given, semiconductor laser element 123, semiconductor laser element 133, and semiconductor laser element 143 may be simply referred to as semiconductor laser element(s) 113. Vias that pass through in the Z-axis direction are formed in each of semiconductor laser elements 113.

Substrate 12 is a semiconductor substrate having an undersurface on which semiconductor laser array element 103 is formed. Through-holes are formed in substrate 12, and vias 560 that are electrodes are formed in the through-holes. Note that in the following, when a common description that applies to the vias included in the semiconductor laser array element is given, the vias may be simply referred to as via(s) 560.

Semiconductor laser array element 103 includes fourth surface 70 on a side opposite first surface 40 to which base 28 is joined. Conductive films 660 to 662 electrically connected to vias 560 are formed on fourth surface 70 that is a top surface of substrate 12. Vias 560 pass through substrate 12 and a semiconductor layer such as one conductivity type semiconductor layer 300 included in semiconductor laser array element 103, and are electrically connected to n-electrodes (n-electrodes N10 to N15) via wiring electrodes 360. Specifically, for example, n-electrode N10 and n-electrode N11 are electrically connected through vias 561 and 562 and conductive film 660. For example, n-electrode N12 and n-electrode N13 are electrically connected through vias 563 and 564 and conductive film 661. For example, n-electrode N14 and n-electrode N15 are electrically connected through vias 565 and 566 and conductive film 662.

Here, when substrate 12 is conductive, substrate 12 and vias 561 to 566 are insulated by forming insulating film 990 on the lateral wall of each through-hole. Further, when substrate 12 is conductive, substrate 12 and conductive films 660 to 662 are insulated by forming insulating film 990 on fourth surface 70. Note that when substrate 12 is an insulating substrate, insulating film 990 may not be formed.

For example, each of vias 561 to 566 is formed with a plurality of vias and each set of vias is aligned in the Y-axis direction.

Base 28 is a base on which semiconductor laser array element 103 is mounted. On second surface 50 of base 28, a wiring pattern (wiring A1, p-wirings P25 to P27, and n-wirings N28 to N33) are formed in the same layout as that of base 22.

Submount 228 includes plural vias 500.

Via 500 is a conductive electrode that passes through base 28 in a direction orthogonal to second surface 50. Specifically, via 500 electrically connects patterned wirings formed on second surface 50 of base 28 and patterned wirings formed on third surface 60 that is the undersurface of base 28 and is located on a side opposite second surface 50. Thus, via 500 passes through from second surface 50 to third surface 60.

Submount 228 includes vias 537 to 542. Each of vias 537 to 542 is formed with a plurality of vias are provided, and each set of vias is aligned in the Y-axis direction.

Vias 500 are electrically connected to one another by respective conductive films 639 to 641.

Conductive films 639 to 641 are electrically conductive films formed on third surface 60 of base 28.

For example, conductive film 639 electrically connects via 537 and via 538. Thus, conductive film 639 connects wiring A1 and p-electrode P10 of semiconductor laser element 123. For example, conductive film 640 electrically connects via 539 and via 540. Thus, conductive film 640 connects n-electrode N11 of semiconductor laser element 123 and p-electrode P11 of semiconductor laser element 133. For example, conductive film 641 electrically connects via 541 and via 542. Thus, conductive film 641 connects n-electrode N13 of semiconductor laser element 133 and p-electrode P12 of semiconductor laser element 143.

With the above configuration, for example, n-electrode N11 and p-electrode P11 are electrically connected through vias 539 and 540 and conductive film 640.

### Advantageous Effects and Others

As described above, in the present embodiment, for example, substrate 12 includes fourth surface 70 located on a side opposite first surface 40. In this case, for example, semiconductor laser element 130 includes a ninth through-hole (in which via 563 is formed) that passes through from first surface 40 to fourth surface 70, and a tenth through-hole (in which via 564 is formed) that passes through from first surface 40 to fourth surface 70. In this case, for example, the second conductor includes an eleventh conductor (via 563), a twelfth conductor (via 564), and a fifth conductive film (conductive film 661). In this case, for example, the fifth conductive film (conductive film 661) is formed on fourth surface 70. In this case, for example, the eleventh conductor (via 563) is formed in the ninth through-hole, and electrically connects n-electrode N12 and the fifth conductive film (conductive film 661). In this case, for example, the twelfth conductor (via 564) is formed in the tenth through-hole, and electrically connects n-electrode N13 and the fifth conductive film (conductive film 661).

According to this, the second conductor is not disposed on first surface 40 in array type semiconductor laser device 211. Accordingly, the arrangement of the first conductor and the second conductor on first surface 40 in array type semiconductor laser device 211 can be prevented from being complicated. With such a configuration, wires do not need to be provided later. Accordingly, current can be injected in the length direction of the entire resonator (the Y-axis direction), and thus the current density in semiconductor laser element 113 can be readily made uniform. Accordingly, optical properties of array type semiconductor laser device 211 can be stabilized.

### Variation

Next, a variation of the array type semiconductor laser device according to Embodiment 5 is to be described. Note that in the variation described in the following, differences from the elements included in the array type semiconductor laser device according to Embodiment 5 are to be mainly described, and a description of the same elements may be simplified or omitted.

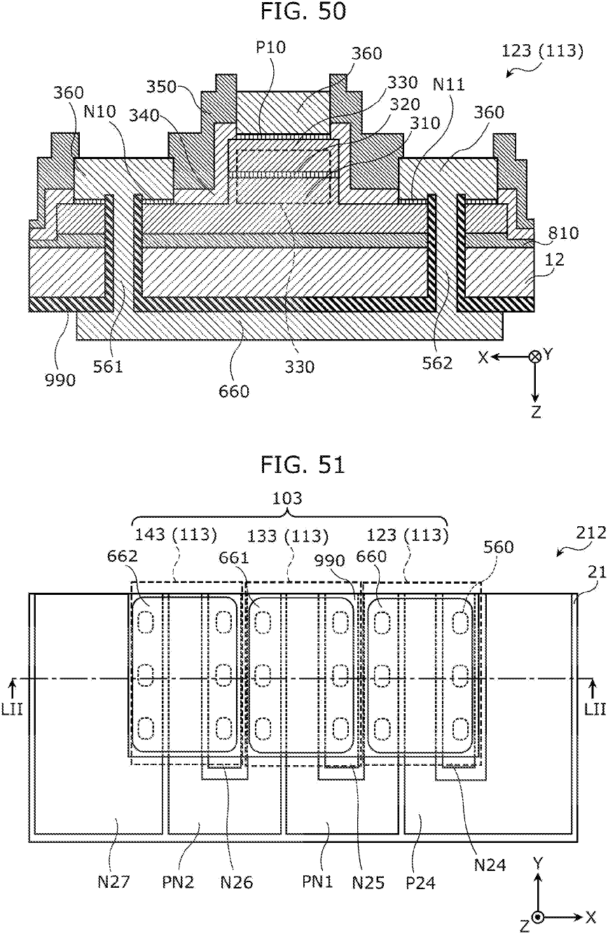

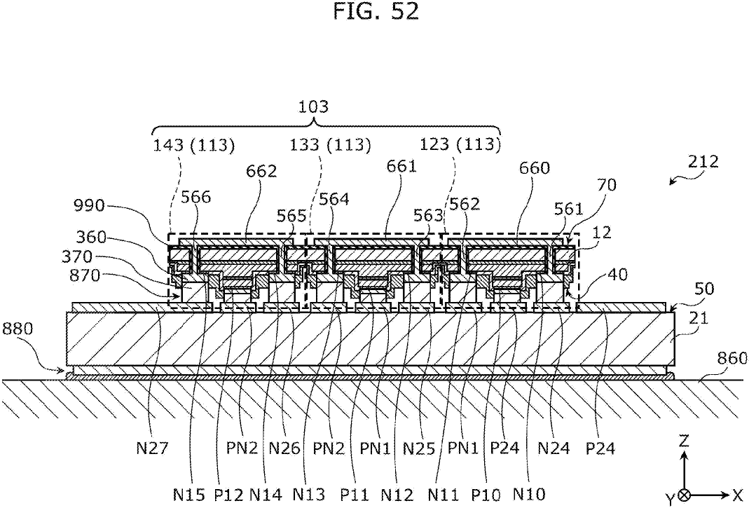

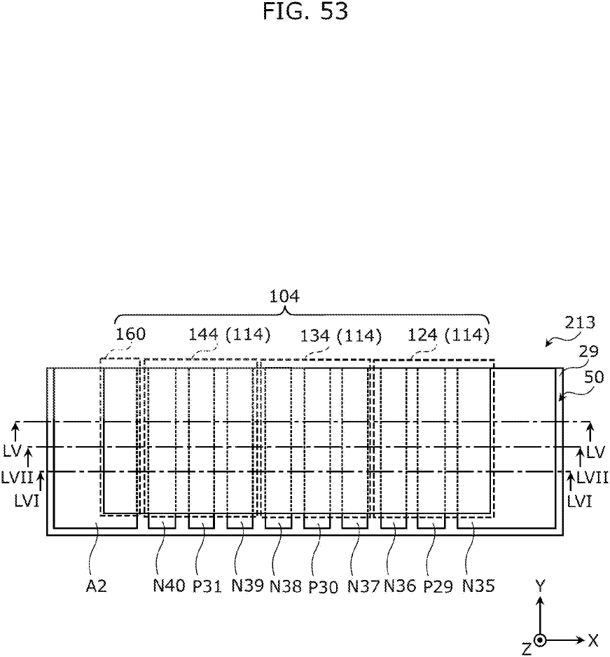

FIG. 51 is a top view illustrating array type semiconductor laser device 212 according to Variation 1 of Embodiment 5. FIG. 52 is a cross sectional view illustrating array type semiconductor laser device 212 according to Variation 1 of Embodiment 5, which is taken along line LII-LII in FIG. 51.

Array type semiconductor laser device 212 includes substrate 12, semiconductor laser array element 103, and base 21.

Thus, in array type semiconductor laser device 212, n-electrodes N10 to N15 in semiconductor laser element 113 are electrically connected by conductive films 660 to 662 formed on fourth surface 70 of substrate 12, and semiconductor laser elements 113 are directly connected by the wiring pattern (p-wiring P24, n-wirings N24 to N27, and pn-wirings PN1 and PN2) formed on second surface 50 of base 21.

Accordingly, the layouts of wirings that electrically connect electrodes included in the semiconductor laser elements according to the present disclosure may be combined arbitrarily.

### Embodiment 6

Next, an array type semiconductor laser device according to Embodiment 6 is to be described. Note that in the description of the array type semiconductor laser device according to Embodiment 6, differences from the array type semiconductor laser devices according to Embodiments 1 to 5 are mainly described, and a description of similar structural elements to those of the array type semiconductor laser devices according to Embodiments 1 to 5 may be omitted while substantially the same reference signs are given thereto.

### Configuration

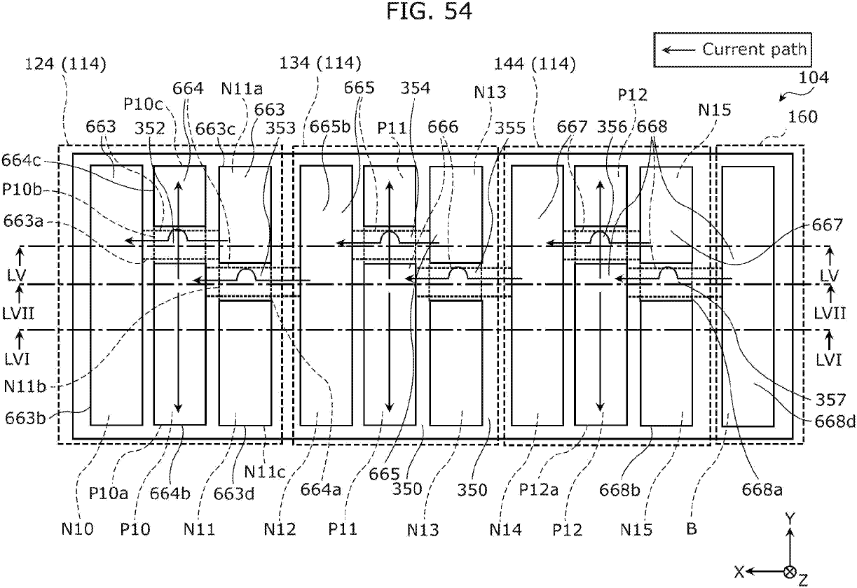

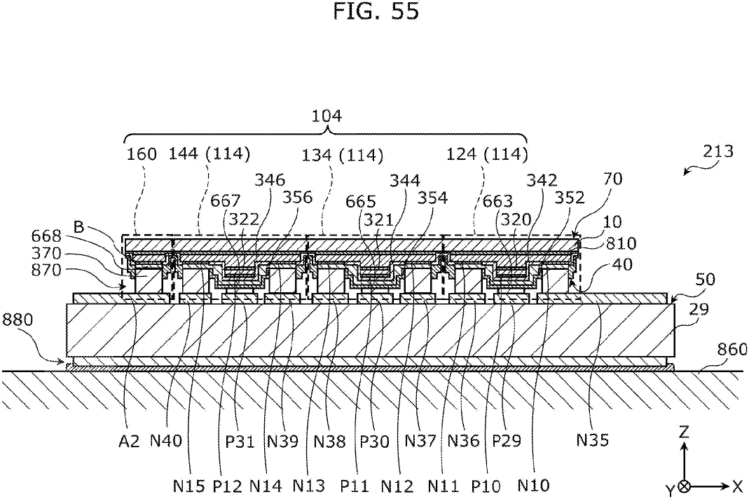

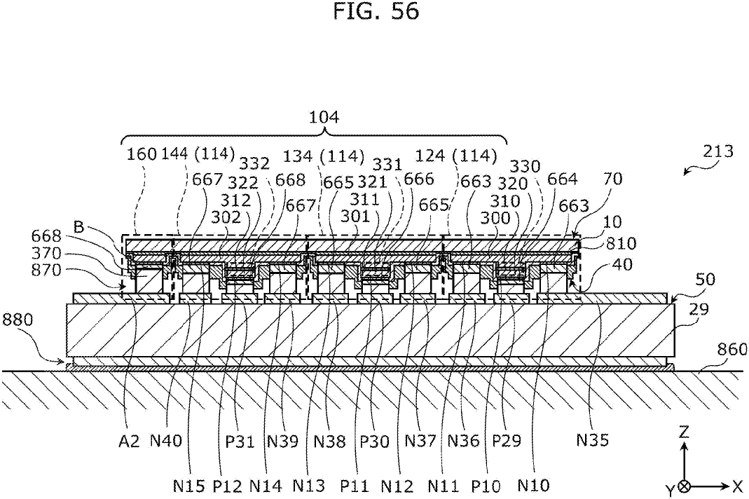

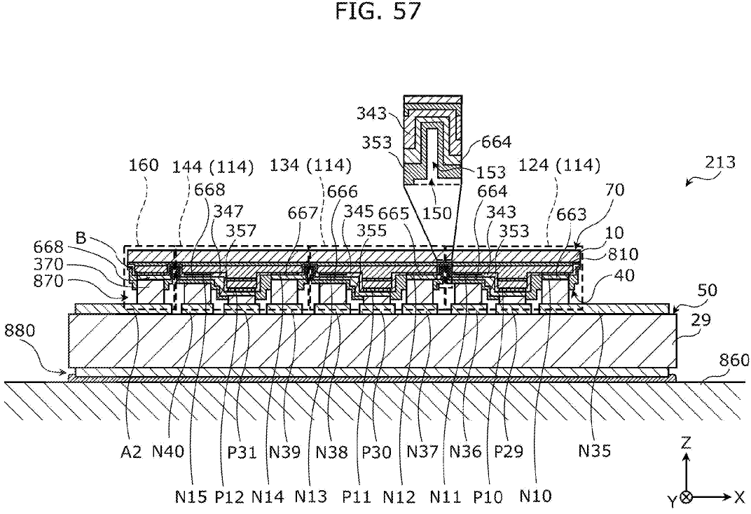

FIG. 53 is a top view illustrating array type semiconductor laser device 213 according to Embodiment 6. FIG. 54 is a bottom view illustrating semiconductor laser array element 104 according to Embodiment 6. FIG. 55 is a cross sectional view of array type semiconductor laser device 213 according to Embodiment 6, which includes a second conductor and is taken along line LV-LV in FIG. 53 and FIG. 54. FIG. 56 is a cross sectional view illustrating array type semiconductor laser device 213 according to Embodiment 6, which is taken along line LVI-LVI in FIG. 53 and FIG. 54. FIG. 57 is a cross sectional view of array type semiconductor laser device 213 according to Embodiment 6, which includes a first conductor and is taken along line LVII-LVII in FIG. 53 and FIG. 54.

Array type semiconductor laser device 213 includes substrate 10, semiconductor laser array element 104, and base 29 (a first base).

Semiconductor laser array element 104 includes plural semiconductor laser elements 114. Specifically, semiconductor laser array element 104 includes semiconductor laser element 124 (a first semiconductor laser element), semiconductor laser element 134 (a second semiconductor laser element), and semiconductor laser element 144 (a third semiconductor laser element). Semiconductor laser array element 104 includes n-electrode N10, p-electrode P10, n-electrode N11, n-electrode N12, p-electrode P11, n-electrode N13, n-electrode N14, p-electrode P12, n-electrode N15, and dummy electrode B in the order from the positive side of the X-axis direction.

Specifically, semiconductor laser element 124 includes n-electrode N10, p-electrode P10, and n-electrode N11. Semiconductor laser element 134 includes n-electrode N12, p-electrode P11, and n-electrode N13. Semiconductor laser element 144 includes n-electrode N14, p-electrode P12, and n-electrode N15.

Note that when a common description that applies to all semiconductor laser elements 124, 134, and 144 is given, semiconductor laser element 124, semiconductor laser element 134, and semiconductor laser element 144 may be simply referred to as semiconductor laser element(s) 114.

Semiconductor laser array element 104 further includes dummy portion 160, conductive films 663 to 668, insulating films 342 to 347, and protective films 352 to 357, in addition to the configuration of semiconductor laser array element 100.

Dummy portion 160 is a portion aligned with semiconductor laser elements 114, and does not emit light. Dummy portion includes dummy electrode B.

Dummy electrode B is connected to wiring A2 included in the patterned wirings formed on second surface 50 of base 29.

Conductive films 663 to 668 are electrically conductive films. Conductive films 663 to 668 are formed on first surface 40 of semiconductor laser array element 104. Conductive films 663 to 668 are electrically connected to electrodes included in semiconductor laser array element 104.

For example, conductive film 663 is electrically connected to n-electrode N10 and n-electrode N11. For example, conductive film 664 is electrically connected to p-electrode P10 and n-electrode N12. For example, conductive film 665 is electrically connected to n-electrode N12 and n-electrode N13. For example, conductive film 666 is electrically connected to p-electrode P11 and n-electrode N14. For example, conductive film 667 is electrically connected to n-electrode N14 and n-electrode N15. For example, conductive film 668 is electrically connected to p-electrode P12 and dummy electrode B.

Conductive films 664, 666, and 668 are also formed in recesses 150 included in semiconductor laser array element 104.

Further, conductive films 664, 666, and 668 are formed in recesses 153 each having a shape that conforms to the shape of recess 150.

In Embodiment 6, conductive films 663 to 668 are each connected to two electrodes out of the electrodes included in semiconductor laser array element 104, in a substantially center of the electrodes in the Y-axis direction.

Insulating films 342 to 347 are insulating films for electrically insulating the electrodes included in semiconductor laser array element 104 from conductive films 663 to 668.

For example, insulating film 342 is located between p-electrode P10 and conductive film 663, and electrically insulates p-electrode P10 from conductive film 663.

For example, insulating film 343 is located between n-electrode N11 and conductive film 664, and electrically insulates n-electrode N11 from conductive film 664.

For example, insulating film 344 is located between p-electrode P11 and conductive film 665, and electrically insulates p-electrode P11 from conductive film 665.

For example, insulating film 345 is located between n-electrode N13 and conductive film 666, and electrically insulates n-electrode N13 from conductive film 666.

For example, insulating film 346 is located between p-electrode P12 and conductive film 667, and electrically insulates p-electrode P12 from conductive film 667.

For example, insulating film 347 is located between n-electrode N15 and conductive film 668, and electrically insulates n-electrode N15 from conductive film 668.

Protective films 352 to 357 are insulating films for electrically insulating conductive films 663 to 668 from wirings (n-wiring N36, n-wiring N38, n-wiring N40, and p-wirings P29 to P31) via connection layer 370.

For example, protective film 352 is located between conductive film 663 and connection layer 370 above p-wiring P29, and electrically insulates conductive film 663 from p-wiring P29.

For example, protective film 353 is located between conductive film 664 and connection layer 370 above n-wiring N36, and electrically insulates conductive film 664 from n-wiring N36.

For example, protective film 354 is located between conductive film 665 and connection layer 370 above p-wiring P30, and electrically insulates conductive film 665 from p-wiring P30.

For example, protective film 355 is located between conductive film 666 and connection layer 370 above n-wiring N38, and electrically insulates conductive film 666 from n-wiring N38.

For example, protective film 356 is located between conductive film 667 and connection layer 370 above p-wiring P31, and electrically insulates conductive film 667 from p-wiring P31.

For example, protective film 357 is located between conductive film 668 and connection layer 370 above n-wiring N40, and electrically insulates conductive film 668 from n-wiring N40.

In FIG. 54, conductive films 663, 665, and 667 do not overlap conductive films 664, 666, and 668 in the Y-axis direction. Thus, the positions in which conductive films 663, 665, and 667 are disposed and the positions in which conductive films 664, 666, and 668 are disposed are different in the Y-axis direction. When semiconductor laser array element 104 is viewed from the undersurface, conductive film 663 includes conductive film 663b that covers n-electrode N10 and is electrically connected to n-electrode N10, conductive film 663c that covers portion N11a of n-electrode N11 and is electrically connected to portion N11a, and conductive film 663a that connects conductive film 663b and conductive film 663c.

N-electrode N11 includes portion N11a covered with conductive film 663c and having the same shape as that of conductive film 663c, portion Nile covered with conductive film 663d, electrically connected to conductive film 663d, and having the same shape as that of conductive film 663d, and portion N11b that connects portion N11a and portion N11c.

Conductive film 664 includes conductive film 664b that covers portion P10a of p-electrode P10 and is electrically connected to portion P10a, and conductive film 664a that connects conductive film 664b and conductive film 665b.

Note that conductive film 665b is a portion of conductive film 665 that covers n-electrode N12 and is electrically connected to n-electrode N12.

P-electrode P10 includes portion P10a covered with conductive film 664b and having the same shape as that of conductive film 664b, portion P10c covered with conductive film 664c, electrically connected to conductive film 664c, and having the same shape as that of conductive film 664c, and portion P10b that connects portion P10a and portion P10c.

Conductive film 668 includes conductive film 668b that covers portion P12a of p-electrode P12 and is electrically connected to dummy electrode B, conductive film 668d that covers dummy electrode B and is electrically connected to dummy electrode B, and conductive film 668a that connects conductive film 668b and conductive film 668d.

Portions of the undersurface of semiconductor laser array element 104 where the conductive films are not exposed are covered with protective film 350. Protective films 352 to 357 are formed integrally with and using the same material as that of protective film 350. Note that dummy electrode B has a shape the same as that of conductive film 668d.

As illustrated in FIG. 55, p-electrode P10b, insulating film 342, conductive film 663a, and protective film 352 are formed in the order from the other conductivity type semiconductor layer 320 side, in a portion in which conductive film 663a and p-electrode P10b are stacked in the cross section taken along line LV-LV in FIG. 54. As illustrated in FIG. 57, n-electrode N11b, insulating film 343, conductive film 664a, and protective film 353 are formed in the order from the one conductivity type semiconductor layer 300 side, in a portion in which conductive film 664a and n-electrode N11b are stacked in the cross section taken along line LVII-LVII in FIG. 54.

Base 29 is a base on which semiconductor laser array element 104 is mounted. A wiring pattern electrically connected to electrodes included in semiconductor laser array element 104 is formed on second surface 50 of base 29. Specifically, n-wirings N35 to N40, p-wirings P29 to P31, and wiring A2 are formed on second surface 50 of base 29.

For example, n-electrode N10 is electrically connected to n-wiring N35. For example, n-electrode N11 is electrically connected to n-wiring N36. For example, n-electrode N12 is electrically connected to n-wiring N37. For example, n-electrode N13 is electrically connected to n-wiring N38. For example, n-electrode N14 is electrically connected to n-wiring N39. For example, n-electrode N15 is electrically connected to n-wiring N40.

For example, p-electrode P10 is electrically connected to p-wiring P29. For example, p-electrode P11 is electrically connected to p-wiring P30. For example, p-electrode P12 is electrically connected to p-wiring P31.

For example, wiring A2 is electrically connected to dummy electrode B.

With the above configuration, for example, the flow of current in array type semiconductor laser device 213 starts from wiring A2 that is an anode electrode, and is as follows: wiring A2 → dummy electrode B → conductive film 668 (conductive film 668d → conductive film 668a → conductive film 668b) → p-electrode P12 → n-electrodes N14 and N15 → conductive film 667 → conductive film 666 → p-electrode P11 → n-electrodes N12 and N13 → conductive film 665 → conductive film 664 → p-electrode P10 → n-electrodes N10 and N11 → n-wiring N35 that is a cathode electrode.

Note that current from p-electrode P12 to conductive film 666 flows through a path that is p-electrode P12 → n-electrode N14 → conductive film 667 → conductive film 666, and through a path that is p-electrode P12 → n-electrode N15 → conductive film 667 → conductive film 666. Similarly, current from p-electrode P11 to conductive film 664 flows through a path that is p-electrode P11 → n-electrode N12 → conductive film 665 → conductive film 664, and through a path that is p-electrode P11 → n-electrode N13 → conductive film 665 → conductive film 664. Similarly, current from p-electrode P10 to n-wiring N35 flows through a path that is p-electrode P10 → n-electrode N10 → conductive film 663b → n-wiring N35, and through a path that is p-electrode P10 → n-electrode N11 → conductive film 663c → conductive film 663a → conductive film 663b → n-wiring N35.

As described above, in semiconductor laser array element 104, semiconductor laser elements 114 are connected in series not via the patterned wirings formed on base 29.

### Advantageous Effects and Others

As described above, in the present embodiment, for example, array type semiconductor laser device 213 further includes recess 150 between semiconductor laser element 124 and semiconductor laser element 134. In the present embodiment, the first conductor (conductive film 664) is formed in recess 150.

According to this, p-electrode P10 and n-electrode N12 can be electrically connected over a shorter distance.

### Variation

Next, a variation of the array type semiconductor laser device according to Embodiment 6 is to be described. Note that in the variation described in the following, differences from the elements included in the array type semiconductor laser device according to Embodiment 6 are to be mainly described, and a description of the same elements may be simplified or omitted.

### Variation 1

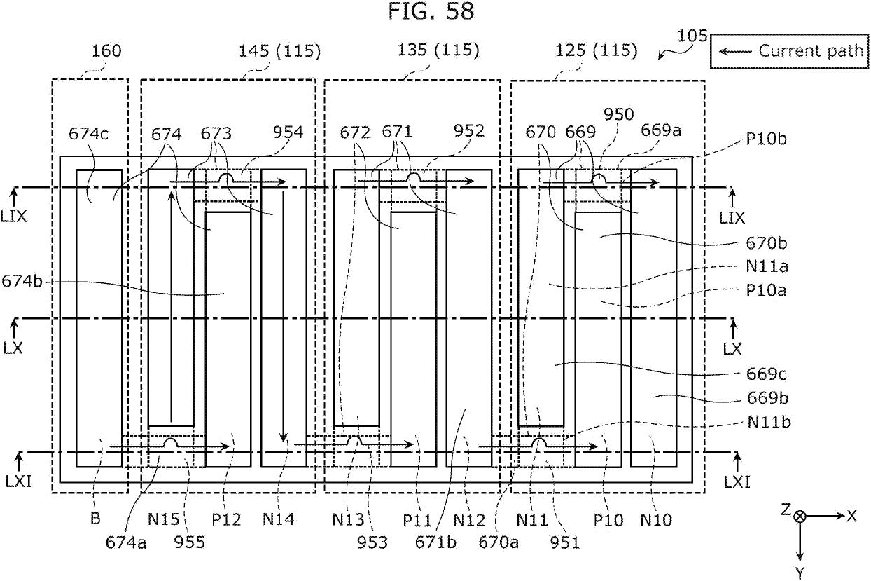

FIG. 58 is a bottom view illustrating semiconductor laser array element 105 according to Variation 1 of Embodiment 6.

FIG. 59 is a cross sectional view of semiconductor laser array element 105 according to Variation 1 of Embodiment 6, which includes a second conductor and is taken along line LIX-LIX in

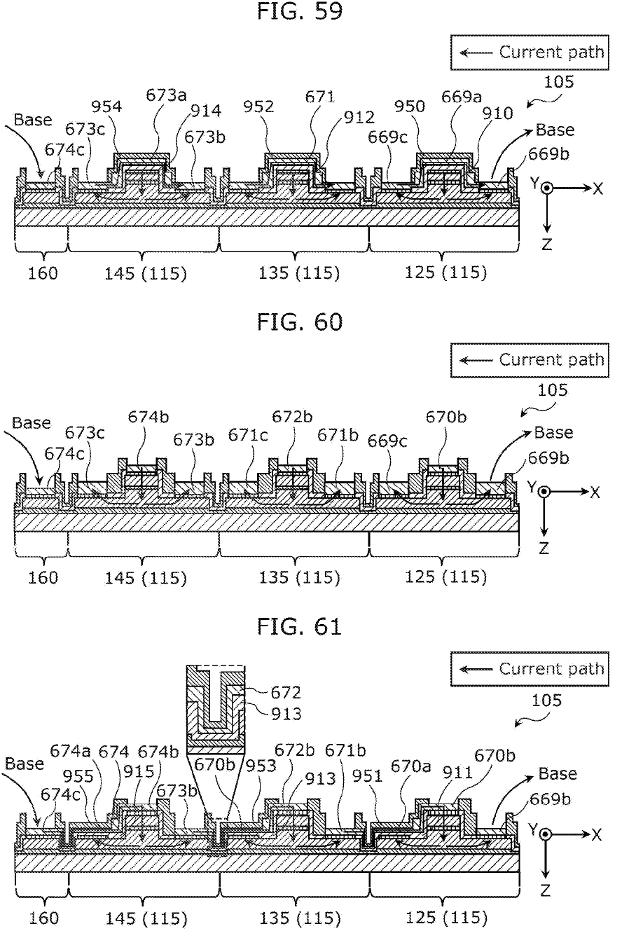

FIG. 58. FIG. 60 is a cross sectional view illustrating semiconductor laser array element 105 according to Variation 1 of Embodiment 6, which is taken along line LX-LX in FIG. 58.

FIG. 61 is a cross sectional view of semiconductor laser array element 105 according to Variation 1 of Embodiment 6, which includes a first conductor and is taken along line LXI-LXI in FIG. 58.

Semiconductor laser array element 105 includes plural semiconductor laser elements 115. Specifically, semiconductor laser array element 105 includes semiconductor laser element 125 (a first semiconductor laser element), semiconductor laser element 135 (a second semiconductor laser element), and semiconductor laser element 145 (a third semiconductor laser element). Semiconductor laser array element 105 includes n-electrode N10, p-electrode P10, n-electrode N11, n-electrode N12, p-electrode P11, n-electrode N13, n-electrode N14, p-electrode P12, n-electrode N15, and dummy electrode B in the order from the positive side of the X-axis direction.

Specifically, semiconductor laser element 125 includes n-electrode N10, p-electrode P10, and n-electrode N11. Semiconductor laser element 135 includes n-electrode N12, p-electrode P11, and n-electrode N13. Semiconductor laser element 145 includes n-electrode N14, p-electrode P12, and n-electrode N15.

Note that when a common description that applies to all semiconductor laser elements 125, 135, and 145 is given, semiconductor laser element 125, semiconductor laser element 135, and semiconductor laser element 145 may be simply referred to as semiconductor laser element(s) 115.

Semiconductor laser array element 105 further includes dummy portion 160, conductive films 669 to 674, insulating films 910 to 915, and protective films 950 to 955, in addition to the configuration of semiconductor laser array element 100.

Dummy portion 160 is aligned with plural semiconductor laser elements 115.

Conductive films 669 to 674 are electrically conductive films. Conductive films 669 to 674 are formed on first surface 40 of semiconductor laser array element 105. Conductive films 669 to 674 are electrically connected to electrodes included in semiconductor laser array element 105.

For example, conductive film 669 is electrically connected to n-electrode N10 and n-electrode N11. For example, conductive film 670 is electrically connected to p-electrode P10 and n-electrode N12. For example, conductive film 671 is electrically connected to n-electrode N12 and n-electrode N13. For example, conductive film 672 is electrically connected to p-electrode P11 and n-electrode N14. For example, conductive film 673 is electrically connected to n-electrode N14 and n-electrode N15. For example, conductive film 674 is electrically connected to p-electrode P12 and dummy electrode B.

In this variation, conductive films 669, 671, and 673 are connected to two electrodes out of a plurality of electrodes included in semiconductor laser array element 105, at end portions on the rear side of the plurality of electrodes in the Y-axis direction. Further, conductive films 670, 672, and 674 are connected to two electrodes out of a plurality of electrodes included in semiconductor laser array element 105, at end portions on the emission side of the plurality of electrodes in the Y-axis direction. Conductive films 669, 671, and 673 are connected to the end portions of the electrodes on the side opposite, in the Y-axis direction, the end portions of electrodes to which conductive films 670, 672, and 674 are connected.

Insulating films 910 to 915 are insulating films for electrically insulating the electrodes included in semiconductor laser array element 105 from conductive films 669 to 674.

For example, insulating film 910 is located between p-electrode P10 and conductive film 669, and electrically insulates p-electrode P10 from conductive film 669. For example, insulating film 911 is located between n-electrode N11 and conductive film 670, and electrically insulates n-electrode N11 from conductive film 670. For example, insulating film 912 is located between p-electrode P11 and conductive film 671, and electrically insulates p-electrode P11 from conductive film 671. For example, insulating film 913 is located between n-electrode N13 and conductive film 672, and electrically insulates n-electrode N13 from conductive film 672. For example, insulating film 914 is located between p-electrode P12 and conductive film 673, and electrically insulates p-electrode P12 from conductive film 673. For example, insulating film 915 is located between n-electrode N15 and conductive film 674, and electrically insulates n-electrode N15 from conductive film 674.

Protective films 950 to 955 are insulating films for electrically insulating conductive films 669 to 674 from wirings (n-wiring N36, n-wiring N38, n-wiring N40, and p-wirings P29 to P31) via connection layer 370.

For example, protective film 950 is located between conductive film 669 and connection layer 370 above p-wiring P29, and electrically insulates conductive film 670 from p-wiring P29.

For example, protective film 951 is located between conductive film 670 and connection layer 370 above n-wiring N36, and electrically insulates conductive film 670 from n-wiring N36.

For example, protective film 952 is located between conductive film 671 and connection layer 370 above p-wiring P30, and electrically insulates conductive film 671 from p-wiring P30.

For example, protective film 953 is located between conductive film 672 and connection layer 370 above n-wiring N38, and electrically insulates conductive film 672 from n-wiring N38.

For example, protective film 954 is located between conductive film 673 and connection layer 370 above p-wiring P31, and electrically insulates conductive film 673 from p-wiring P31.

For example, protective film 955 is located between conductive film 674 and connection layer 370 above n-wiring N40, and electrically insulates conductive film 674 from n-wiring N40.

When semiconductor laser array element 105 is viewed from the undersurface, conductive film 669 includes conductive film 669b that covers n-electrode N10 and is electrically connected to n-electrode N10, conductive film 669c that covers portion N11a of n-electrode N11 and is electrically connected to portion N11a, and conductive film 669a that connects conductive film 669b and conductive film 669c.

N-electrode N11 includes portion N11a covered with conductive film 669c and having the same shape as that of conductive film 669c, and portion N11b covered with conductive film 670a and connected to portion N11a.

Conductive film 670 includes conductive film 670b that covers portion P10a of p-electrode P10 and is electrically connected to portion P10a, and conductive film 670a that connects conductive film 670b and conductive film 671b.

Note that conductive film 671b is a portion of conductive film 671 that covers n-electrode N12 and is electrically connected to n-electrode N12.

P-electrode P10 includes portion P10a covered with conductive film 670b and having the same shape as that of conductive film 670b, and portion P10b connected to portion P10a.

Conductive film 674 includes conductive film 674b that covers portion P12a of p-electrode P12 and is electrically connected to portion P12a, conductive film 674c that covers dummy electrode B and is electrically connected to dummy electrode B, and conductive film 674a that connects conductive film 674b and conductive film 674c

Portions of the undersurface of semiconductor laser array element 105 where the conductive films are not exposed are covered with protective film 350. Note that dummy electrode B has a shape the same as that of conductive film 674c.

With the above configuration, for example, the flow of current in semiconductor laser array element 105 is as follows: dummy electrode B → conductive film 674 → p-electrode P12 → n-electrodes N14 and N15 → conductive film 672 → p-electrode P11 → n-electrodes N12 and N13 → conductive film 670 → p-electrode P10 → n-electrodes N10 and N11.

Note that current from p-electrode P12 to conductive film 672 flows through a path that is p-electrode P12 → n-electrode N14 → conductive film 672, and through a path that is p-electrode P12 → n-electrode N15 → conductive film 673 → conductive film 672. Similarly, current from p-electrode P11 to conductive film 670 flows through a path that is p-electrode P11 → n-electrode N12 → conductive film 670, and through a path that is p-electrode P11 → n-electrode N13 → conductive film 671 → conductive film 670. Similarly, current from p-electrode P10 to conductive film 669 flows through a path that is p-electrode P10 → n-electrode N10 → conductive film 669, and through a path that is p-electrode P10 → n-electrode N11 → conductive film 669.

Accordingly, also in semiconductor laser array element 105, plural semiconductor laser elements 115 are connected in series not via the patterned wirings formed on the base on which semiconductor laser array element 105 is mounted.

### Variation 2

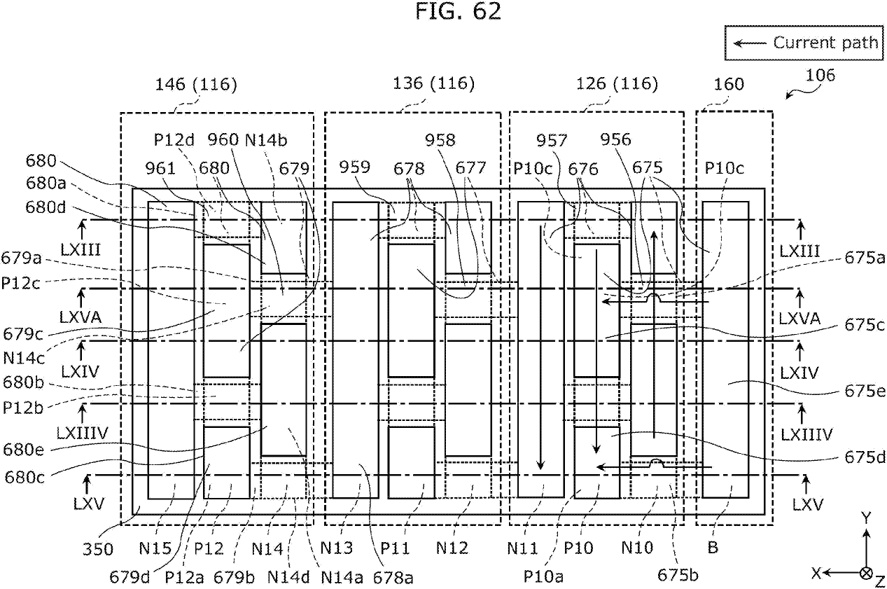

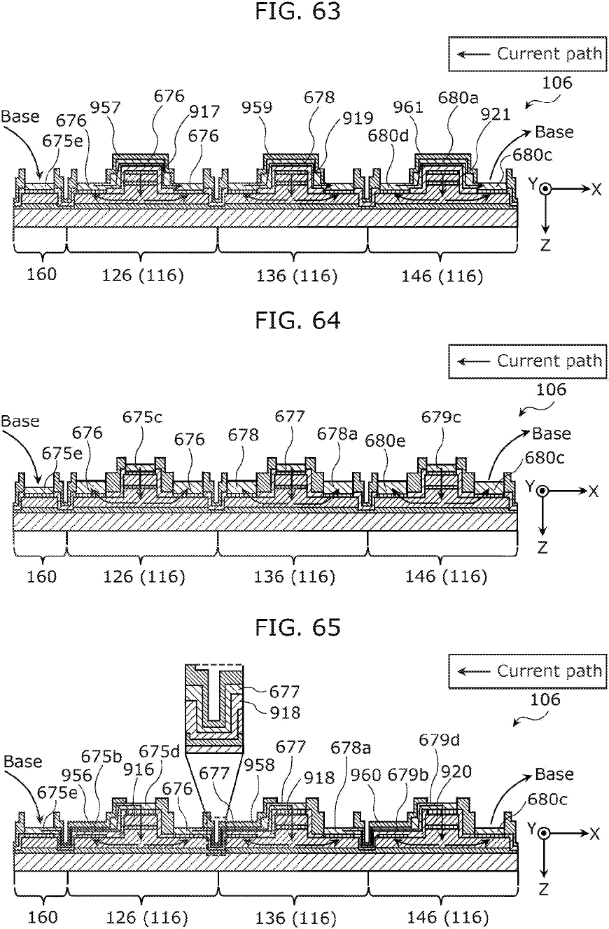

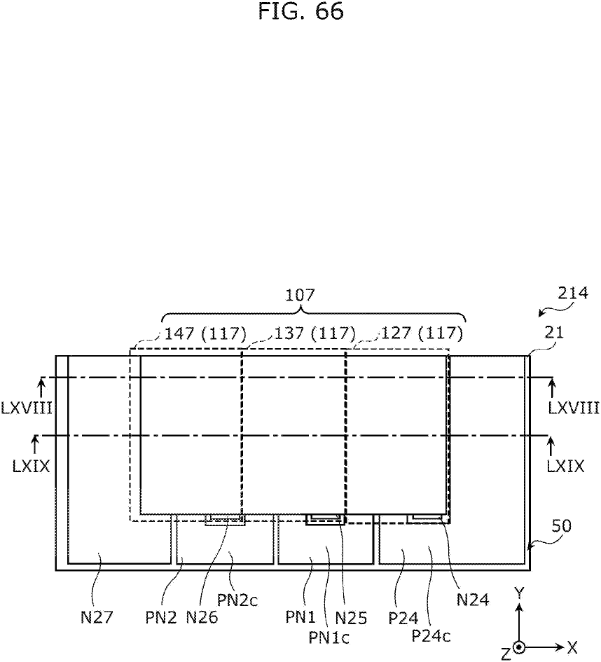

FIG. 62 is a bottom view illustrating semiconductor laser array element 106 according to Variation 2 of Embodiment 6. FIG. 63 is a cross sectional view of semiconductor laser array element 106 according to Variation 2 of Embodiment 6, which includes a second conductor and is taken along line LXIII-LXIII in FIG. 62. FIG. 64 is a cross sectional view illustrating semiconductor laser array element 106 according to Variation 2 of Embodiment 6, which is taken along line LXIV-LXIV in FIG. 62. FIG. 65 is a cross sectional view of semiconductor laser array element 106 according to Variation 2 of Embodiment 6, which includes a first conductor and is taken along line LXV-LXV in FIG. 62.

Note that the cross section taken along line LXIII-LXIII in FIG. 62 and the cross section taken along line LXIIIA-LXIIIA in FIG. 62 have the same shape. Further, the cross section taken along line LXV-LXV in FIG. 62 and the cross section taken along line LXVA-LXVA in FIG. 62 have the same shape.

Semiconductor laser array element 106 includes plural semiconductor laser elements 116. Specifically, semiconductor laser array element 106 includes semiconductor laser element 126 (a first semiconductor laser element), semiconductor laser element 136 (a second semiconductor laser element), and semiconductor laser element 146 (a third semiconductor laser element). Semiconductor laser array element 106 includes dummy electrode B, n-electrode N10, p-electrode P10, n-electrode N11, n-electrode N12, p-electrode P11, n-electrode N13, n-electrode N14, p-electrode P12, and n-electrode N15 in the order from the negative side of the X-axis direction.

Specifically, semiconductor laser element 126 includes n-electrode N10, p-electrode P10, and n-electrode N11. Semiconductor laser element 136 includes n-electrode N12, p-electrode P11, and n-electrode N13. Semiconductor laser element 146 includes n-electrode N14, p-electrode P12, and n-electrode N15.

Note that when a common description that applies to all semiconductor laser elements 126, 136, and 146 is given, semiconductor laser element 126, semiconductor laser element 136, and semiconductor laser element 146 may be simply referred to as semiconductor laser element(s) 116.

Semiconductor laser array element 106 further includes dummy portion 160, conductive films 675 to 680, insulating films 916 to 921, and protective films 956 to 961, in addition to the configuration of semiconductor laser array element 100.

Dummy portion 160 is aligned with plural semiconductor laser elements 116.

Conductive films 675 to 680 are electrically conductive films. Conductive films 675 to 680 are formed on first surface 40 of semiconductor laser array element 106. Conductive films 675 to 680 are electrically connected to electrodes included in semiconductor laser array element 106.

For example, conductive film 675 is electrically connected to dummy electrode B and p-electrode P10. For example, conductive film 676 is electrically connected to n-electrode N10 and n-electrode N11. For example, conductive film 677 is electrically connected to n-electrode N11 and p-electrode P11. For example, conductive film 678 is electrically connected to n-electrode N12 and n-electrode N13. For example, conductive film 679 is electrically connected to n-electrode N13 and p-electrode P12. For example, conductive film 680 is electrically connected to n-electrode N14 and n-electrode N15.

Insulating films 916 to 921 are insulating films for electrically insulating a plurality of electrodes included in semiconductor laser array element 106 from conductive films 675 to 680.

For example, insulating film 916 is located between n-electrode N10 and conductive film 675, and electrically insulates n-electrode N10 from conductive film 675. For example, insulating film 917 is located between p-electrode P10 and conductive film 676, and electrically insulates p-electrode P10 from conductive film 676. For example, insulating film 918 is located between n-electrode N12 and conductive film 677, and electrically insulates n-electrode N12 from conductive film 677. For example, insulating film 919 is located between p-electrode P11 and conductive film 678, and electrically insulates p-electrode P11 from conductive film 678. For example, insulating film 920 is located between n-electrode N14 and conductive film 679, and electrically insulates n-electrode N14 from conductive film 679. For example, insulating film 921 is located between p-electrode P12 and conductive film 680, and electrically insulates p-electrode P12 from conductive film 680.

Protective films 956 to 961 are insulating films for electrically insulating conductive films 675 to 680 from wirings (n-wiring N36, n-wiring N38, n-wiring N40, and p-wirings P29 to P31) via connection layer 370.

For example, protective film 961 is located between conductive film 680 and connection layer 370 above p-wiring P29, and electrically insulates conductive film 680 from p-wiring P29.

For example, protective film 960 is located between conductive film 679 and connection layer 370 above n-wiring N36, and electrically insulates conductive film 679 from n-wiring N36.

For example, protective film 959 is located between conductive film 678 and connection layer 370 above p-wiring P30, and electrically insulates conductive film 678 from p-wiring P30.

For example, protective film 958 is located between conductive film 677 and connection layer 370 above n-wiring N38, and electrically insulates conductive film 677 from n-wiring N38.

For example, protective film 957 is located between conductive film 676 and connection layer 370 above p-wiring P31, and electrically insulates conductive film 670 from p-wiring P31.

For example, protective film 956 is located between conductive film 675 and connection layer 370 above n-wiring N40, and electrically insulates conductive film 675 from n-wiring N40.

When semiconductor laser array element 106 is viewed from the undersurface, conductive film 680 includes conductive film 680c that covers n-electrode N15 and is electrically connected to n-electrode N15, conductive film 680e that covers portion N14a of n-electrode N14 and is electrically connected to portion N14a, conductive film 680d that covers portion N14b of n-electrode N14 and is electrically connected to portion N14b, conductive film 680a that connects conductive film 680c and conductive film 680d, and conductive film 680b that connects conductive film 680c and conductive film 680e.

N-electrode N14 includes portion N14b covered with conductive film 680d and having the same shape as that of conductive film 680d, portion N14a covered with conductive film 680e, electrically connected to conductive film 680e, and having the same shape as that of conductive film 680e, portion N14c that connects portion N14a and portion N14b, and portion N14d connected to portion N14a.

Conductive film 679 includes conductive film 679d that covers portion P12a of p-electrode P12 and is electrically connected to portion P12a, conductive film 679c that covers portion P12c of p-electrode P12 and is electrically connected to portion P12c, conductive film 679a that connects conductive film 679c and conductive film 678a, and conductive film 679b that connects conductive film 679d and conductive film 678a.

Note that conductive film 678a is a portion of conductive film 678 that covers n-electrode N13 and is electrically connected to n-electrode N13.

P-electrode P12 includes portion P12a covered with conductive film 679d and having the same shape as that of conductive film 679d, portion P12c covered with conductive film 679c, electrically connected to conductive film 679c, and having the same shape as that of conductive film 679c, portion P12b that connects portion P12a and portion P12c, and portion P12d connected to portion P12c.

Conductive film 675 includes conductive film 675d that covers portion P10a of p-electrode P10 and is electrically connected to portion P10a, conductive film 675c that covers portion P10c of p-electrode P10 and is electrically connected to portion P10c, conductive film 675e that covers dummy electrode B and is electrically connected to dummy electrode B, conductive film 675a that connects conductive film 675c and conductive film 675e, and conductive film 675b that connects conductive film 675d and conductive film 675e.

Portions of the undersurface of semiconductor laser array element 106 where the conductive films are not exposed are covered with protective film 350. Note that dummy electrode B has a shape the same as that of conductive film 675e.

With the above configuration, for example, the flow of current in semiconductor laser array element 106 is as follows: dummy electrode B → conductive film 675 → p-electrode P10 → n-electrodes N10 and N11 → conductive film 677 → p-electrode P11 → n-electrodes N12 and N13 → conductive film 679 → p-electrode P12 → n-electrodes N14 and N15.

Note that current from p-electrode P10 to conductive film 677 flows through a path that is p-electrode P10 → n-electrode N11 → conductive film 677, and through a path that is p-electrode P10 → n-electrode N10 → conductive film 676 → conductive film 677. Similarly, current from p-electrode P11 to conductive film 679 flows through a path that is p-electrode P11 → n-electrode N13 → conductive film 679, and through a path that is p-electrode P11 → n-electrode N12 → conductive film 678 → conductive film 679. Similarly, current from p-electrode P12 to conductive film 680 flows through a path that is p-electrode P12 → n-electrode N14 → conductive film 680d (conductive film 680e) → conductive film 680a (conductive film 680b) →conductive film 680c, and through a path that is p-electrode P10 → n-electrode N15 → conductive film 680c.

Accordingly, also in semiconductor laser array element 106, plural semiconductor laser elements 116 are connected in series not via the patterned wirings formed on the base on which semiconductor laser array element 106 is mounted.

Semiconductor laser array element 106 includes conductive films 675 to 680, insulating films 916 to 921, and protective films 956 to 961, the numbers of which are each two or more. Specifically, each of conductive films 675 to 680 and insulating films 916 to 921 is formed with a plurality of films and each set of films is aligned in the Y-axis direction.

As described above, in this variation, a first conductor (conductive film 677 in this variation) is formed on first surface 40.

According to this, p-electrode P11 and n-electrode N11 can be electrically connected over a shorter distance.

For example, conductive film 677 is formed on n-electrode N12 with a first insulating film (insulating film 918) being provided therebetween.

According to this, n-electrode N12 and conductive film 677 can be electrically insulated.

For example, plural conductive films 677 are formed in the Y-axis direction.

According to this, current can be caused to flow through p-electrode P11 and n-electrode N11 uniformly in the Y-axis direction. For example, when a single first conductor is provided, there is a problem that most of the current flows through p-electrode P11 and n-electrode N11 in the vicinity of the first conductor. However, the above configuration can reduce the occurrence of the problem that most of the current flows through p-electrode P11 and n-electrode N11 in the vicinity of the first conductor, and can cause current to flow through p-electrode P11 and n-electrode N11 uniformly in the Y-axis direction.

For example, a second conductor (conductive film 678 in this variation) is formed on first surface 40.

According to this, n-electrode N12 and n-electrode N13 can be electrically connected over a shorter distance.

For example, conductive film 678 is formed on p-electrode P11 with a second insulating film (insulating film 919) being provided therebetween.

According to this, p-electrode P11 and conductive film 678 can be electrically insulated.

For example, plural conductive films 678 are formed in the Y-axis direction.

According to this, current can be caused to flow through n-electrode N12 and n-electrode N13 uniformly in the Y-axis direction. For example, when a single second conductor is provided, there is a problem that most of the current flows through n-electrode N12 and n-electrode N13 in the vicinity of the second conductor. However, the above configuration can reduce the occurrence of the problem that most of the current flows through n-electrode N12 and n-electrode N13 in the vicinity of the second conductor, and can cause current to flow through n-electrode N12 and n-electrode N13 uniformly in the Y-axis direction.

For example, conductive film 677 is formed on n-electrode N12 with insulating film 918 being provided therebetween, and conductive film 678 is formed on other conductivity type semiconductor layer 321 with insulating film 919 being provided therebetween. For example, conductive film 677 and conductive film 678 do not overlap in the Y-axis direction.

According to this, the first conductor and the second conductor can be prevented from being in contact with each other.

### Embodiment 7

Next, an array type semiconductor laser device according to Embodiment 7 is to be described. Note that in the description of the array type semiconductor laser device according to Embodiment 7, differences from the array type semiconductor laser devices according to Embodiments 1 to 6 are mainly described, and a description of similar structural elements to those of the array type semiconductor laser devices according to Embodiments 1 to 6 may be omitted while substantially the same reference signs are given thereto.

### Configuration

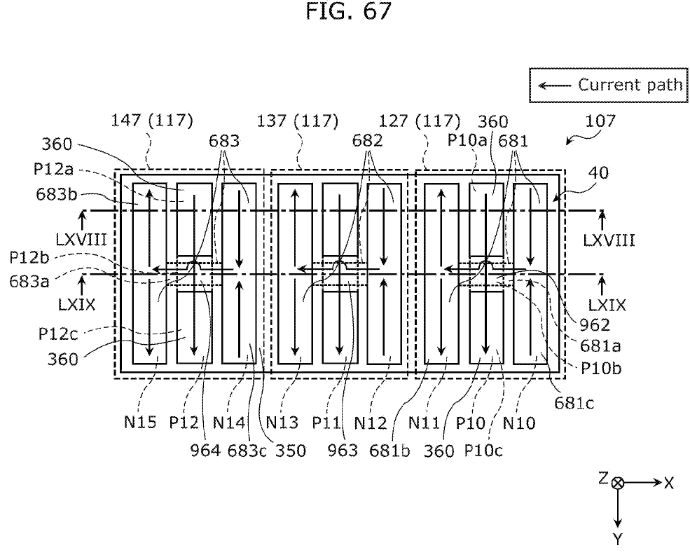

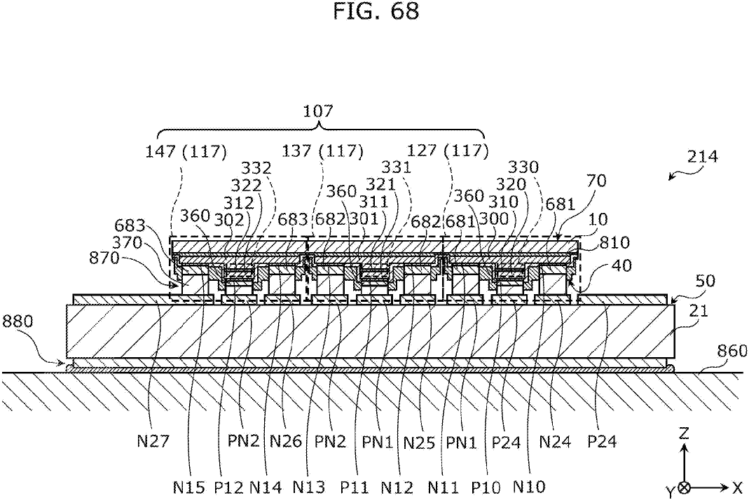

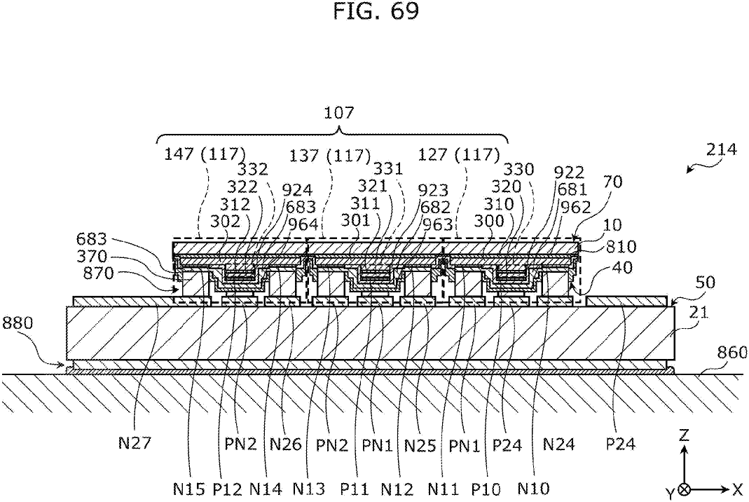

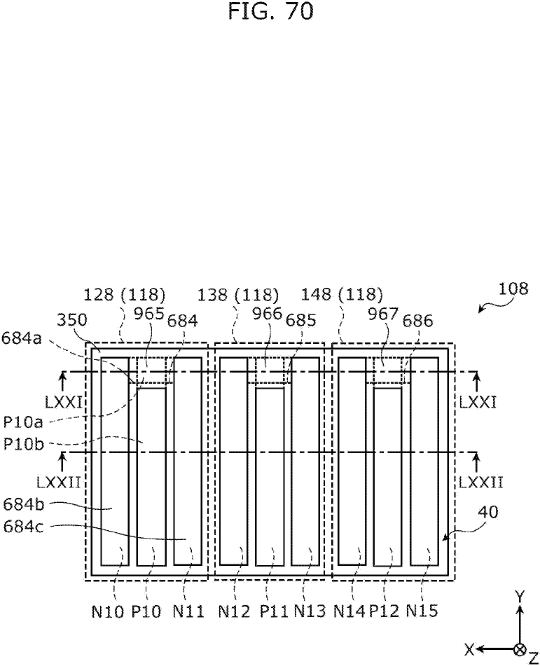

FIG. 66 is a top view illustrating array type semiconductor laser device 214 according to Embodiment 7. FIG. 67 is a bottom view illustrating semiconductor laser array element 107 according to Embodiment 7. FIG. 68 is a cross sectional view illustrating array type semiconductor laser device 214 according to Embodiment 7, which is taken along line LXVIII-LXVIII in FIG. 66 and FIG. 67. FIG. 69 is a cross sectional view of array type semiconductor laser device 214 according to Embodiment 7, which includes a second conductor and is taken along line LXIX-LXIX in FIG. 66 and FIG. 67.

Array type semiconductor laser device 214 includes substrate 10, semiconductor laser array element 107, and base 21 (a first base).

Semiconductor laser array element 107 includes semiconductor laser elements 117. Specifically, semiconductor laser array element 107 includes semiconductor laser element 127 (a first semiconductor laser element), semiconductor laser element 137 (a second semiconductor laser element), and semiconductor laser element 147 (a third semiconductor laser element). Semiconductor laser array element 107 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction.

Specifically, semiconductor laser element 127 includes n-electrode N10, p-electrode P10, and n-electrode N11. Semiconductor laser element 137 includes n-electrode N12, p-electrode P11, and n-electrode N13. Semiconductor laser element 147 includes n-electrode N14, p-electrode P12, and n-electrode N15.

Note that when a common description that applies to all semiconductor laser elements 127, 137, and 147 is given, semiconductor laser element 127, semiconductor laser element 137, and semiconductor laser element 147 may be simply referred to as semiconductor laser element(s) 117.

Semiconductor laser array element 107 further includes conductive films 681 to 683, insulating films 922 to 924, and protective films 962 to 964, in addition to the configuration of semiconductor laser array element 100.

Conductive films 681 to 683 are electrically conductive films. Conductive films 681 to 683 are formed on first surface 40 of semiconductor laser array element 107. Conductive films 681 to 683 are electrically connected to electrodes included in semiconductor laser array element 107.

For example, conductive film 681 is electrically connected to n-electrode N10 and n-electrode N11. For example, conductive film 682 is electrically connected to n-electrode N12 and n-electrode N13. For example, conductive film 683 is electrically connected to n-electrode N14 and n-electrode N15.

Conductive films 681 to 683 each electrically connect two n-electrodes included in semiconductor laser element 117, and thus current readily uniformly flows through the two n-electrodes.

Insulating films 922 to 924 are insulating films for electrically insulating the electrodes included in semiconductor laser array element 107 from conductive films 681 to 683.

In Embodiment 7, conductive films 681 to 683 are each connected to two electrodes included in semiconductor laser element 117, in a substantially center of the two n-electrodes in the Y-axis direction.

For example, insulating film 922 is located between p-electrode P10 and conductive film 681, and electrically insulates p-electrode P10 from conductive film 681. Specifically, conductive film 681 is formed below p-electrode P10 with insulating film 922 being provided therebetween.

For example, insulating film 923 is located between p-electrode P11 and conductive film 682, and electrically insulates p-electrode P11 from conductive film 682. Specifically, conductive film 682 is formed below p-electrode P11 with insulating film 923 being provided therebetween.

For example, insulating film 924 is located between p-electrode P12 and conductive film 683, and electrically insulates p-electrode P12 from conductive film 683. Specifically, conductive film 683 is formed below p-electrode P12 with insulating film 923 being provided therebetween.

Protective films 962 to 964 are insulating films for electrically insulating conductive films 681 to 683 from wirings (p-wiring P24, pn-wiring PN1, and pn-wiring PN2) with connection layer 370 being provided therebetween.

For example, protective film 962 is located between conductive film 681 and connection layer 370 above p-wiring P24, and electrically insulates conductive film 681 from p-wiring P24.

For example, protective film 963 is located between conductive film 682 and connection layer 370 above pn-wiring PN1, and electrically insulates conductive film 682 from pn-wiring PN1.

For example, protective film 964 is located between conductive film 683 and connection layer 370 above pn-wiring PN2, and electrically insulates conductive film 683 from pn-wiring PN2.

When semiconductor laser array element 107 is viewed from the undersurface, conductive film 681 includes conductive film 681c that covers n-electrode N10 and is electrically connected to n-electrode N10, conductive film 681b that covers n-electrode N11 and is electrically connected to n-electrode N11, and conductive film 681a that connects conductive film 681b and conductive film 681c.

P-electrode P10 includes portion P10a covered with wiring electrode 360, electrically connected to wiring electrode 360, and having the same shape as that of wiring electrode 360, portion P10c covered with wiring electrode 360, electrically connected to wiring electrode 360, and having the same shape as that of wiring electrode 360, and portion P10b that connects portion P10a and portion P10c. Portions of the undersurface of semiconductor laser array element 107 where the conductive films are not exposed are covered with protective film 350.

As illustrated in FIG. 69, p-electrode P10b, insulating film 922, conductive film 681a, and protective film 962 are formed in the order from the other conductivity type semiconductor layer 320 side, in a portion in which conductive film 681a and p-electrode P10b are stacked.

Conductive patterned wirings (p-wiring P24, n-wirings N24 to N27, and pn-wirings PN1 and PN2) are formed on base 21.

Center portion P24c of p-wiring P24, center portion PN1c of pn-wiring PN1, and center portion PN2c of pn-wiring PN2 are exposed from backward ends of semiconductor laser array element 107 in the Y-axis direction (end portions on the negative side of the Y-axis direction in the present embodiment).

With the above configuration, for example, the flow of current through array type semiconductor laser device 214 starts from p-wiring P24 that is an anode electrode, and is as follows: p-wiring P24 →p-electrode P10 →n-electrodes N10 and N11 → pn-wiring PN1 → p-electrode P11 →n-electrodes N12 and N13 → pn-wiring PN2 →p-electrode P12 →n-electrodes N14 and N15 → n-wiring N27 that is a cathode electrode.

Note that current from p-electrode P10 to pn-wiring PN1 flows through a path that is p-electrode P10 → n-electrode N11 → pn-wiring PN1, and through a path that is p-electrode P10 → n-electrode N10 → conductive film 681 → pn-wiring PN1. Similarly, current from p-electrode P11 to pn-wiring PN2 flows through a path that is p-electrode P11 → n-electrode N13 → pn-wiring PN2, and through a path that is p-electrode P11 → n-electrode N12 → conductive film 682 → pn-wiring PN2. Similarly, current from p-electrode P12 to n-wiring N27 flows through a path that is p-electrode P12 → n-electrode N15 → n-wiring N27, and through a path that is p-electrode P10 → n-electrode N14 → conductive film 683 → n-wiring N27.

According to this, semiconductor laser array element 107 can be provided with some of the wirings that connect semiconductor laser elements 117 in series, and base 21 can be provided with the remaining wirings. Accordingly, the structure can be simplified by, for instance, omitting wirings such as wires on base 21.

### Variation

Next, a variation of the array type semiconductor laser device according to Embodiment 7 is to be described. Note that in the variation described in the following, differences from the elements included in the array type semiconductor laser device according to Embodiment 7 are to be mainly described, and a description of the same elements may be simplified or omitted.

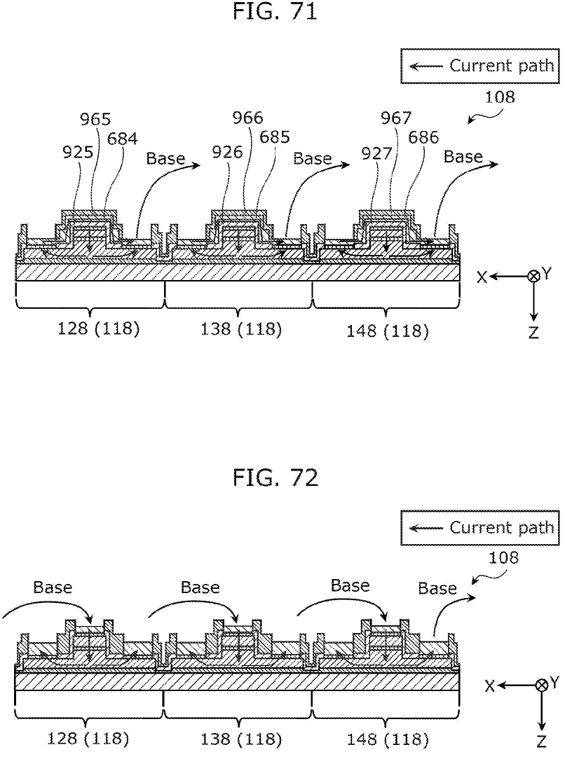

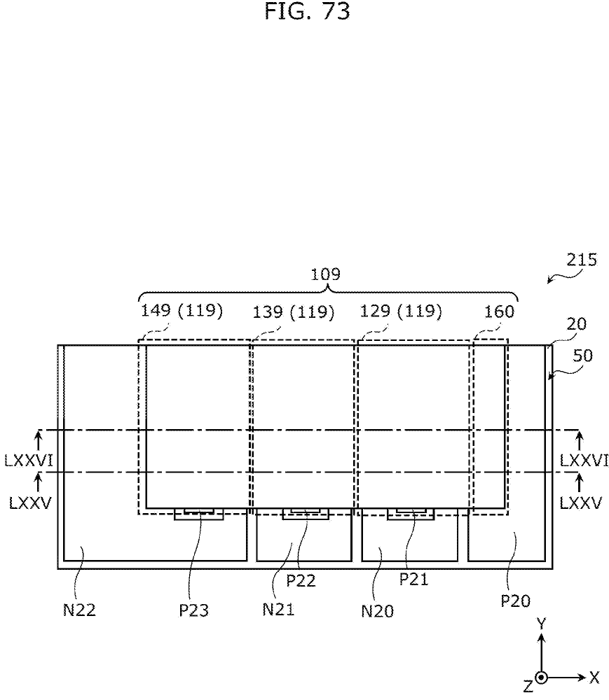

FIG. 70 is a bottom view illustrating semiconductor laser array element 108 according to a variation of Embodiment 7. FIG. 71 is a cross sectional view of semiconductor laser array element 108 according to the variation of Embodiment 7, which includes a first conductor and is taken along line LXXI-LXXI in FIG. 70. FIG. 72 is a cross sectional view illustrating semiconductor laser array element 108 according to the variation of Embodiment 7, which is taken along line LXXII-LXXII in FIG. 70.

Note that although not illustrated, semiconductor laser array element 108 is mounted on base 21, similarly to semiconductor laser array element 107.

Semiconductor laser array element 108 includes plural semiconductor laser elements 118. Specifically, semiconductor laser array element 108 includes semiconductor laser element 128 (a first semiconductor laser element), semiconductor laser element 138 (a second semiconductor laser element), and semiconductor laser element 148 (a third semiconductor laser element). Semiconductor laser array element 108 includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction.

Specifically, semiconductor laser element 128 includes n-electrode N10, p-electrode P10, and n-electrode N11. Semiconductor laser element 138 includes n-electrode N12, p-electrode P11, and n-electrode N13. Semiconductor laser element 148 includes n-electrode N14, p-electrode P12, and n-electrode N15.

Note that when a common description that applies to all semiconductor laser elements 128, 138, and 148 is given, semiconductor laser element 128, semiconductor laser element 138, and semiconductor laser element 148 may be simply referred to as semiconductor laser element(s) 118.

Semiconductor laser array element 108 further includes conductive films 684 to 686, insulating films 925 to 927, and protective films 965 to 967, in addition to the configuration of semiconductor laser array element 100.

Conductive films 684 to 686 are electrically conductive films. Conductive films 684 to 686 are formed on first surface 40 of semiconductor laser array element 108. Conductive films 684 to 686 are electrically connected to electrodes included in semiconductor laser array element 108.

For example, conductive film 684 is electrically connected to n-electrode N10 and n-electrode N11. For example, conductive film 685 is electrically connected to n-electrode N12 and n-electrode N13. For example, conductive film 686 is electrically connected to n-electrode N14 and n-electrode N15.

Conductive films 684 to 686 each electrically connect two n-electrodes included in semiconductor laser element 118, and thus current readily uniformly flows through the two n-electrodes.

In this variation, conductive films 684 to 686 are each connected to two electrodes included in semiconductor laser element 118, in end portions of the two n-electrodes in the Y-axis direction.

As described above, the layout in which conductive films each connected to two n-electrodes included in the semiconductor laser element are disposed is not limited in particular.

Insulating films 925 to 927 are insulating films for electrically insulating the plurality of electrodes included in semiconductor laser array element 108 from conductive films 684 to 686.

For example, insulating film 925 is located between p-electrode P10 and conductive film 684, and electrically insulates p-electrode P10 from conductive film 684. Specifically, conductive film 684 is formed below p-electrode P10 with insulating film 925 being provided therebetween.

For example, insulating film 926 is located between p-electrode P11 and conductive film 685, and electrically insulates p-electrode P11 from conductive film 685. Specifically, conductive film 685 is formed below p-electrode P11 with insulating film 926 being provided therebetween.

For example, insulating film 927 is located between p-electrode P12 and conductive film 686, and electrically insulates p-electrode P12 from conductive film 686. Specifically, conductive film 686 is formed below p-electrode P12 with insulating film 927 being provided therebetween.

Protective films 965 to 967 are insulating films for electrically insulating conductive films 684 to 686 from wirings (p-wiring P24, pn-wiring PN1, and pn-wiring PN2) via connection layer 370.

For example, protective film 965 is located between conductive film 684 and connection layer 370 above p-wiring P24, and electrically insulates conductive film 684 from p-wiring P24.

For example, protective film 966 is located between conductive film 685 and connection layer 370 above pn-wiring PN1, and electrically insulates conductive film 685 from pn-wiring PN1.

For example, protective film 967 is located between conductive film 686 and connection layer 370 above pn-wiring PN2, and electrically insulates conductive film 686 and pn-wiring PN2.

When semiconductor laser array element 108 is viewed from the undersurface, conductive film 684 includes conductive film 684b that covers n-electrode N10 and is electrically connected to n-electrode N10, conductive film 684c that covers n-electrode N11 and is electrically connected to n-electrode N11, and conductive film 684a that connects conductive film 684b and conductive film 684c. P-electrode P10 includes portion P10b covered with wiring electrode 360, electrically connected to wiring electrode 360, and having the same shape as that of wiring electrode 360, and portion P10a connected to portion P10b. Portions of the undersurface of semiconductor laser array element 108 where the conductive films are not exposed are covered with protective film 350.

With the above configuration, for example, the flow of current through semiconductor laser array element 108 starts from p-wiring P24 that is an anode electrode, and is as follows: p-wiring P24 → p-electrode P10 →n-electrodes N10 and N11 → pn-wiring PN1 → p-electrode P11 → n-electrodes N12 and N13 → pn-wiring PN2 → p-electrode P12 → n-electrodes N14 and N15 → n-wiring N27 that is a cathode electrode.

Note that current from p-electrode P10 to pn-wiring PN1 flows through a path that is p-electrode P10 → n-electrode N11 → pn-wiring PN1, and through a path that is p-electrode P10 → n-electrode N10 → conductive film 684 → pn-wiring PN1. Similarly, current from p-electrode P11 to pn-wiring PN2 flows through a path that is p-electrode P11 → n-electrode N13 → pn-wiring PN2, and through a path that is p-electrode P11 → n-electrode N12 → conductive film 685 → pn-wiring PN2. Similarly, current from p-electrode P12 to n-wiring N27 flows through a path that is p-electrode P12 → n-electrode N15 → n-wiring N27, and through a path that is p-electrode P10 → n-electrode N14 → conductive film 686 → n-wiring N27.

According to this, similarly to Embodiment 7, semiconductor laser array element 108 can be provided with some of the wirings that connect plural semiconductor laser elements 118 in series, and base 21 can be provided with the remaining wirings. Accordingly, the structure can be simplified by, for instance, omitting wirings such as wires on base 21.

### Embodiment 8

Next, an array type semiconductor laser device according to Embodiment 8 is to be described. Note that in the description of the array type semiconductor laser device according to Embodiment 8, differences from the array type semiconductor laser devices according to Embodiments 1 to 7 are mainly described, and a description of similar structural elements to those of the array type semiconductor laser devices according to Embodiments 1 to 7 may be omitted while substantially the same reference signs are given thereto.

### Configuration

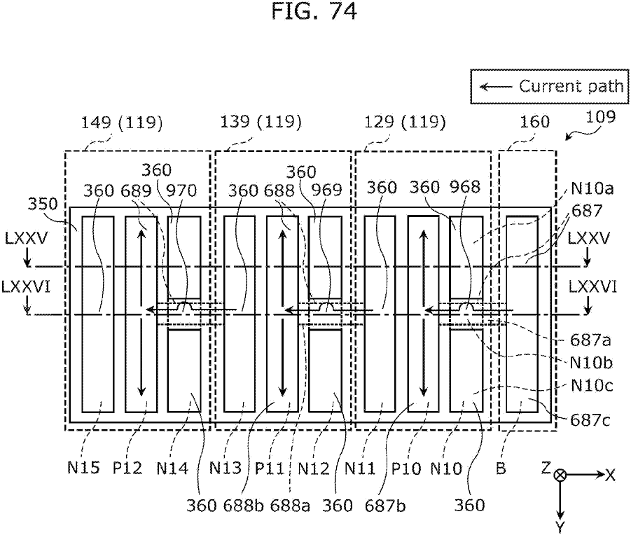

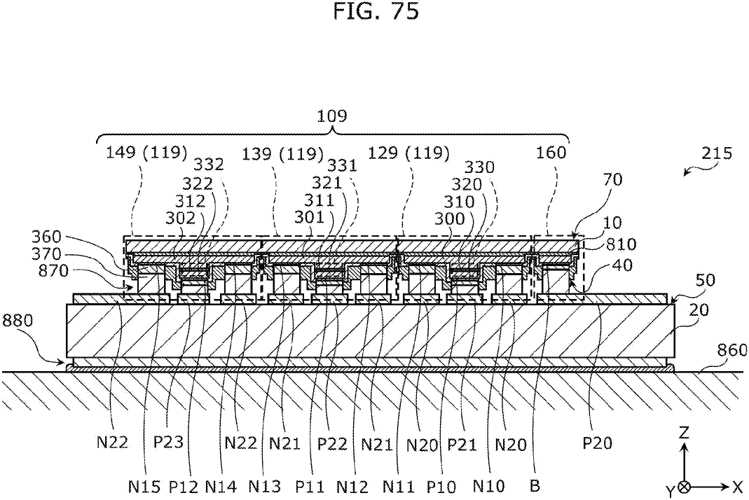

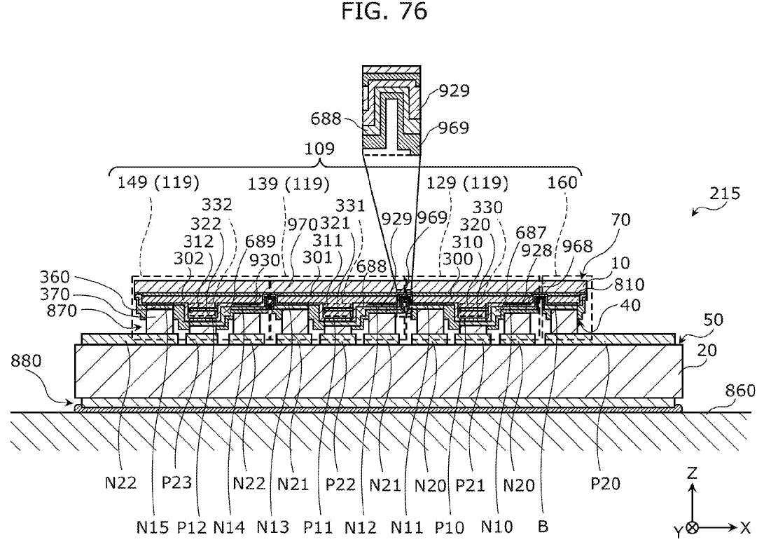

FIG. 73 is a top view illustrating array type semiconductor laser device 215 according to Embodiment 8. FIG. 74 is a bottom view illustrating semiconductor laser array element 109 according to Embodiment 8. FIG. 75 is a cross sectional view illustrating array type semiconductor laser device 215 according to Embodiment 8, which is taken along line LXXV-LXXV in FIG. 73 and FIG. 74. FIG. 76 is a cross sectional view of array type semiconductor laser device 215 according to Embodiment 8, which includes a first conductor and is taken along line LXXVI-LXXVI in FIG. 73 and FIG. 74.

Array type semiconductor laser device 215 includes substrate 10, semiconductor laser array element 109, and base 20 (a first base).

Semiconductor laser array element 109 includes plural semiconductor laser elements 119. Specifically, semiconductor laser array element 109 includes semiconductor laser element 129 (a first semiconductor laser element), semiconductor laser element 139 (a second semiconductor laser element), and semiconductor laser element 149 (a third semiconductor laser element). Semiconductor laser array element 109 includes dummy electrode B, n-electrode N10, p-electrode P10, n-electrode N11, n-electrode N12, p-electrode P11, n-electrode N13, n-electrode N14, p-electrode P12, and n-electrode N15 in the order from the positive side of the X-axis direction.

Specifically, semiconductor laser element 129 includes n-electrode N10, p-electrode P10, and n-electrode N11. Semiconductor laser element 139 includes n-electrode N12, p-electrode P11, and n-electrode N13. Semiconductor laser element 149 includes n-electrode N14, p-electrode P12, and n-electrode N15.

Note that when a common description that applies to all semiconductor laser elements 129, 139, and 149 is given, semiconductor laser element 129, semiconductor laser element 139, and semiconductor laser element 149 may be simply referred to as semiconductor laser element(s) 119.

Semiconductor laser array element 109 further includes dummy portion 160, conductive films 687 to 689, insulating films 928 to 930, and protective films 968 to 970, in addition to the configuration of semiconductor laser array element 100.

Dummy portion 160 is an electrode aligned with plural semiconductor laser elements 119, and connected to p-wiring P20 included in patterned wirings formed on second surface 50 of base 20.

Conductive films 687 to 689 are electrically conductive films. Conductive films 687 to 689 are formed on first surface 40 of semiconductor laser array element 109. Conductive films 687 to 689 are electrically connected to electrodes included in semiconductor laser array element 109.

For example, conductive film 687 is electrically connected to dummy electrode B and p-electrode P10. For example, conductive film 688 is electrically connected to n-electrode N11 and p-electrode P11. For example, conductive film 689 is electrically connected to n-electrode N13 and p-electrode P12.

Conductive films 687 to 689 each connect adjacent semiconductor laser elements 119 in series, and thus the arrangement of wirings can be simplified.

Insulating films 928 to 930 are insulating films for electrically insulating a plurality of electrodes included in semiconductor laser array element 109 from conductive films 687 to 689.

For example, insulating film 928 is located between n-electrode N10 and conductive film 687, and electrically insulates n-electrode N10 from conductive film 687. Specifically, conductive film 687 is formed below n-electrode N10 with insulating film 928 being provided therebetween.

Conductive films 687 to 689 are each connected to two electrodes out of the plurality of electrodes included in semiconductor laser array element 109, in a substantially center of the plurality of electrodes in the Y-axis direction.

For example, insulating film 929 is located between n-electrode N12 and conductive film 688, and electrically insulates n-electrode N12 from conductive film 688. Specifically, conductive film 688 is formed below n-electrode N12 with insulating film 929 being provided therebetween.

For example, insulating film 930 is located between n-electrode N14 and conductive film 689, and electrically insulates n-electrode N14 from conductive film 689. Specifically, conductive film 689 is formed below n-electrode N14 with insulating film 930 being provided therebetween.

Protective films 968 to 970 are insulating films for electrically insulating conductive films 687 to 689 from wirings (n-wiring N22, n-wiring N21, and n-wiring N20) via connection layer 370.

For example, protective film 968 is located between conductive film 687 and connection layer 370 above n-wiring N20, and electrically insulates conductive film 687 from n-wiring N20.

For example, protective film 969 is located between conductive film 688 and connection layer 370 above n-wiring N21, and electrically insulates conductive film 688 from n-wiring N21.

For example, protective film 970 is located between conductive film 689 and connection layer 370 above n-wiring N22, and electrically insulates conductive film 689 from n-wiring N22.

As illustrated in FIG. 74, when semiconductor laser array element 109 is viewed from the undersurface, n-electrode N11 is covered with wiring electrode 360, has the same shape as that of wiring electrode 360, and is electrically connected to wiring electrode 360.

Conductive film 688 includes conductive film 688b that covers p-electrode P11 and is electrically connected to p-electrode P11, and conductive film 688a that connects wiring electrode 360 that covers n-electrode N11 to conductive film 688b.

Conductive film 687 includes conductive film 687b that covers p-electrode P10 and is electrically connected to p-electrode P10, conductive film 687c that covers dummy electrode B and is electrically connected to dummy electrode B, and conductive film 687a that connects conductive film 687b and conductive film 687c.

N-electrode N10 includes portion N10a covered with wiring electrode 360, electrically connected to wiring electrode 360, and having the same shape as that of wiring electrode 360, portion N10c covered with wiring electrode 360, electrically connected to wiring electrode 360, and having the same shape as that of wiring electrode 360, and portion N10b that connects portion N10a and portion N10c. Portions of the undersurface of semiconductor laser array element 109 where the conductive films are not exposed are covered with protective film 350. Note that dummy electrode B has a shape the same as that of conductive film 687c.

As illustrated in FIG. 76, n-electrode N10b, insulating film 340, conductive film 687a, and protective film 968 are formed in the order from the one conductivity type semiconductor layer 300 side, in a portion in which conductive film 687a and n-electrode N10b are stacked.

As illustrated in FIG. 4, conductive patterned wirings (p-wirings P20, P21, P22, and P23 and n-wirings N20, N21, and N22) are formed on base 20.

Center portion N20c of n-wiring N20, center portion N21c of n-wiring N21, and center portion N22c of n-wiring N22 are exposed from backward ends of semiconductor laser array element 109 in the Y-axis direction (end portions on the negative side of the Y-axis direction in the present embodiment).

With the above configuration, for example, the flow of current through array type semiconductor laser device 215 starts from p-wiring P20 that is an anode electrode, and is as follows: p-wiring P20 → dummy electrode B →conductive film 687 → p-electrode P10 → n-electrodes N10 and N11 → conductive film 688 → p-electrode P11 → n-electrodes N12 and N13 → conductive film 689 → p-electrode P12 → n-electrodes N14 and N15 → n-wiring N22 that is a cathode electrode.

Note that current from p-electrode P10 to conductive film 688 flows through a path that is p-electrode P10 → n-electrode N11 → conductive film 688, and through a path that is p-electrode P10 → n-electrode N10 → n-wiring N20 → conductive film 688. Similarly, current from p-electrode P11 to conductive film 689 flows through a path that is p-electrode P11 → n-electrode N13 → conductive film 689, and through a path that is p-electrode P11 → n-electrode N12 → n-wiring N21 → conductive film 689. Similarly, current from p-electrode P12 to n-wiring N22 flows through a path that is p-electrode P12 → n-electrode N15 → n-wiring N22, and through a path that is p-electrode P10 → n-electrode N14 → n-wiring N22.

According to this, semiconductor laser array element 109 can be provided with some of the wirings that connect plural semiconductor laser elements 119 in series, and base 20 can be provided with the remaining wirings. Accordingly, the structure can be simplified by, for instance, omitting wirings such as wires on base 20.

### Variation

Next, a variation of the array type semiconductor laser device according to Embodiment 8 is to be described. Note that in the variation described in the following, differences from the elements included in the array type semiconductor laser device according to Embodiment 8 are to be mainly described, and a description of the same elements may be simplified or omitted.

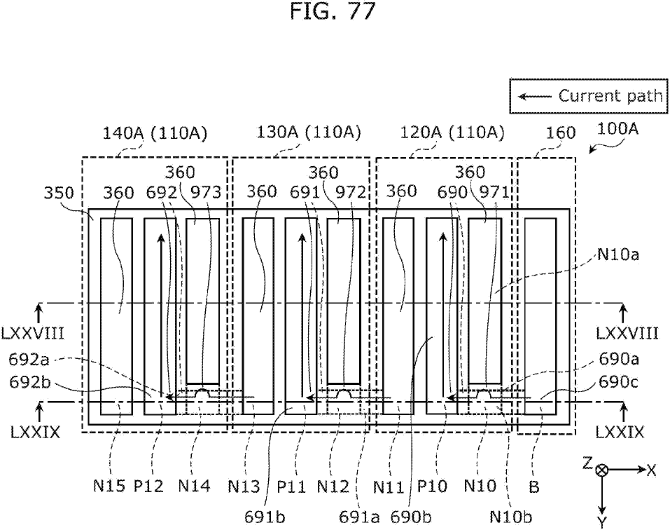

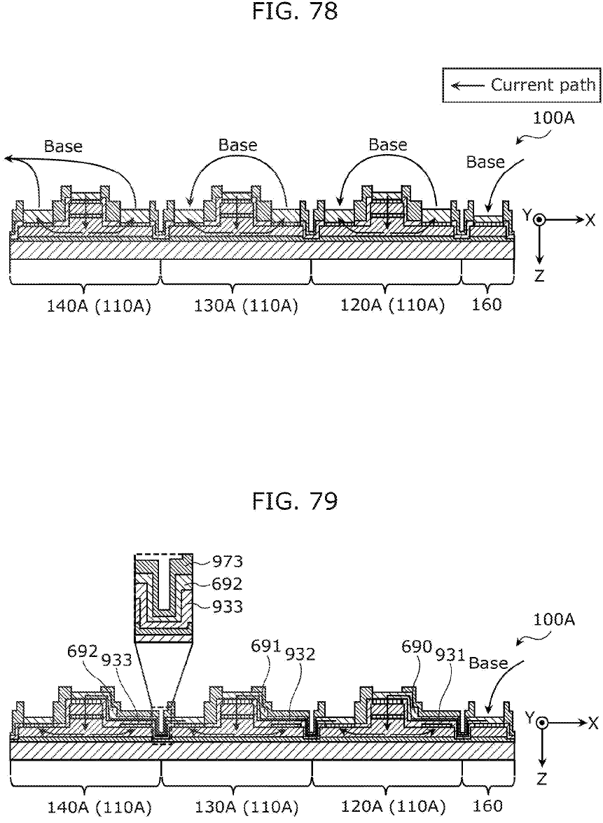

FIG. 77 is a bottom view illustrating semiconductor laser array element 100A according to a variation of Embodiment 8. FIG. 78 is a cross sectional view illustrating semiconductor laser array element 100A according to the variation of Embodiment 8, which is taken along line LXXVIII-LXXVIII in FIG. 77. FIG. 79 is a cross sectional view illustrating semiconductor laser array element 100A according to the variation of Embodiment 8, which is taken along line LXXIX-LXXIX in FIG. 77.

Note that although not illustrated, semiconductor laser array element 100A is mounted on base 20, similarly to semiconductor laser array element 109.

Semiconductor laser array element 100A includes plural semiconductor laser elements 110A. Specifically, semiconductor laser array element 100A includes semiconductor laser element 120A (a first semiconductor laser element), semiconductor laser element 130A (a second semiconductor laser element), and semiconductor laser element 140A (a third semiconductor laser element). Semiconductor laser array element 100A includes n-electrode N10, p-electrode P10, n-electrode N11, n-electrode N12, p-electrode P11, n-electrode N13, n-electrode N14, p-electrode P12, and n-electrode N15 in the order from the positive side of the X-axis direction. Semiconductor laser element 120A includes n-electrode N10, p-electrode P10, and n-electrode N11, semiconductor laser element 100A includes n-electrode N12, p-electrode P11, and n-electrode N13, and semiconductor laser element 140A includes n-electrodeN14, p-electrode P12, and n-electrode N15.

Note that when a common description that applies to all semiconductor laser elements 120A, 100A, and 140A is given, semiconductor laser element 120A, semiconductor laser element 100A, and semiconductor laser element 140A may be simply referred to as semiconductor laser element(s) 110A.

Semiconductor laser array element 100A further includes dummy portion 160, conductive films 690 to 692, insulating films 931 to 933, and protective films 971 to 973, in addition to the configuration of semiconductor laser array element 100.

Dummy portion 160 is aligned with plural semiconductor laser elements 110A.

Conductive films 690 to 692 are electrically conductive films. Conductive films 690 to 692 are formed on first surface 40 of semiconductor laser array element 100A. Conductive films 690 to 692 are electrically connected to electrodes included in semiconductor laser array element 100A.

For example, conductive film 690 is electrically connected to dummy electrode B and p-electrode P10. For example, conductive film 691 is electrically connected to n-electrode N11 and p-electrode P11. For example, conductive film 692 is electrically connected to n-electrode N13 and p-electrode P12.

Similarly to Embodiment 8, also in this variation, conductive films 690 to 692 each connect adjacent semiconductor laser elements 110A in series, and thus the arrangement of wirings can be simplified.

In this variation, conductive films 690 to 692 are each connected to two electrodes out of a plurality of electrodes included in semiconductor laser element 110A, in end portions of the plurality of electrodes in the Y-axis direction.

As described above, the layout in which conductive films connected to the electrodes included in the semiconductor laser elements are disposed is not limited in particular.

Insulating films 931 to 933 are insulating films for electrically insulating the plurality of electrodes included in semiconductor laser array element 100A from conductive films 690 to 692.

For example, insulating film 931 is located between n-electrode N10 and conductive film 690, and electrically insulates n-electrode N10 from conductive film 690. Specifically, conductive film 690 is formed below n-electrode N10 with insulating film 931 being provided therebetween.

For example, insulating film 932 is located between n-electrode N12 and conductive film 691, and electrically insulates n-electrode N12 from conductive film 691. Specifically, conductive film 691 is formed below n-electrode N12 with insulating film 932 being provided therebetween.

For example, insulating film 933 is located between n-electrode N14 and conductive film 692, and electrically insulates n-electrode N14 and conductive film 692. Specifically, conductive film 692 is formed below n-electrode N14 with insulating film 933 being provided therebetween.

Protective films 971 to 973 are insulating films for electrically insulating conductive films 690 to 692 from wirings (n-wiring N22, n-wiring N21, and n-wiring N20) via connection layer 370.

For example, protective film 971 is located between conductive film 690 and connection layer 370 above n-wiring N20, and electrically insulates conductive film 690 from n-wiring N20.

For example, protective film 972 is located between conductive film 691 and connection layer 370 above n-wiring N21, and electrically insulates conductive film 691 from n-wiring N21.

For example, protective film 973 is located between conductive film 692 and connection layer 370 above n-wiring N22, and electrically insulates conductive film 692 from n-wiring N22.

As illustrated in FIG. 77, when semiconductor laser array element 100A is viewed from the undersurface, n-electrode N11 is covered with wiring electrode 360, has the same shape as that of wiring electrode 360, and is electrically connected to wiring electrode 360.

Conductive film 691 includes conductive film 691b that covers p-electrode P11 and is electrically connected to p-electrode P11, and conductive film 691a that connects wiring electrode 360 that covers n-electrode N11 to conductive film 691b.

Conductive film 690 includes conductive film 690b that covers p-electrode P10 and is electrically connected to p-electrode P10, conductive film 690c that covers dummy electrode B and is electrically connected to dummy electrode B, and conductive film 690a that connects conductive film 690b and conductive film 690c.

N-electrode N10 includes portion N10a covered with wiring electrode 360, electrically connected to wiring electrode 360, and having the same shape as that of wiring electrode 360, and portion N10b connected to portion N10a.

Portions of the undersurface of semiconductor laser array element 100A where the conductive films are not exposed are covered with protective film 350. Note that dummy electrode B has a shape the same as that of conductive film 690c.

With the above configuration, for example, the flow of current through semiconductor laser array element 100A starts from p-wiring P20 that is an anode electrode, and is as follows: p-wiring P20 → dummy electrode B → conductive film 690 → p-electrode P10 → n-electrodes N10 and N11 → conductive film 691 → p-electrode P11 → n-electrodes N12 and N13 → conductive film 692 → p-electrode P12 → n-electrodes N14 and N15 → n-wiring N22 that is a cathode electrode.

Note that current from p-electrode P10 to conductive film 691 flows through a path that is p-electrode P10 → n-electrode N11 → conductive film 691, and through a path that is p-electrode P10 → n-electrode N10 → n-wiring N20 → conductive film 691. Similarly, current from p-electrode P11 to conductive film 692 flows through a path that is p-electrode P11 → n-electrode N13 → conductive film 692, and through a path that is p-electrode P11 → n-electrode N12 → n-wiring N21 → conductive film 692. Similarly, current from p-electrode P12 to n-wiring N22 flows through a path that is p-electrode P12 → n-electrode N15 → n-wiring N22, and through a path that is p-electrode P10 → n-electrode N14 → n-wiring N22.

According to this, similarly to Embodiment 8, semiconductor laser array element 100A can be provided with some of the wirings that connect plural semiconductor laser elements 110A in series, and base 20 can be provided with the remaining wirings. Accordingly, the structure can be simplified by, for instance, omitting wirings such as wires on base 20.

### Other Embodiments

The above has described the array type semiconductor laser devices according to the present disclosure based on the embodiments and the variations, yet the present disclosure is not limited to the embodiments or to the variations. The scope of one or more aspects may also encompass embodiments as a result of adding, to the embodiments and the variations, various modifications that may be conceived by those skilled in the art, and embodiments obtained by combining elements in different embodiments, as long as the resultant embodiments do not depart from the gist of the present disclosure.

For example, as the substrate, an insulating substrate that includes n-GaAs, n-GaN, or sapphire or an insulating substrate that includes a nitride-based semiconductor can be used.

For example, for the n-type semiconductor layer, n-GaAs, n-AlGaInP, n-AlGaAs, n-GaInP, n-AlGaN, or n-GaN, for instance, can be used.

For example, the active layer includes an undoped barrier layer and an undoped well layer. For the active layer, AlGaAs, InGaAs, GaAsP, GaAs, InGaN, or GaN, for instance, can be used.

For example, for the p-type semiconductor layer, p-AlGaAs, p-AlGaInP, p-GaInP, p-AlGaN, or p-GaN, for instance, can be used.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

An array type semiconductor laser device according to the present disclosure is applicable to a light source of a laser processing device that processes components using laser beams, for example.

1. An array type semiconductor laser device comprising:
a semiconductor laser array element in which a first semiconductor laser element and a second semiconductor laser element are disposed on a substrate,
wherein the first semiconductor laser element includes a first one conductivity type semiconductor layer and a first other conductivity type semiconductor layer, the first one conductivity type semiconductor layer being closer to the substrate than the first other conductivity type semiconductor layer is to the substrate,
the second semiconductor laser element includes a second one conductivity type semiconductor layer and a second other conductivity type semiconductor layer, the second one conductivity type semiconductor layer being closer to the substrate than the second other conductivity type semiconductor layer is to the substrate,
the first semiconductor laser element includes a first waveguide that extends in a first direction along a surface of the substrate,
the second semiconductor laser element is disposed, relative to the first semiconductor laser element, in a second direction along the surface of the substrate, the second direction being orthogonal to the first direction,
the second semiconductor laser element includes a second waveguide that extends in the first direction,
the first semiconductor laser element includes, on a first surface, a first electrode disposed on the first other conductivity type semiconductor layer, the first surface being an opposite surface of the semiconductor laser array element to the substrate,
the second semiconductor laser element includes, on the first surface, a second electrode disposed on the second other conductivity type semiconductor layer,
the first semiconductor laser element includes, on the first surface:
a third electrode disposed on the first one conductivity type semiconductor layer and between the first electrode and the second electrode; and
a fourth electrode disposed on the first one conductivity type semiconductor layer and across from the third electrode,
the second semiconductor laser element includes, on the first surface:
a fifth electrode disposed on the second one conductivity type semiconductor layer and between the second electrode and the third electrode; and
a sixth electrode disposed on the second one conductivity type semiconductor layer and across from the fifth electrode, and
the array type semiconductor laser device further comprises:
a first conductor that electrically connects the second electrode and the third electrode; and
a second conductor that electrically connects the fifth electrode and the sixth electrode.

2. The array type semiconductor laser device according to claim 1,
wherein at least one of the first semiconductor laser element or the second semiconductor laser element oscillates in a multi-transverse mode.

3. The array type semiconductor laser device according to claim 1,
wherein the first one conductivity type semiconductor layer and the second one conductivity type semiconductor layer each include an n-type semiconductor layer, and
the first other conductivity type semiconductor layer and the second other conductivity type semiconductor layer each include a p-type semiconductor layer.

4. The array type semiconductor laser device according to claim 1,
wherein the substrate is an insulating substrate.

5. The array type semiconductor laser device according to claim 1, further comprising:
a barrier layer between the substrate and the first one conductivity type semiconductor layer and between the substrate and the second one conductivity type semiconductor layer.

6. The array type semiconductor laser device according to claim 1, further comprising:
a recess between the first semiconductor laser element and the second semiconductor laser element.

7. The array type semiconductor laser device according to claim 6,
wherein the recess reaches the substrate.

8. The array type semiconductor laser device according to claim 6,
wherein a width of the recess in the second direction increases from a bottom of the recess to an opening of the recess.

9. The array type semiconductor laser device according to claim 1,
wherein a side of the semiconductor laser array element where the first surface is located is joined to a second surface of a first base.

10. The array type semiconductor laser device according to claim 9,
wherein the first base is provided with the first conductor.

11. The array type semiconductor laser device according to claim 10,
wherein the first conductor is a first conductive film disposed on the second surface.

12. The array type semiconductor laser device according to claim 11,
wherein the first conductive film is exposed from a backward end of the second semiconductor laser element in the first direction.

13. The array type semiconductor laser device according to claim 11,
wherein the first conductive film includes:
a first portion exposed from the first semiconductor laser element and the second semiconductor laser element, and electrically connected to the second electrode; and
a second portion exposed from the first semiconductor laser element and the second semiconductor laser element, and electrically connected to the third electrode, and
the array type semiconductor laser device further comprises a first metal wire that electrically connects the first portion and the second portion.

14. The array type semiconductor laser device according to claim 9,
wherein the first base is provided with the second conductor.

15. The array type semiconductor laser device according to claim 14,
wherein the second conductor is a second conductive film disposed on the second surface.

16. The array type semiconductor laser device according to claim 15,
wherein the second conductive film is exposed from a backward end of the second semiconductor laser element in the first direction.

17. The array type semiconductor laser device according to claim 1, further comprising:
a first terminal connected to the first electrode.

18. The array type semiconductor laser device according to claim 1, further comprising:
a second terminal connected to the fifth electrode.

19. The array type semiconductor laser device according to claim 16,
wherein the first conductor is a first conductive film disposed on the second surface,
the second conductive film includes:
a straight portion that is one end portion of the second conductive film and connected to the sixth electrode;
a straight portion that is an other end portion of the second conductive film and connected to the fifth electrode; and
a center portion, the first conductive film includes a first portion connected to the second electrode,
the first portion is between the straight portion that is the one end portion and the straight portion that is the other end portion,
the first conductive film includes a second portion connected to the third electrode,
an end portion of the second portion is exposed from a backward end of the first semiconductor laser element in the first direction, and
the center portion and an end portion of the first portion are exposed from the backward end of the second semiconductor laser element in the first direction.

20. The array type semiconductor laser device according to claim 16,
wherein the second conductive film is U-shaped in a top view.

21. The array type semiconductor laser device according to claim 19,
wherein the first conductor includes a metal wire that connects the first portion and the second portion.

22. The array type semiconductor laser device according to claim 16,
wherein the first conductor is a first conductive film disposed on the second surface, the first conductive film includes:
a straight portion that is one end portion of the first conductive film and connected to the second electrode;
a straight portion that is an other end portion of the first conductive film and connected to the third electrode; and
a center portion,
the second conductive film includes a first portion connected to the fifth electrode,
the first portion is between the straight portion that is the one end portion and the straight portion that is the other end portion,
the second conductive film includes a second portion connected to the sixth electrode,
an end portion of the first portion and an end portion of the second portion are exposed from a backward end of the first semiconductor laser element in the first direction, and
the center portion is exposed from the backward end of the first semiconductor laser element and the backward end of the second semiconductor laser element in the first direction.

23. The array type semiconductor laser device according to claim 16,
wherein the first conductor is a first conductive film disposed on the second surface, and
the first conductive film is U-shaped in a top view.

24. The array type semiconductor laser device according to claim 22,
wherein the second conductor includes a metal wire that connects the first portion and the second portion.

25. The array type semiconductor laser device according to claim 22,
wherein the second conductive film includes a connection film that connects the first portion and the second portion, and
the connection film is disposed above the second conductive film with an insulating film being disposed therebetween.

26. The array type semiconductor laser device according to claim 16,
wherein the first conductor is a first conductive film disposed on the second surface,
the first conductive film includes a p-wiring connected to the second electrode, and a first n-wiring connected to the third electrode,
the second conductive film includes a second n-wiring connected to the fifth electrode, and a third n-wiring connected to the sixth electrode,
an end portion of the first n-wiring is exposed from a backward end of the first semiconductor laser element in the first direction, the end portion of the first n-wiring being connected to the third electrode,
an end portion of the p-wiring, an end portion of the second n-wiring, and an end portion of the third n-wiring connected to the sixth electrode are exposed from the backward end of the second semiconductor laser element in the first direction, the end portion of the p-wiring being connected to the second electrode, the end portion of the second n-wiring being connected to the fifth electrode, and the end portion of the third n-wiring being connected to the sixth electrode,
the first conductor includes a first metal wire that connects the p-wiring and the first n-wiring, and
the second conductor includes a second metal wire that connects the second n-wiring and the third n-wiring.
